(19) United States
(12) Patent Application Publication
(10) Pub. No.: US 2022/0190243 A1
(43) Pub. Date: Jun. 16, 2022

(54) Tunable Adsorption and Wetting

(71) Applicant: The Research Foundation for The State University of New York, Binghamton, NY (US)

(72) Inventors: Morgteza Haji Bagheri, Babol (IR); Scott N. Schiffres, Vestal, NY (US)

(21) Appl. No.: 17/549,548

(22) Filed: Dec. 13, 2021

Related U.S. Application Data
(60) Provisional application No. 63/124,868, filed on Dec. 13, 2020.

(51) Int. Cl. H01L 49/00

(52) U.S. Cl. CPC H01L 49/006

(57) ABSTRACT

A device having a semiconductor nanomaterial surface, formed on a dielectric layer, having a conductive material under the dielectric layer, wherein a potential across the dielectric modified an absorption property of the semiconductor nanomaterial. A method of controlling a property of surface is provided, comprising: providing a device having a semiconductor nanomaterial having the surface, formed on a dielectric layer, having a conductive material under the dielectric layer; and controlling an electrostatic field at the semiconductor nanomaterial to modify at least one property of the surface with respect to molecules. The property may be absorption or wetting, for example.

### CROSS REFERENCE TO RELATED APPLICATIONS

The present application is a non-provisional of, and claims benefit of priority from, U.S. Patent Application No. 63/124,868, filed Dec. 13, 2020, the entirety of which is expressly incorporated herein by reference.

### FIELD OF THE INVENTION

The present invention relates to the field of controlling the surface properties of a material, particularly relating to wetting and adsorption.

### BACKGROUND OF THE INVENTION

Citation or identification of any reference herein, in any section of this application, shall not be construed as an admission that such reference is available as prior art to the present application. The disclosures of each reference disclosed herein, whether U.S. or foreign patent literature, or non-patent literature, are hereby incorporated by reference in their entirety in this application, and shall be treated as if the entirety thereof forms a part of this application.

Such references are provided for their disclosure of technologies to enable practice of the present invention, to provide basis for claim language, to make clear applicant's possession of the invention with respect to the various aggregates, combinations, and subcombinations of the respective disclosures or portions thereof (within a particular reference or across multiple references). The citation of references is intended to be part of the disclosure of the invention, and not merely supplementary background information. The incorporation by reference does not extend to teachings which are inconsistent with the invention as expressly described herein, and is evidence of a proper interpretation by persons of ordinary skill in the art of the terms, phrase and concepts discussed herein, without being limiting as the sole interpretation available.

Water condensation on a surface begins with the adsorption of water vapor molecules onto the surface. This is followed by the creation of hydrogen bonds among water molecules, which coalesce to form droplets and finally wet the surface. Wettability, a surface property, plays an important role in applications like ambient air water harvesting^{1,2} and condensation-evaporation in thermal power generation^{3,4}. Reversibly controlling adsorption, however, has yet to be demonstrated. Many of the methods to modify wetting use permanent surface functionalization^{5,6}. In contrast, making surfaces with the ability to reversibly change the wetting in real time could open up pathways toward creating new surface cleaning methods^{7,8}, more energy efficient adsorption refrigeration^{9,10} and water harvesting systems¹¹.

Condensation heat transfer plays a key role in many applications such as power generation, air conditioning, and water harvesting Among them, thermoelectric power plants account for ˜40% of fresh water withdrawal (and ˜3% use) in the United States which is mainly used for cooling in the condensers.¹² With the DOE's Water Security Grand Challenge goal to significantly lower fresh water use in power plants,¹³ there is an essential need to enhance the thermal efficiency of condensers.

Water condensation onto a surface begins with the adsorption of water vapor. This is followed by the creation of hydrogen bonds among water molecules, which coalesce to form droplets. Adsorption plays an important role in applications such as condensation-evaporation in thermal power generation, ambient air water harvesting, ice-nucleation, self-cleaning surfaces, and oil-water separation. The energy efficiency of these adsorption technologies can be improved by tunable adsorption. For example, in condensation heat transfer, tunable adsorption could enable a surface to condense more vapor by periodically switching between being easier to form a condensation film to easier to shed condensation. However, no method to reversibly control water adsorption has been detailed in the literature.

Thermoelectric power plants mostly burn fossil fuels to produce steam¹⁴ which is used in a turbine to generate power. To complete the thermodynamic cycle (Rankine cycle), the steam exiting the turbine needs to be converted to liquid water which is done through a phase change heat transfer process in the condensers. The condenser can be classified into two groups: surface and direct contact. In a surface condenser of a thermoelectric power plant, the steam is cooled down through passing over tubes that have fresh water circulating inside them. Condensation on the tube surfaces begins with the adsorption of water vapor molecules onto the surfaces. This is followed by the creation of hydrogen bonds among water molecules, which coalesce to form droplets and finally wet the surface. Therefore, the wettability of the tubes plays an important role in the condensation heat transfer rate and consequently the efficiency of the condenser. Usually, steam condenses by a process called film-wise condensation, which leads to a film of water that acts as a heat transfer barrier. Extensive research has been conducted in order to avoid film-wise and promote drop-wise condensation, which is more efficient because a fresh metal surface to the steam for more efficient condensation. Controlling the wettability of the surface through drop-wise condensation maximizes the heat transfer rate, however, the large nucleation energy barrier and high thermal resistance underneath the Cassie-state condensate droplets on the superhydrophobic surfaces with drop-wise condensation would compromise the heat transfer efficiency.¹⁵

Nanomaterials are materials with at least one external dimension that measures 100 nanometers (nm) or less or with internal structures measuring 100 nm or less. The nanomaterials that have the same composition as known materials in bulk form may have different physico-chemical properties. See, www.nanowerk.com/what-are-nanomaterials.php

Materials reduced to the nanoscale can suddenly show very different properties compared to what they show on a macroscale. For instance, opaque substances become transparent (copper); inert materials become catalysts (platinum); stable materials turn combustible (aluminum); solids turn into liquids at room temperature (gold); insulators become conductors (silicon).

Nanomaterials are not simply another step in the miniaturization of materials or particles. They often require very different production approaches. There are several processes to create various sizes of nanomaterials, classified as ‘top-down’ and ‘bottom-up’. Nanomaterials can be constructed by top down techniques, producing very small structures from larger pieces of material, for example by etching to create circuits on the surface of a silicon microchip. They may also be constructed by bottom up techniques, atom by atom or molecule by molecule. One way of doing this is self-assembly, in which the atoms or molecules arrange themselves into a structure due to their natural properties. Crystals grown for the semiconductor industry provide an example of self assembly, as does chemical synthesis of large molecules.

In zero-dimensional (0D) nanomaterials all the dimensions are measured within the nanoscale (no dimensions are larger than 100 nm). Most commonly, 0D nanomaterials are nanoparticles. In one-dimensional nanomaterials (1D), one dimension is outside the nanoscale. This class includes nanotubes, nanorods, and nanowires. In two-dimensional nanomaterials (2D), two dimensions are outside the nanoscale. This class exhibits plate-like shapes and includes graphene, nanofilms, nanolayers, and nanocoatings. Three-dimensional nanomaterials (3D) are materials that are not confined to the nanoscale in any dimension. This class can contain bulk powders, dispersions of nanoparticles, bundles of nanowires, and nanotubes as well as multi-nanolayers.

The properties of 1D materials may differ from 2D and 3D materials of the same constituents. For example, the bond strain will differ, which can materially change orbital hybridization as compared to planar materials.

As used herein, a “semiconductor nanomaterial” is a nanomaterial (i.e., nanoscale in at least one dimension) which has semiconductor properties within a range of applied conditions, and which have surface properties dependent on induced changes in a Fermi level.

a 2D material is one which has a region or regions of regular atomic array, which are present in a sheet. These are typically one or a few atomic layers thick. A 1D material as used herein has an elongated structure whose surface has a regular atomic arrangement which is cylindrical or narrow plates, For example, a 1D structure is a nanowire or nanotube, which may be affixed to and electrically influenced by a support. 0D structures, e.g., nanodots, are small clusters of atoms, which can display quantum properties. (According to the present invention, 0D materials are not preferred, as controlling their properties with an electrostatic field is challenging, and interactions between particles and clusters of particles may produce macroscale properties).

Carbon nanotubes (CNTs) are extended tubes of rolled graphene sheets. There are two types of CNT: single-walled (one tube) or multi-walled (several concentric tubes). Both of these are typically a few nanometers in diameter and several micrometers to centimeters long. CNTs have assumed an important role in the context of nanomaterials, because of their novel chemical and physical properties. They are mechanically very strong (their Young's modulus is over 1 terapascal, making CNTs as stiff as diamond), flexible (about their axis), and can conduct electricity extremely well (the helicity of the graphene sheet determines whether the CNT is a semiconductor or metallic). All of these remarkable properties give CNTs a range of potential applications: for example, in reinforced composites, sensors, nanoelectronics and display devices.

Inorganic nanotubes and inorganic fullerene-like materials based on layered compounds such as molybdenum disulphide were discovered shortly after CNTs. They have excellent tribological (lubricating) properties, resistance to shockwave impact, catalytic reactivity, and high capacity for hydrogen and lithium storage, which suggest a range of promising applications. Oxide-based nanotubes (such as titanium dioxide) are being explored for their applications in catalysis, photo-catalysis and energy storage.

Nanowires are ultrafine wires or linear arrays of dots, formed by self-assembly. They can be made from a wide range of materials. Semiconductor nanowires made of silicon, gallium nitride and indium phosphide have demonstrated remarkable optical, electronic and magnetic characteristics (for example, silica nanowires can bend light around very tight corners).

Nanowires have potential applications in high-density data storage, either as magnetic read heads or as patterned storage media, and electronic and opto-electronic nanodevices, for metallic interconnects of quantum devices and nanodevices.

The variability and site recognition of biopolymers, such as DNA molecules, offer a wide range of opportunities for the self-organization of wire nanostructures into much more complex patterns. The DNA backbones may then, for example, be coated in metal. They also offer opportunities to link nano- and biotechnology in, for example, biocompatible sensors and small, simple motors. Such self-assembly of organic backbone nanostructures is often controlled by weak interactions, such as hydrogen bonds, hydrophobic, or van der Waals interactions (generally in aqueous environments) and hence requires quite different synthesis strategies to CNTs, for example. The combination of one-dimensional nanostructures consisting of biopolymers and inorganic compounds opens up a number of scientific and technological opportunities.

“Buckminsterfullerene” (C60) is a 0D material. C60 are spherical molecules about 1 nm in diameter, comprising 60 carbon atoms arranged as 20 hexagons and 12 pentagons: the configuration of a football.

Dendrimers are spherical polymeric molecules, formed through a nanoscale hierarchical self-assembly process. There are many types of dendrimer; the smallest is several nanometers in size. Dendrimers are used in conventional applications such as coatings and inks, but they also have a range of interesting properties which could lead to useful applications.

Nanoparticles of semiconductors (quantum dots) display quantum effects, which limit the energies at which electrons and holes (the absence of an electron) can exist in the particles. As energy is related to wavelength (or color), this means that the optical properties of the particle can be finely tuned depending on its size. Thus, particles can be made to emit or absorb specific wavelengths (colors) of light, merely by controlling their size.

Two principal factors cause the properties of nanomaterials to differ significantly from other materials: increased relative surface area, and quantum effects. These factors can change or enhance properties such as reactivity, strength and electrical characteristics. As a particle decreases in size, a greater proportion of atoms are found at the surface compared to those inside. For example, a particle of size 30 nm has 5% of its atoms on its surface, at 10 nm 20% of its atoms, and at 3 nm 50% of its atoms. Thus, nanoparticles have a much greater surface area per unit mass compared with larger particles. As growth and catalytic chemical reactions occur at surfaces, this means that a given mass of material in nanoparticulate form will be much more reactive than the same mass of material made up of larger particles.

The 2D nature of graphene along with its stability at different temperature ranges allows for graphene to be used as a coating to modify bulk surface phenomena like adsorption⁵⁶ and wetting⁵⁷. The ability to change the carrier type (electrons and holes) and concentration in graphene via an applied electric field makes graphene an ideal candidate for creating surface coatings with selective adsorption properties.

Being extremely thin and thermally stable, graphene is an appealing method of surface modification. For instance, the contact angle of water on graphene has been found to be controllable through electrical- and chemical-doping. It has been noted that water adsorption onto a supported graphene changes graphene's electronic structure. Density functional theory (DFT) calculations have shown water adsorption tunes the charge carrier concentration and shifts the Fermi level of graphene in the case of weak physical contact between graphene and the supporting substrate (such as Cu, Pt, Au, Al, and Ag). Moreover, studies have incidentally demonstrated that chemisorption of oxygen onto bilayer graphene can be altered by changing the gate-graphene voltage.

Two-dimensional (2D) materials, sometimes referred to as single-layer materials, are crystalline materials consisting of a single layer of atoms. These materials have found use in applications such as photovoltaics, semiconductors, electrodes and water purification.

2D materials can generally be categorized as either 2D allotropes of various elements or as compounds (consisting of two or more covalently bonding elements). Layered combinations of different 2D materials are generally called van der Waals heterostructures. Some 700 2D materials have been predicted to be stable.

Graphene is an atomic-scale honeycomb lattice of carbon atoms. Graphene is a crystalline allotrope of carbon in the form of a nearly transparent (to visible light) one atom thick sheet. It is hundreds of times stronger than most steels by weight. It has the highest known thermal and electrical conductivity, displaying current densities 1,000,000 times that of copper.

Graphyne is another 2-dimensional carbon allotrope whose structure is similar to graphene's. It can be seen as a lattice of benzene rings connected by acetylene bonds. Depending on the content of the acetylene groups, graphyne can be considered a mixed hybridization, spⁿ, where 1<n<2, and versus graphene's (pure sp²) and diamond (pure sp³). First-principle calculations using phonon dispersion curves and ab-initio finite temperature, quantum mechanical molecular dynamics simulations showed graphyne and its boron nitride analogues to be stable.

Graphane is a polymer of carbon and hydrogen with the formula unit (CH)ₙ where n is large. Graphane is a form of fully hydrogenated (on both sides) graphene. Partial hydrogenation is then hydrogenated graphene. Graphane's carbon bonds are in sp³ configuration, as opposed to graphene's sp² bond configuration. Thus, graphane is a two-dimensional analog of cubic diamond. Graphane can be formed by electrolytic hydrogenation of graphene, few-layer graphene or high-oriented pyrolytic graphite. In the last case mechanical exfoliation of hydrogenated top layers can be used. p-doped graphane is postulated to be a high-temperature BCS theory superconductor with a Tc above 90 K.

Borophene is a crystalline atomic monolayer of boron and also known as boron sheet.

Germanene is a two-dimensional allotrope of germanium, with a buckled honeycomb structure.

Silicene is a two-dimensional allotrope of silicon, with a hexagonal honeycomb structure similar to that of graphene.

Si₂BN is predicted to have a 2d hexagonal, metallic allotrope with only sp² bonds.

Stanene is a predicted topological insulator that may display dissipationless currents at its edges near room temperature. It is composed of tin atoms arranged in a single layer, in a manner similar to graphene. Its buckled structure leads to high reactivity against common air pollutions such as NOₓ and COₓ and is able to trap and dissociate them at low temperature. Recently structure determination of stanene is done using low energy electron diffraction and it shows very interesting result of ultra-flat stanene on Cu(111) surface.

Plumbene is a two-dimensional allotrope of lead, with a hexagonal honeycomb structure similar to that of graphene.

Phosphorene is a 2-dimensional, crystalline allotrope of phosphorus. Its mono-atomic hexagonal structure makes it conceptually similar to graphene. However, phosphorene has substantially different electronic properties; in particular it possesses a nonzero band gap while displaying high electron mobility. This property potentially makes it a better semiconductor than graphene. The synthesis of phosphorene mainly consists of micromechanical cleavage or liquid phase exfoliation methods. The former has a low yield while the latter produce free standing nanosheets in solvent and not on the solid support. The bottom-up approaches like chemical vapor deposition (CVD) are still blank because of its high reactivity. Therefore, the most effective method for large area fabrication of thin films of phosphorene consists of wet assembly techniques like Langmuir-Blodgett involving the assembly followed by deposition of nanosheets on solid supports.

Antimonene is a two-dimensional allotrope of antimony, with its atoms arranged in a buckled honeycomb lattice. Antimonene is predicted to be a stable semiconductor in ambient conditions with suitable performance for (opto)electronics. Antimonene is very stable under ambient conditions. In a study made in 2018, antimonene modified screen-printed electrodes (SPE's) were subjected to a galvanostatic charge/discharge test using a two-electrode approach to characterize their supercapacitive properties. The best configuration observed, which contained 36 nanograms of antimonene in the SPE, showed a specific capacitance of 1578 F g⁻¹ at a current of 14 A g⁻¹. Over 10,000 of these galvanostatic cycles, the capacitance retention values drop to 65% initially after the first 800 cycles, but then remain between 65% and 63% for the remaining 9,200 cycles. The 36 ng antimonene/SPE system also showed an energy density of 20 mW h kg⁻¹ and a power density of 4.8 kW kg⁻¹.

Bismuthene, the two-dimensional allotrope of bismuth, is a topological insulator. At first glance the system is similar to graphene, as the Bi atoms arrange in a honeycomb lattice. However, the bandgap is as large as 800 mV due to the large spin-orbit-coupling of the Bi atoms and their interaction with the substrate. Thus, room-temperature applications of the quantum spin Hall effect come into reach. Top-down exfoliation of bismuthene has been reported in various instances with recent works promoting the implementation of bismuthene in the field of electrochemical sensing.

Single and double atom layers of platinum in a two-dimensional film geometry has been demonstrated. These atomically thin platinum films are epitaxially grown on graphene which imposes a compressive strain that modifies the surface chemistry of the platinum, while also allowing charge transfer through the graphene. Single atom layer of palladium with the thickness down to 2.6 Å, and rhodium with the thickness of less than 4 Å have also been synthesized.

Exotic hexagonal NaCl thin films on the (110) diamond surface were crystallized in the experiment following a theoretical prediction based on ab initio evolutionary algorithm USPEX.

Two-dimensional alloys are single atomic layers of alloy that is incommensurate with underlying substrate. The 2D ordered alloy of Pb and Sn has been synthesized. Moreover, the 2D all proportional solid solution alloy of Pb and Bi has been synthesized.

The supracrystals of 2D are monolayer crystals built of supra atomic periodic structures, where atoms in the nodes of the lattice are replaced by symmetric complexes. For example, in the hexagonal structure of graphene patterns of 4 or 6 carbon atoms would be arranged hexagonally instead of single atoms, as the repeating node in the unit cell.

2D boron nitride is an sp²-conjugated compound that forms a honeycomb structure of alternating boron and nitrogen atoms with a lattice spacing of 1.45Å. It adopts the hexagonal (h-BN) allotrope of the three possible crystalline forms of boron nitride because it is the most ubiquitous and stable structure. Boron nitride nanosheets contain two different edges. In the armchair edge structure, the edge consists of either boron or nitrogen atoms. In the zig-zag edge structure, the edge consists of alternating boron and nitrogen atoms. These 2D structures can stack on top of each other and are held by Van der Waal forces to form what is called few-layer boron nitride nanosheets. In these structures, the boron atoms of one sheet are positioned on top or below the nitrogen atoms due to electron deficient nature of boron and electron rich nature of nitrogen, respectively. Due to several similar structural similarities with graphene, boron nitride nanosheets are considered graphene analogs, often called “white graphene”.

Boron nanosheets (BNNS) defined as single or few layers of boron nitride whose aspect ratio is small. There are a few variations of 2D boron nitride structure. Boron nitride nanoribbons (BNNR) are boron nitride nanosheets with significant edge effects and have widths that are smaller than 50 nanometers. Boron nitride nanomeshes (BNNM) are boron nitride nanosheets that are placed upon specific metal substrates.

Boron nitride nanosheets have a wide bandgap that ranges from 5 to 6 eV and can be changed by the presence of Stone-Wales defects within the structure, by doping or functionalization, or by changing the number of layers. Due to this large bandgap and tunability as well as its surface flatness, boron nitride nanosheets are considered to be an excellent electric insulators and are often used as dielectrics in electrical devices. 2D boron nitride structures are excellent thermal conductors, with a thermal conductivity range of 100-270 W/mK. It has been suggested that single layer boron nitride nanosheets have a greater thermal conductivity than other forms of boron nitride nanosheets due to decreased phonon scattering from subsequent layers.

The thermal stability of boron nitride nanosheets is very high due to the high thermal stability properties of hexagonal boron nitride. As single layer and few-layer boron nitride nanosheets begin to oxidize and lose their electrical properties at 800° C.

Chemical vapor deposition (CVD) is a popular synthesis method to produce boron nitride because it is a highly controllable process that produces high quality and defect free monolayer and few-layer boron nitride nanosheets. In the majority of CVD methods, boron and nitride precursors react with a metal substrate at high temperature. This allows for nanosheets of a large area as the layers grow uniformly on the substrate. There is a wide range of boron and nitride precursors such as borazine and selection of these precursors depend on factors such as toxicity, stability, reactivity, and the nature of the CVD method.

While there are several mechanical cleaving methods to produce boron nitride nanosheets, they employ the same principle: using shear forces to break the Van der Waals interactions between the layers of boron nitride. The advantage of mechanical cleavage is that the nanosheets isolated from these techniques have few defects and retain the lateral size of the original substrate.

Inspired by its use in the isolation of graphene, micromechanical cleavage, also known as the Scotch-tape method, has been used to consistently isolate few-layer and monolayer boron nitride nanosheets by subsequent exfoliation of the beginning material with adhesive tape. Ball milling is another technique used to mechanically exfoliate boron nitride sheets from the parent substrate. In this process, shear forces are applied on the face of bulk boron nitride by rolling balls, which break the Van der Waal interactions between each layer. While the ball milling technique may allow for large quantities of boron nitride nanosheets, it does not allow for control the size or the number of layers of the resulting nanosheets. Furthermore, these nanosheets have more defects due to the aggressive nature of this technique.

Boron nitride nanosheets have also been isolated by using a vortex fluidic device, which uses centripetal force to shear off layers of boron nitride.

Boron nitride nanosheets may also be synthesized by the unzipping of boron nitride nanotubes (BNNT). These nanotubes can be made into sheets by breaking the bonds connecting the N and B atoms by potassium intercalation or by etching by plasma or an inert gas. The unzipping of boron nitride nanotubes by plasma can be used to control the size of the nanosheets, but it produces semiconducting boron nitride nanosheets. The potassium intercalation method produces a low yield of nanosheets as boron nitride is resistive to the effects of intercalants.

Solvent exfoliation is often used in tandem with sonication to break the weak Van der Waals interactions present in bulk boron nitride to isolate large quantities of boron nitride nanosheets. Polar solvents such as isopropyl alcohol and DMF have been found to be more effective in exfoliating boron nitride layers than nonpolar solvents because these solvents possess a similar surface energy to the surface energy of boron nitride nanosheets. Combinations of different solvents also exfoliate boron nitride better than when the solvents were used individually. However, many solvents that can be used to exfoliate boron nitride are fairly toxic and expensive. Common solvents such as water and isopropyl alcohol have been determined to be comparable to these toxic polar solvents in exfoliating boron nitride sheets.

Chemical functionalization of boron nitride involves attaching molecules onto the outer and inner layers of bulk boron nitride. There are three types of functionalization that can be done to boron nitride: covalent functionalization, ionic functionalization, or noncovalent functionalization. Layers are then exfoliated by placing the functionalized boron nitride into a solvent and allow the solvation force between the attached groups and the solvent to overcome the Van der Waal forces present in each layer. This method is slightly different than solvent exfoliation as solvent exfoliation relies on the similarities between the surface energies of the solvent and boron nitride layers to overcome the Van der Waals interactions.

The reaction of a mixture of boron and nitrogen precursors at high temperature can produce boron nitride nanosheets. In one method, boric acid and urea were reacted together at 900° C. The numbers of layers of these nanosheets were controlled by the urea content as well as the temperature.

Borocarbonitrides (BCN) are two-dimensional compounds that are synthesized such that they contain boron, nitrogen, and carbon atoms in a ratio BₓC_{y}N_{z}. Borocarbonitrides are distinct from B,N co-doped graphene in that the former contains separate boron nitride and graphene domains as well as rings with B—C, B—N, C—N, and C—C bonds. These compounds generally have a high surface area, but borocarbonitrides synthesized from a high surface area carbon material, urea, and boric acid tend to have the highest surface areas. This high surface area coupled with the presence of Stone-Wales defects in the structure of borocarbonitrides also allows for high absorption of CO₂ and CH₄, which may make borocarbonitride compounds a useful material in sequestering these gases.

The band gap of borocarbonitrides range from 1.0-3.9 eV and is dependent on the content of the carbon and boron nitride domains as they have different electrical properties. Borocarbonitrides with a high carbon content have lower bandgaps whereas those with higher content of boron nitride domains have higher band gaps. Borocarbonitrides synthesized in gas or solid reactions also tend to have large bandgaps and are more insulating in character. The wide range of composition of boronitrides allows for the tuning of the bandgap, which when coupled with its high surface area and Stone-Wales defects may make boronitrides a promising material in electrical devices.

Germanane is a single-layer crystal composed of germanium with one hydrogen bonded in the z-direction for each atom. Germanane's structure is similar to graphane, Bulk germanium does not adopt this structure. Germanane is produced in a two-step route starting with calcium germanide. From this material, the calcium (Ca) is removed by de-intercalation with HCl to give a layered solid with the empirical formula GeH. The Ca sites in Zintyl-phase CaGe₂ interchange with the hydrogen atoms in the HCl solution, producing GeH and CaCl₂.

Molybdenum disulfide monolayers consist of a unit of one layer of molybdenum atoms covalently bonded to two layers of sulfur atoms. While bulk molybdenum sulfide exists as 1T, 2H, or 3R polymorphs, molybdenum disulfide monolayers are found only in the 1T or 2H form. The 2H form adopts a trigonal prismatic geometry while the 1T form adopts an octahedral or trigonal antiprismatic geometry. Molybdenum monolayers can also be stacked due to Van der Waals interactions between each layer.

The electrical properties of molybdenum sulfide in electrical devices depends on factors such as the number of layers, the synthesis method, the nature of the substrate on which the monolayers are placed on, and mechanical strain.

As the number of layers decrease, the band gap begins to increase from 1.2 eV in the bulk material up to a value of 1.9 eV for a monolayer. Odd number of molybdenum sulfide layers also produce different electrical properties than even numbers of molybdenum sulfide layers due to cyclic stretching and releasing present in the odd number of layers. Molybdenum sulfide is a p-type material, but it shows ambipolar behavior when molybdenum sulfide monolayers that were 15 nm thick were used in transistors. However, most electrical devices containing molybdenum sulfide monolayers tend to show n-type behavior. The band gap of molybdenum disulfide monolayers can also be adjusted by applying mechanical strain or an electrical field. Increasing mechanical strain shifts the phonon modes of the molybdenum sulfide layers. This results in a decrease of the band gap and metal-to-insulator transition. Applying an electric field of 2-3 Vnm⁻¹ also decreases the indirect bandgap of molybdenum sulfide bilayers to zero.

Solution phase lithium intercalation and exfolation of bulk molybdenum sulfide produces molybdenum sulfide layers with metallic and semiconducting character due to the distribution of 1Tand 2H geometries within the material. This is due to the two forms of molybdenum sulfide monolayers having different electrical properties. The 1Tpolymorph of molybdenum sulfide is metallic in character while the 2H form is more semiconducting. However, molybdenum disulfide layers produced by electrochemical lithium intercalation are predominantly 1T and thus metallic in character as there is no conversion to the 2H form from the 1T form.

Chemical vapor deposition of molybdenum disulfide nanosheets involves reacting molybdenum and sulfur precursors on a substrate at high temperatures. This technique is often used in the preparing electrical devices with molybdenum disulfide components because the nanosheets are applied directly on the substrate; unfavorable interactions between the substrate and the nanosheets that would have occurred had they been separately synthesized are decreased. In addition, since the thickness and area of the molybdenum disulfide nanosheets can be controlled by the selection of specific precursors, the electrical properties of the nanosheets can be tuned.

Among the techniques that have been used to deposit molybdenum disulfide is electroplating. Ultra-thin films consisting of few-layers have been produced via this technique over graphene electrodes. In addition, other electrode materials were also electroplated with MoS₂, such as Titanium Nitride (TiN), glassy carbon and polytetrafluoroethylene. The advantage that this technique offers in producing 2D materials is its spatial growth selectivity and its ability to deposit over 3D surfaces. Controlling the thickness of electrodeposited materials can be achieved by adjusting the deposition time or current. Lasers can be used to form molybdenum disulfide nanosheets from molybdenum disulfide fullerene-like molecules.

Hafnium disulfide (HfS₂) has a layered structure with strong covalent bonding between the Hf and S atoms in a layer and weak van der Waals forces between layers. The compound has CdI₂ type structure and is an indirect band gap semiconducting material. The interlayer spacing between the layers is 0.56 nm, which is small compared to group VIB TMDs like MoS₂, making it difficult to cleave its atomic layers. However, recently its crystals with large interlayer spacing has grown using a chemical vapor transport route. These crystals exfoliate in solvents like N-Cyclohexyl-2-pyrrolidone (CHP) in a time of just some minutes resulting in a high-yield production of its few-layers resulting in increase of its indirect bandgap from 0.9 eV to 1.3 eV. As an application in electronics, its field-effect transistors have been realized using its few layers as a conducting channel material offering a high current modulation ratio larger than 10,000 at room temperature. Therefore, group IVB TMDs also holds potential applications in the field of opto-electronics.

Tungsten diselenide is an inorganic compound with the formula WSe2. The compound adopts a hexagonal crystalline structure similar to molybdenum disulfide. Every tungsten atom is covalently bonded to six selenium ligands in a trigonal prismatic coordination sphere, while each selenium is bonded to three tungsten atoms in a pyramidal geometry. The tungsten-selenium bond has a bond distance of 2.526 Å and the distance between selenium atoms is 3.34 Å. Layers stack together via van der Waals interactions. WSe2 is a stable semiconductor in the group-VI transition metal dichalcogenides. The electronic bandgap of WSe₂ can be tuned by mechanical strain which can also allow for conversion of the band type from indirect-to-direct in a WSe₂ bilayer.

MXenes are layered transition metal carbides and carbonitrides with general formula of Mₙ₊₁XₙTx, where M stands for early transition metal, X stands for carbon and/or nitrogen and Tx stands for surface terminations (mostly ═O, —OH or —F), and n=1−4. MXenes have high electric conductivity (10000−1500 Scm₋₁) combined with hydrophilic surfaces that can be tuned with solvents. MXene synthesis is readily scalable, with large (>50 g) batch sizes produced with no loss or change in properties as the size is increased. These materials show promise in energy storage applications, gas sensing, and composites. They are synthesized from ceramic precursor MAX phases by removing the single atomic layer “A” where M stands for Ti, Mo, W, Nb, Zr, Hf, V, Cr, Ta, Sc, A stands for Al, Si, and X stands for C, N.

Titanium Carbonitride has the formula Ti3CN and is an MXene, a compound composed of layered nitrides, carbides, or carbonitrides of transition metals. MXenes are synthesized via exfoliation or etching from a bulk three dimensional precursor MAX phase compound with the general formula Mₙ₊₁AXₙ, where M is a transition metal, A is an element such as aluminum or silicon, and X is either carbon or nitrogen, with n=1, 2, or 3. Selectively removing the A layer from the MAX phase material results in two dimensional layers of the MXene which can be separated by other ions (known as intercalation). MXenes are notable for their properties that combine aspects of both metals and ceramics including excellent thermal and electrical conductivity, heat resistance, easy machinability, and excellent volumetric capacitance. Ti₃CN may also be synthesized via thermal annealing. Applications include use as electronic shielding as it blocks electromagnetic interference 3-5 times better than copper foil. The material absorbs rather than reflects electronic signals.

Ni₃(HITP)₂ is an organic, crystalline, structurally tunable electrical conductor with a high surface area. HITP is an organic chemical (2,3,6,7,10,11-hexaaminotriphenylene). It shares graphene's hexagonal honeycomb structure. Multiple layers naturally form perfectly aligned stacks, with identical 2-nm openings at the centers of the hexagons. Room temperature electrical conductivity is ˜40 S cm⁻¹, comparable to that of bulk graphite and among the highest for any conducting metal-organic frameworks (MOFs). The temperature dependence of its conductivity is linear at temperatures between 100 K and 500 K, suggesting an unusual charge transport mechanism that has not been previously observed in organic semiconductors. The material was claimed to be the first of a group formed by switching metals and/or organic compounds. The material can be isolated as a powder or a film with conductivity values of 2 and 40 S cm⁻¹, respectively.

Single layers of 2D materials can be combined into layered assemblies. For example, bilayer graphene is a material consisting of two layers of graphene. Layered combinations of different 2D materials are generally called van der Waals heterostructures. Twistronics is the study of how the angle (the twist) between layers of two-dimensional materials can change their electrical properties.

See, en.wikipedia.org/wiki/Two-dimensional_materials

“A new self-assembling graphene-like material for flat semiconductors”. Kurzweil A I. 2014 May 1. Retrieved 2014 Aug. 24.

“Applied Graphene Materials plc: Graphene dispersions”. appliedgraphenematerials.com.

“‘Germanane’ may replace silicon for lighter, faster electronics”. Kurzweil A I. Retrieved 2013 Apr. 12.

“Global Demand for Graphene after Commercial Production to be Enormous”. AZONANO.com. 28 Feb. 2014. Retrieved 24 Jul. 2014.

“Graphene properties”. www.graphene-battery.net.2014-05-29. Retrieved 2014 May 29.

“Graphene Uses & Applications”. Graphenea. Retrieved 2014Apr. 13.

“Graphene-Info Market Report”. Graphene-info. June 2015. Retrieved 16 Jun. 2015.

“MaterialsWeb.org—Databases of Structural, Electronic, and Thermodynamic data for 2D and 3D Materials”.

“The Nobel Prize in Physics 2010”. The Nobel Foundation. Retrieved 2013Dec. 3.

“This Month in Physics History: Oct. 22, 2004: Discovery of Graphene”. APS News. Series II. 18 (9): 2. 2009.

Abdelhafiz, Ali; Vitale, Adam; Buntin, Parker; deGlee, Ben; Joiner, Corey; Robertson, Alex; Vogel, Eric M.; Warner, Jamie; Alamgir, Faisal M. (2018). “Epitaxial and atomically thin graphene—metal hybrid catalyst films: the dual role of graphene as the support and the chemically-transparent protective cap”. Energy & Environmental Science. 11 (6): 1610-1616. doi:10.1039/c8ee00539g.

Abdelhafiz, Ali; Vitale, Adam; Joiner, Corey; Vogel, Eric; Alamgir, Faisal M. (2015 Mar. 16). “Layer-by-Layer Evolution of Structure, Strain, and Activity for the Oxygen Evolution Reaction in Graphene-Templated Pt Monolayers”. ACS Applied Materials & Interfaces. 7 (11): 6180-6188. doi:10.1021/acsami.5b00182. PMID 25730297.

Ahmed, Rezwan; Nakagawa, Takeshi; Mizuno, Seigi (2020). “Structure determination of ultra-flat stanene on Cu(111) using low energy electron diffraction”. Surface Science. 691: 121498. Bibcode:2020SurSc.69121498A. doi:10.1016/j.susc.2019.121498.

Anasori, Babak; Lukatskaya, Maria R.; Gogotsi, Yury (2017Jan. 17). “2D metal carbides and nitrides (MXenes) for energy storage”. Nature Reviews Materials. 2 (2): 16098. Bibcode:2017NatRM...216098A. doi:10.1038/natrevmats.2016.98. ISSN 2058-8437. OSTI 1399374.

Andriotis, Antonis N. (2016 Jan. 1). “Prediction of a new graphenelike”. Physical Review B. 93 (8): 081413. Bibcode:2016PhRvB..93h1413A. doi:10.1103/PhysRevB.93.081413.

Andronico, Michael (14 Apr. 2014). “5 Ways Graphene Will Change Gadgets Forever”. Laptop.

Ares, P.; Aguilar-Galindo, F.; Rodríguez-San-Miguel, D.; Aldave, D. A.; Díaz-Tendero, S.; Alcamí, M.; Martín, F.; Gómez-Herrero, J.; Zamora, F. (2016). “Mechanical Isolation of Highly Stable Antimonene under Ambient Conditions”. Adv. Mater. 28 (30): 6332-6336. arXiv:1608.06859. Bibcode:2016arXiv160806859A. doi:10.1002/adma.201602128. hdl:10486/672484. PMID 27272099. S2CID 8296292.

Ares, P.; Palacios, J. J.; Abellán, G.; Gómez-Herrero, J.; Zamora, F. (2018). “Recent progress on antimonene: a new bidimensional material”. Adv. Mater. 30 (2): 1703771. doi:10.1002/adma.201703771. hdl:10486/688820. PMID 29076558.

Ashton, M.; Paul, J.; Sinnott, S. B.; Hennig, R. G. (2017). “Topology-Scaling Identification of Layered Solids and Stable Exfoliated 2D Materials”. Phys. Rev. Lett. 118 (10): 106101. arXiv:1610.07673. Bibcode:2017PhRvL.118j6101A. doi:10.1103/PhysRevLett.118.106101. PMID 28339265. S2CID 32012137.

Backes, Claudia; et al. (2020). “Production and processing of graphene and related materials”. 2D Materials. 7 (2): 022001. Bibcode:2020TDM.....7b2001B. doi:10.1088/2053-1583/ab1e0a.

Balaban A T, Rentia C C, Ciupitu E (1968). “Chemical graphs. 6. Estimation of relative stability of several planar and tridimensional lattices for elementary carbon”. Revue Roumaine de Chimie. 13 (2): 231-.

Bampoulis, P.; Zhang, L.; Safaei, A.; van Gastel, R.; Poelsema, B.; Zandvliet, H. J. W. (2014). “Germanene termination of Ge2Pt crystals on Ge(110)”. Journal of Physics: Condensed Matter. 26 (44): 442001. arXiv:1706.00697. Bibcode:2014JPCM...26R2001B. doi:10.1088/0953-8984/26/44/442001. PMID 25210978. S2CID 36478002.

Berger, Andy (Jul. 17, 2015). “Beyond Graphene, a Zoo of New 2-D Materials”. Discover Magazine. Retrieved 2015 Sep. 19.

Bhimanapati, G. R.; Glavin, N. R.; Robinson, J. A. (2016 Jan. 1). “2D Boron Nitride”. In lacopi, Francesca; Boeckl, John J.; Jagadish, Chennupati (eds.). Semiconductors and Semimetals. 2D Materials. 95. Elsevier. pp. 101-147. doi:10.1016/bs.semsem.2016.04.004. ISBN 9780128042724.

Bhimanapati, Ganesh R.; Lin, Zhong; Meunier, Vincent; Jung, Yeonwoong; Cha, Judy; Das, Saptarshi; Xiao, Di; Son, Youngwoo; Strano, Michael S. (2015). “Recent Advances in Two-Dimensional Materials beyond Graphene”. ACS Nano. 9 (12): 11509-11539. doi:10.1021/acsnano.5b05556. PMID 26544756.

Bianco, E.; Butler, S.; Jiang, S.; Restrepo, O. D.; Windl, W.; Goldberger, J. E. (2013). “Stability and Exfoliation of Germanane: A Germanium Graphane Analogue”. ACS Nano. 7 (5): 4414-21. doi:10.1021/nn4009406. hdl:1811/54792. PMID 23506286.

Boustani, Ihsan (January 1997). “New quasi-planar surfaces of bare boron”. Surface Science. 370 (2-3): 355-363. Bibcode:1997SurSc.370..355B. doi:10.1016/50039-6028(96)00969-7.

Brazhe, R. A.; Kochaev, A. I. (2012). “Flexural waves in graphene and 2D supracrystals”. Physics of the Solid State. 54 (8): 1612-1614. Bibcode:2012PhSS...54.1612B. doi:10.1134/S1063783412080069. S2CID 120094142.

Briggs, Natalie; Subramanian, Shruti; Lin, Zhong; Li, Xufan; Zhang, Xiaotian; Zhang, Kehao; Xiao, Kai; Geohegan, David; Wallace, Robert; Chen, Long-Qing; Terrones, Mauricio; Ebrahimi, Aida; Das, Saptarshi; Redwing, Joan; Hinkle, Christopher; Momeni, Kasra; van Duin, Adri; Crespi, Vin; Kar, Swastik; Robinson, Joshua A. (2019). “A roadmap for electronic grade 2D materials”. 2D Materials. 6 (2): 022001. Bibcode:2019TDM.....6b2001B. doi:10.1088/2053-1583/aaf836. OSTI 1503991.

Butler, Sheneve Z.; Hollen, Shawna M.; Cao, Linyou; Cui, Yi; Gupta, Jay A.; Gutiérrez, Humberto R.; Heinz, Tony F.; Hong, Seung Sae; Huang, Jiaxing (2013). “Progress, Challenges, and Opportunities in Two-Dimensional Materials Beyond Graphene”. ACS Nano. 7 (4): 2898-2926. doi:10.1021/nn400280c. PMID 23464873.

Cao, Yameng; Robson, Alexander J.; Alharbi, Abdullah; Roberts, Jonathan; Woodhead, Christopher Stephen; Noori, Yasir Jamal; Gavito, Ramon Bernardo; Shahrjerdi, Davood; Roedig, Utz (2017). “Optical identification using imperfections in 2D materials”. 2D Materials. 4 (4): 045021. arXiv:1706.07949. Bibcode:2017TDM.....4d5021C. doi:10.1088/2053-1583/aa8b4d. S2CID 35147364.

Carrow, James K.; Gaharwar, Akhilesh K. (February 2015). “Bioinspired Polymeric Nanocomposites for Regenerative Medicine”. Macromolecular Chemistry and Physics. 216 (3): 248-264. doi:10.1002/macp.201400427.

Conley, Hiram J.; Wang, Bin; Ziegler, Jed I.; Haglund, Richard F.; Pantelides, Sokrates T.; Bolotin, Kirill I. (2013). “Bandgap Engineering of Strained Monolayer and Bilayer MoS2”. Nano Letters. 13 (8): 3626-3630. arXiv:1305.3880. Bibcode:2013NanoL..13.3626C. doi:10.1021/n14014748. PMID 23819588. S2CID 8191142.

Deysher, Grayson; Shuck, Christopher Eugene; Hantanasirisakul, Kanit; Frey, Nathan C.; Foucher, Alexandre C.; Maleski, Kathleen; Sarycheva, Asia; Shenoy, Vivek B.; Stach, Eric A.; Anasori, Babak; Gogotsi, Yury (5 Dec. 2019). “Synthesis of Mo4VAlC4 MAX Phase and Two-Dimensional Mo4VC4 MXene with Five Atomic Layers of Transition Metals”. ACS Nano. 14 (1): 204-217. doi:10.1021/acsnano.9b07708. PMID 31804797.

Duan, Haohong; Yan, Ning; Yu, Rong; Chang, Chun-Ran; Zhou, Gang; Hu, Han-Shi; Rong, Hongpan; Niu, Zhiquiang; Mao, Junjie; Asakura, Hiroyuki; Tanaka, Tsunehiro; Dyson, Paul Joseph; Li, Jun; Li, Yadong (17 Jan. 2014). “Ultrathin rhodium nanosheets”. Nature Communications. 5: 3093. Bibcode:2014NatCo...5.3093D. doi:10.1038/ncomms4093. PMID 24435210.

Elias, D. C.; Nair, R. R.; Mohiuddin, T. M. G.; Morozov, S. V.; Blake, P.; Halsall, M. P.; Ferrari, A. C.; Boukhvalov, D. W.; Katsnelson, M. I.; Geim, A. K.; Novoselov, K. S.; et al. (2009). “Control of Graphene's Properties by Reversible Hydrogenation: Evidence for Graphane”. Science. 323 (5914): 610-3. arXiv:0810.4706. Bibcode:2009Sci...323..610E. doi:10.1126/science.1167130. PMID 19179524. S2CID 3536592.

Enyashin, Andrey N.; Ivanovskii, Alexander L. (2011). “Graphene Allotropes”. Physica Status Solidi B. 248 (8): 1879-1883. Bibcode:2011PSSBR.248.1879E. doi:10.1002/pssb.201046583.

Feng, Baojie; Zhang, Jin; Zhong, Qing; Li, Wenbin; Li, Shuai; Li, Hui; Cheng, Peng; Meng, Sheng; Chen, Lan; Wu, Kehui (28 Mar. 2016). “Experimental realization of two-dimensional boron sheets”. Nature Chemistry. 8 (6): 563-568. arXiv:1512.05029. Bibcode:2016NatCh...8..563F. doi:10.1038/nchem.2491. PMID 27219700. S2CID 19475989.

Gaharwar, A. K.; et al. (2013). Nanomaterials in tissue engineering: fabrication and applications. Oxford: Woodhead Publishing. ISBN 978-0-85709-596-1.

Gaharwar, A K; Peppas, N A; Khademhosseini, A (March 2014). “Nanocomposite hydrogels for biomedical applications”. Biotechnology and Bioengineering. 111 (3): 441-53. doi:10.1002/bit.25160. PMC 3924876. PMID 24264728.

Garcia, J. C.; de Lima, D. B.; Assali, L. V. C.; Justo, J. F. (2011). “Group IV graphene- and graphane-like nanosheets”. J. Phys. Chem. C. 115 (27): 13242-13246. arXiv:1204.2875. doi:10.1021/jp203657w. S2CID 98682200.

Goenka, S; Sant, V; Sant, S (10 Jan. 2014). “Graphene-based nanomaterials for drug delivery and tissue engineering”. Journal of Controlled Release. 173: 75-88. doi:10.1016/j.jconrel.2013.10.017. PMID 24161530.

Gopalakrishnan, K.; Moses, Kota; Govindaraj, A.; Rao, C. N. R. (2013 Dec. 1). “Supercapacitors based on nitrogen-doped reduced graphene oxide and borocarbonitrides”. Solid State Communications. Special Issue: Graphene V: Recent Advances in Studies of Graphene and Graphene analogues. 175-176: 43-50. Bibcode:2013SSCom.175...43G. doi:10.1016/j.ssc.2013.02.005.

Gusmao, Rui; Sofer, Zdenek; Bousa, Daniel; Pumera, Martin (29 Jul. 2017). “Pnictogens (As, Sb, Bi) Nanosheets by Shear Exfoliation Using Kitchen Blenders for Electrochemical Applications”. Angewandte Chemie International Edition. 56 (46): 14417-14422. doi:10.1002/anie.201706389. PMID 28755460.

Heimann, R. B.; Evsvukov, S. E.; Koga, Y. (1997). “Carbon allotropes: a suggested classification scheme based on valence orbital hybridization”. Carbon. 35 (10-11): 1654-1658. doi:10.1016/S0008-6223(97)82794-7.

Hsu, Chia-Hsiu; Huang, Zhi-Quan; Chuang, Feng-Chuan; Kuo, Chien-Cheng; Liu, Yu-Tzu; Lin, Hsin; Bansil, Arun (2015 Feb. 10). “The nontrivial electronic structure of Bi/Sb honeycombs on SiC(0001)”. New Journal of Physics. 17 (2): 025005. Bibcode:2015NJPh...17b5005H. doi:10.1088/1367-2630/17/2/025005.

Hu, Guohua; Kang, Joohoon; Ng, Leonard W. T.; Zhu, Xiaoxi; Howe, Richard C. T.; Jones, Christopher G.; Hersam, Mark C.; Hasan, Tawfique (2018). “Functional inks and printing of two-dimensional materials”. Chemical Society Reviews. 47 (9): 3265-3300. doi:10.1039/c8cs00084k. PMID 29667676.

Huang, X; Tan, C; Yin, Z; Zhang, H (9 Apr. 2014). “25th anniversary article: hybrid nanostructures based on two-dimensional nanomaterials”. Advanced Materials & Processes. 26 (14): 2185-204. doi:10.1002/adma.201304964. PMID 24615947.

Ilyin, A. M.; et al. (2011). “Computer simulation and experimental study of graphane-like structures formed by electrolytic hydrogenation”. Physica E. 43 (6): 1262-65. Bibcode:2011PhyE...43.1262I. doi:10.1016/j.physe.2011.02.012.

Ipaves, B.; Justo, J. F.; Assali, L. V. C. (2019). “Carbon-Related Bilayers: Nanoscale Building Blocks for Self-Assembly Nanomanufacturing”. J. Phys. Chem. C. 123 (37): 23195-23204. arXiv:1908.06218. doi:10.1021/acs.jpcc.9b05446. S2CID 201070776.

Iqbal, Aamir; Shahzad, Faisal; Hantanasirisakul, Kanit; Kim, Myung-Ki; Kwon, Jisung; Hong, Junpyo; Kim, Hyerim; Kim, Daesin; Gogotsi, Yury; Koo, Chong Min (2020 Jul. 24). “Anomalous absorption of electromagnetic waves by 2D transition metal carbonitride Ti3CNTx (MXene)”. Science. 369 (6502): 446-450. Bibcode:2020Sci...369..446I. doi:10.1126/science.aba7977 (inactive 2020 Dec. 5). ISSN 0036-8075. PMID 32703878.

Irving, Michael (2020 Jul. 24). “2D material absorbs electromagnetic waves for superior shielding”. New Atlas. Retrieved 2020 Jul. 26.

Kannan, Padmanathan Karthick; Late, Dattatray J.; Morgan, Hywel; Rout, Chandra Sekhar (2015 Aug. 6). “Recent developments in 2D layered inorganic nanomaterials for sensing”. Nanoscale. 7 (32): 13293-13312. Bibcode:2015Nanos...713293K. doi:10.1039/c5nr03633j. PMID 26204797.

Kaur, Harneet (2016). “High Yield Synthesis and Chemical Exfoliation of Two-Dimensional Layered Hafnium Disulphide”. Nano Research. 11: 343-353. arXiv:1611.00895. doi:10.1007/s12274-017-1636-x. S2CID 99414438.

Kerativitayanan, P; Carrow, J K; Gaharwar, A K (26 May 2015). “Nanomaterials for Engineering Stem Cell Responses”. Advanced Healthcare Materials. 4 (11): 1600-27. doi:10.1002/adhm.201500272. PMID 26010739.

Khakbaz, Pedram; Moshayedi, Milad; Hajian, Sajjad; Soleimani, Maryam; Narakathu, Binu B.; Bazuin, Bradley J.; Pourfath, Mandi; Atashbar, Massood Z. (2019 Dec. 12). “Titanium Carbide MXene as NH3 Sensor: Realistic First-Principles Study”. The Journal of Physical Chemistry C. 123 (49): 29794-29803. doi:10.1021/acs.jpcc.9b09823. ISSN 1932-7447.

Kochaev, A. I.; Karenin, A. A.; Meftakhutdinov, R. M.; Brazhe, R. A. (2012). “2D supracrystals as a promising materials for planar nanoacoustoelectronics”. Journal of Physics: Conference Series. 345 (1): 012007. Bibcode:2012JPhCS.345a2007K. doi:10.1088/1742-6596/345/1/012007.

Kumar, Nitesh; Moses, Kota; Pramoda, K.; Shirodkar, Sharmila N.; Mishra, Abhishek Kumar; Waghmare, Umesh V.; Sundaresan, A.; Rao, C. N. R. (2013 Apr. 23). “Borocarbonitrides, BxCyNz”. Journal of Materials Chemistry A. 1 (19): 5806. doi:10.1039/c3ta01345f.

Lazanas, Alexandros Ch.; Tsirka, Kyriaki; Paipetis, Alkiviadis S.; Prodromidis, Mamas I. (2020). “2D bismuthene/graphene modified electrodes for the ultra-sensitive stripping voltammetric determination of lead and cadmium”. Electrochimica Acta. 336: 135726. doi:10.1016/j.electacta.2020.135726.

Lee, Kangho; Kim, Hye-Young; Lotya, Mustafa; Coleman, Jonathan N.; Kim, Gyu-Tae; Duesberg, Georg S. (2011 Sep. 22). “Electrical Characteristics of Molybdenum Disulfide Flakes Produced by Liquid Exfoliation”. Advanced Materials. 23 (36): 4178-4182. doi:10.1002/adma.201101013. PMID 21823176.

Li, Guoxing; Li, Yuliang; Liu, Huibiao; Guo, Yanbing; Li, Yongjun; Zhu, Daoben (2010). “Architecture of graphdiyne nanoscale films”. Chemical Communications. 46 (19): 3256-3258. doi:10.1039/B922733D. PMID 20442882. S2CID 43416849.

Li, L.; Yu, Y.; Ye, G. J.; Ge, Q.; Ou, X.; Wu, H.; Feng, D.; Chen, X. H.; Zhang, Y. (2014). “Black phosphorus field-effect transistors”. Nature Nanotechnology. 9 (5): 372-377. arXiv:1401.4117. Bibcode:2014NatNa...9..372L. doi:10.1038/nnano.2014.35. PMID 24584274. S2CID 17218693.

Li, Lu Hua; Cervenka, Jiri; Watanabe, Kenji; Taniguchi, Takashi; Chen, Ying (2014 Feb. 25). “Strong Oxidation Resistance of Atomically Thin Boron Nitride Nanosheets”. ACS Nano. 8 (2): 1457-1462. arXiv:1403.1002. Bibcode:2014arXiv1403.1002L. doi:10.1021/nn500059s. PMID 24400990. S2CID 5372545.

Li, Lu Hua; Chen, Ying (2016). “Atomically Thin Boron Nitride: Unique Properties and Applications”. Advanced Functional Materials. 26 (16): 2594-2608. arXiv:1605.01136. Bibcode:2016arXiv160501136L. doi:10.1002/adfm.201504606. S2CID 102038593.

Li, Lu Hua; Chen, Ying; Behan, Gavin; Zhang, Hongzhou; Petravic, Mladen; Glushenkov, Alexey M. (2011 Aug. 3). “Large-scale mechanical peeling of boron nitride nanosheets by low-energy ball milling”. Journal of Materials Chemistry. 21 (32): 11862. doi:10.1039/c1jm11192b. S2CID 41206042.

Li, Xiao; Zhu, Hongwei (2015 Mar. 1). “Two-dimensional MoS2: Properties, preparation, and applications”. Journal of Materiomics. 1 (1): 33-44. doi:10.1016/j.jmat.2015.03.003.

Lin, Yi; Connell, John W. (2012 Oct. 29). “Advances in 2D boron nitride nanostructures: nanosheets, nanoribbons, nanomeshes, and hybrids with graphene”. Nanoscale. 4 (22): 6908-39. Bibcode:2012Nanos...4.6908L. doi:10.1039/c2nr32201c. PMID 23023445.

Mak, Kin Fai; Lee, Changgu; Hone, James; Shan, Jie; Heinz, Tony F. (2010). “Atomically ThinMoS2: A New Direct-Gap Semiconductor”. Physical Review Letters. 105 (13): 136805. arXiv:1004.0546. Bibcode:2010PhRvL.105m6805M. doi:10.1103/physrevlett.105.136805. PMID 21230799. S2CID 40589037.

Mannix, A. J.; Zhou, X.-F.; Kiraly, B.; Wood, J. D.; Alducin, D.; Myers, B. D.; Liu, X.; Fisher, B. L.; Santiago, U.; Guest, J. R.; et al. (17 Dec. 2015). “Synthesis of borophenes: Anisotropic, two-dimensional boron polymorphs”. Science. 350 (6267): 1513-1516. Bibcode:2015Sci...350.1513M. doi:10.1126/science.aad1080. PMC 4922135. PMID 26680195.

Martinez, Carmen C.; Gusmao, Rui; Sofer, Zdenek; Pumera, Martin (2019). “Pnictogen-Based Enzymatic Phenol Biosensors: Phosphorene, Arsenene, Antimonene, and Bismuthene”. Angewandte Chemie International Edition. 58 (1): 134-138. doi:10.1002/anie.201808846. PMID 30421531.

Martínez-Periñán, Emiliano; Down, Michael P.; Gibaja, Carlos; Lorenzo, Encarnación; Zamora, Félix; Banks, Craig E. (2018). “Antimonene: A Novel 2D Nanomaterial for Supercapacitor Applications”. Advanced Energy Materials. 8 (11): 1702606. doi:10.1002/aenm.201702606. hdl:10486/688798. ISSN 1614-6840.

Murugesan, Sankaran; Akkineni, Arunkumar; Chou, Brendan P.; Glaz, Micah S.; Vanden Bout, David A.; Stevenson, Keith J. (2013 Sep. 24). “Room Temperature Electrodeposition of Molybdenum Sulfide for Catalytic and Photoluminescence Applications”. ACS Nano. 7 (9): 8199-8205. doi:10.1021/nn4036624. ISSN 1936-0851. PMID 23962095.

Naguib, M.; Kurtoglu, M.; Presser, V.; Lu, J.; Niu, J.; Heon, M.; Hultman, L.; Gogotsi, Y.; Barsoum, M. W. (2011). “Two-dimensional nanocrystals produced by exfoliation of Ti3AlC2”. Advanced Materials. 23 (37): 4248-53. doi:10.1002/adma.201102306. PMID 21861270.

Najmaei, Sina; Zou, Xiaolong; Er, Dequan; Li, Junwen; Jin, Zehua; Gao, Weilu; Zhang, Qi; Park, Sooyoun; Ge, Liehui (2014 Mar. 12). “Tailoring the Physical Properties of Molybdenum Disulfide Monolayers by Control of Interfacial Chemistry”. Nano Letters. 14 (3): 1354-1361. Bibcode:2014NanoL..14.1354N. CiteSeerX 10.1.1.642.1938. doi:10.1021/n1404396p. PMID 24517325.

Nandwana, Dinkar; Ertekin, Elif (21 Jun. 2015). “Lattice mismatch induced ripples and wrinkles in planar graphene/boron nitride superlattices”. Journal of Applied Physics. 117 (234304): 234304. arXiv:1504.02929. Bibcode:2015JAP...117w4304N. doi:10.1063/1.4922504. S2CID 119251606.

Noori, Yasir J.; Thomas, Shibin; Ramadan, Sami; Smith, Danielle E.; Greenacre, Vicki K.; Abdelazim, Nema; Han, Yisong; Beanland, Richard; Hector, Andrew L.; Klein, Norbert; Reid, Gillian (2020 Nov. 4). “Large-Area Electrodeposition of Few-Layer MoS2 on Graphene for 2D Material Heterostructures”. ACS Applied Materials & Interfaces. 12 (44): 49786-49794. arXiv:2005.08616. doi:10.1021/acsami.0c14777. ISSN 1944-8244. PMID 33079533. S2CID 224828493.

Özçelik, V. Ongun; Ciraci, S. (Jan. 10, 2013). “Size Dependence in the Stabilities and Electronic Properties of α-Graphyne and Its Boron Nitride Analogue”. The Journal of Physical Chemistry C. 117 (5): 2175-2182. arXiv:1301.2593. doi:10.1021/jp3111869. hdl:11693/11999. S2CID 44136901.

Ozdemir, Burak; Barone, Veronica (2020). “Thickness dependence of solar cell efficiency in transition metal dichalcogenides MX2 (M: Mo, W; X: S, Se, Te)”. Solar Energy Materials and Solar Cells. 212: 110557. doi:10.1016/j.solmat.2020.110557.

Pakdel, Amir; Zhi, Chunyi; Bando, Yoshio; Golberg, Dmitri (2012 Jun. 1). “Low-dimensional boron nitride nanomaterials”. Materials Today. 15 (6): 256-265. doi:10.1016/S1369-7021(12)70116-5.

Qi-Qi, Yang (2 Oct. 2018). “2D bismuthene fabricated via acid-intercalated exfoliation showing strong nonlinear near-infrared responses for mode-locking lasers”. Nanoscale. 10 (45): 21106-21115. doi:10.1039/c8nr06797j. PMID 30325397.

Raidongia, Kalyan; Nag, Angshuman; Hembram, K. P. S. S.; Waghmare, Umesh V.; Datta, Ranjan; Rao, C. N. R. (2010 Jan. 4). “BCN: A Graphene Analogue with Remarkable Adsorptive Properties”. Chemistry—A European Journal. 16 (1): 149-157. doi:10.1002/chem.200902478. PMID 19946909.

Rao, C. N. R.; Gopalakrishnan, K. (2016 Oct. 31). “Borocarbonitrides, BxCyNz: Synthesis, Characterization, and Properties with Potential Applications”. ACS Applied Materials & Interfaces. 9 (23): 19478-19494. doi:10.1021/acsami.6b08401. PMID 27797466.

Rao, C. N. R.; Nag, Angshuman (2010 Sep. 1). “Inorganic Analogues of Graphene”. European Journal of Inorganic Chemistry. 2010 (27): 4244-4250. doi:10.1002/ejic.201000408.

Rao, C. N. R.; Ramakrishna Matte, H. S. S.; Maitra, Urmimala (2013 Dec. 9). “Graphene Analogues of Inorganic Layered Materials”. Angewandte Chemie International Edition. 52 (50): 13162-13185. doi:10.1002/anie.201301548. PMID 24127325.

Rao, C. N. R; Maitra, Urmimala (2015 Jan. 1). “Inorganic Graphene Analogs”. Annual Review of Materials Research. 45 (1): 29-62. Bibcode:2015AnRMS..45...29R. doi:10.1146/annurev-matsci-070214-021141.

Reis, Felix; Li, Gang; Dudy, Lenart; Bauernfiend, Maximilian; Glass, Stefan; Hanke, Werner; Thomale, Ronny; Schaefer, Joerg; Claessen, Ralph (Jul. 21, 2017). “Bismuthene on a SiC substrate: A candidate for a high-temperature quantum spin Hall material”. Science. 357 (6348): 287-290. arXiv:1608.00812. Bibcode:2017Sci...357..287R. doi:10.1126/science.aai8142. PMID 28663438. S2CID 23323210.

Ritu, Harneet (2016). “Large Area Fabrication of Semiconducting Phosphorene by Langmuir-Blodgett Assembly”. Sci. Rep. 6: 34095. arXiv:1605.00875. Bibcode:2016NatSR...634095K. doi:10.1038/srep34095. PMC 5037434. PMID 27671093.

Savini, G.; et al. (2010). “Doped graphane: a prototype high-Tc electron-phonon superconductor”. Phys Rev Lett. 105 (5): 059902. arXiv:1002.0653. Bibcode:2010PhRvL.105e9902S. doi:10.1103/physrevlett.105.059902.

Schirber, Michael (24 Feb. 2012). “Focus: Graphyne May Be Better than Graphene”. Physics. 5 (24): 24. Bibcode:2012PhyOJ...5...245. doi:10.1103/Physics.5.24.

Schmidt, Robert; Niehues, Iris; Schneider, Robert; Drüppel, Matthias; Deilmann, Thorsten; Rohlfing, Michael; Michaelis de Vasconcellos, Steffen; Castellanos-Gomez, Andres; Bratschitsch, Rudolf (2016). “Reversible Uniaxial Strain Tuning in Atomically thin WSe2”. 2D Materials. 3 (2): 021011. Bibcode:2016TDM.....3b1011S. doi:10.1088/2053-1583/3/2/021011.

Schutte, W. J.; De Boer, J. L.; Jellinek, F (1986). “Crystal Structures of Tungsten Disulfide and Diselenide”. Journal of Solid State Chemistry. 70 (2): 207-209. Bibcode:1987JSSCh..70..2075. doi:10.1016/0022-4596(87)90057-0.

Shahzad, F.; Alhabeb, M.; Hatter, C. B.; Anasori, B.; Man Hong, S.; Koo, C. M.; Gogotsi, Y. (2016 Sep. 9). “Electromagnetic interference shielding with 2D transition metal carbides (MXenes)”. Science. 353 (6304): 1137-1140. Bibcode:2016Sci...353.1137S. doi:10.1126/science.aag2421. ISSN 0036-8075. PMID 27609888.

Sheberla, Dennis; Sun, Lei; Blood-Forsythe, Martin A.; Er, Süleyman; Wade, Casey R.; Brozek, Carl K.; Aspuru-Guzik, Alán; Dincă, Mircea (2014). “High Electrical Conductivity in Ni3(2,3,6,7,10,11-hexaiminotriphenylene)2, a Semiconducting Metal—Organic Graphene Analogue”. Journal of the American Chemical Society. 136 (25): 8859-8862. doi:10.1021/ja502765n. PMID 24750124.

Shuck, Christopher E.; Sarycheva, Asia; Anayee, Mark; Levitt, Ariana; Zhu, Yuanzhe; Uzun, Simge; Balitskiy, Vitaliy; Zahorodna, Veronika; Gogotsi, Oleksiy; Gogotsi, Yury (March 2020). “Scalable Synthesis of Ti3C2Tx MXene”. Advanced Engineering Materials. 22 (3): 1901241. doi:10.1002/adem.201901241.

Sluiter, Marcel; Kawazoe, Yoshiyuki (2003). “Cluster expansion method for adsorption: Application to hydrogen chemisorption on graphene”. Physical Review B. 68 (8): 085410. Bibcode:2003PhRvB..68h5410S. doi:10.1103/PhysRevB.68.085410.

Sofo, Jorge O.; et al. (2007). “Graphene: A two-dimensional hydrocarbon”. Physical Review B. 75 (15): 153401-4. arXiv:cond-mat/0606704. Bibcode:2007PhRvB..75o3401S. doi:10.1103/PhysRevB.75.153401. S2CID 101537520.

Sung, S. H.; Schnitzer, N.; Brown, L.; Park, J.; Hoyden, R. (2019 Jun. 25). “Stacking, strain, and twist in 2D materials quantified by 3D electron diffraction”. Physical Review Materials. 3 (6): 064003. arXiv:1905.11354. Bibcode:2019PhRvM...3f4003S. doi:10.1103/PhysRevMaterials.3.064003. S2CID 166228311.

Takahashi, L.; Takahashi, K. (2015). “Low temperature pollutant trapping and dissociation over two-dimensional tin”. Physical Chemistry Chemical Physics. 17 (33): 21394-21396. Bibcode:2015PCCP...1721394T. doi:10.1039/C5CP03382A. PMID 26226204. Supporting Information

Thomas, Shibin; Smith, Danielle E.; Greenacre, Victoria K.; Noori, Yasir J.; Hector, Andrew L.; Groot, C. H. (Kees) de; Reid, Gillian; Bartlett, Philip N. (2020 Jun. 23). “Electrodeposition of MoS2 from Dichloromethane”. Journal of the Electrochemical Society. 167 (10): 106511. Bibcode:2020JElS..167j6511T. doi:10.1149/1945-7111/ab9c88. ISSN 1945-7111.

Tikhomirova, K.; Tantardini, C.; Sukhanova, E.; Popov, Z.; Evlashin, S.; Tarkhov, M.; Zhdanov, V.; Dudin, A.; Organov, A.; Kvashnin, D.; Kvashniv, A. (2020). “Exotic Two-Dimensional Structure: The First Case of Hexagonal NaCl”. The Journal of Physical Chemistry Letters. 11 (10): 3821-3827. doi:10.1021/acs.jpclett.0c00874. PMID 32330050.

Wang, Tanyuan; Zhuo, Junqiao; Du, Kuangzhou; Chen, Bingbo; Zhu, Zhiwei; Shao, Yuanhua; Li, Meixian (2014). “Electrochemically Fabricated Polypyrrole and MoSx Copolymer Films as a Highly Active Hydrogen Evolution Electrocatalyst”. Advanced Materials. 26 (22): 3761-3766. doi:10.1002/adma.201400265. ISSN 1521-4095. PMID 24638848.

Wang, Xuebin; Zhi, Chunyi; Weng, Qunhong; Bando, Yoshio; Golberg, Dmitri (2013 Jan. 1). “Boron Nitride Nanosheets: novel Syntheses and Applications in polymeric Composites”. Journal of Physics: Conference Series. 471 (1): 012003. Bibcode:2013JPhCS.471a2003W. doi:10.1088/1742-6596/471/1/012003.

Wang, Zifeng; Tang, Zijie; Xue, Qi; Huang, Yan; Huang, Yang; Zhu, Minshen; Pei, Zengxia; Li, Hongfei; Jiang, Hongbo (2016 Jun. 1). “Fabrication of Boron Nitride Nanosheets by Exfoliation”. The Chemical Record. 16 (3): 1204-1215. doi:10.1002/tcr.201500302. PMID 27062213.

Wu, Haihua; Yang, Rong; Song, Baomin; Han, Qiusen; Li, Jingying; Zhang, Ying; Fang, Yan; Tenne, Reshef; Wang, Chen (2011). “Biocompatible Inorganic Fullerene-Like Molybdenum Disulfide Nanoparticles Produced by Pulsed Laser Ablation in Water”. ACS Nano. 5 (2): 1276-1281. doi:10.1021/nn102941b. PMID 21230008.

Wu, Wei; Wang, Jin; Ercius, Peter; Wright, Nicomario; Leppert-Simenauer, Danielle; Burke, Robert; Dubey, Madan; Dongare, Avinash; Pettes, Michael (2018). “Giant Mechano-Optoelectronic Effect in an Atomically Thin Semiconductor”. Nano Letters. 18 (4): 2351-2357. Bibcode:2018NanoL..18.2351W. doi:10.1021/acs.nanolett.7b05229. OSTI 1432708. PMID 29558623.

Wu, Wenzhuo; Wang, Lei; Li, Yilei; Zhang, Fan; Lin, Long; Niu, Simiao; Chenet, Daniel; Zhang, Xian; Hao, Yufeng (2014 Oct. 23). “Piezoelectricity of single-atomic-layer MoS2 for energy conversion and piezotronics”. Nature. 514 (7523): 470-474. Bibcode:2014Natur.514..470W. doi:10.1038/nature13792. PMID 25317560. S2CID 4448528.

Xu, Yang; Cheng, Cheng; Du, Sichao; Yang, Jianyi; Yu, Bin; Luo, Jack; Yin, Wenyan; Li, Erping; Dong, Shurong; Ye, Peide; Duan, Xiangfeng (2016). “Contacts between Two- and Three-Dimensional Materials: Ohmic, Schottky, and p-n Heterojunctions”. ACS Nano. 10 (5): 4895-4919. doi:10.1021/acsnano.6b01842. PMID 27132492.

Yan, Rusen; Simpson, Jeffrey R.; Bertolazzi, Simone; Brivio, Jacopo; Watson, Michael; Wu, Xufei; Kis, Andras; Luo, Tengfei; Walker, Angela R. Hight (2014). “Thermal Conductivity of Monolayer Molybdenum Disulfide Obtained from Temperature-Dependent Raman Spectroscopy”. ACS Nano. 8 (1): 986-993. doi:10.1021/nn405826k. PMID 24377295.

Yin, Xi; Liu, Xinhong; Pan, Yung-Tin; Walsh, Kathleen A.; Yang, Hong (Nov. 4, 2014). “Hanoi Tower-like Multilayered Ultrathin Palladium Nanosheets”. Nano Letters. 14 (12): 7188-7194. Bibcode:2014NanoL..14.7188Y. doi:10.1021/n1503879a. PMID 25369350.

Yuhara, J.; Fujii, Y.; Isobe, N.; Nakatake, M.; Lede, X.; Rubio, A.; Le Lay, G. (2018). “Large Area Planar Stanene Epitaxially Grown on Ag(111)”. 2D Materials. 5 (2): 025002. Bibcode:2018TDM.....5b5002Y. doi:10.1088/2053-1583/aa9ea0.

Yuhara, J.; He, B.; Le Lay, G. (2019). “Graphene's Latest Cousin: Plumbene Epitaxial Growth on a “Nano WaterCube””. Advanced Materials. 31 (27): 1901017. doi:10.1002/adma.201901017. PMID 31074927.

Yuhara, J.; Schmid, M.; Varga, P. (2003). “A two-dimensional alloy of immiscible metals, The single and binary monolayer films of Pb and Sn on Rh(111)”. Phys. Rev. B. 67 (19): 195407. Bibcode:2003PhRvB..67s5407Y. doi:10.1103/PhysRevB.67.195407.

Yuhara, J.; Shimazu, H.; Ito, K.; Ohta, A.; Kurosawa, M.; Nakatake, M.; Le Lay, Guy (2018). “Germanene Epitaxial Growth by Segregation through Ag(111) Thin Films on Ge(111)”. ACS Nano. 12 (11): 11632-11637. doi:10.1021/acsnano.8b07006. PMID 30371060.

Yuhara, J.; Yokoyama, M.; Matsui, T. (2011). “Two-dimensional solid solution alloy of Bi-Pb binary films on Rh(111)”. J. Appl. Phys. 110 (7): 074314-074314-4. Bibcode:2011JAP...110g4314Y. doi:10.1063/1.3650883.

Zhang, S.; Yan, Z.; Li, Y.; Chen, Z.; Zeng, H. (2015). “Atomically Thin Arsenene and Antimonene: Semimetal-Semiconductor and Indirect-Direct Band-Gap Transitions”. Angew. Chem. Int. Ed. 54 (10): 3112-3115. doi:10.1002/anie.201411246. PMID 25564773.

Zhang, Z.; Yang, Y.; Gao, G.; Yakobson, B. I. (2 Sep. 2015). “Two-Dimensional Boron Monolayers Mediated by Metal Substrates”. Angewandte Chemie International Edition. 54 (44): 13022-13026. doi:10.1002/anie.201505425. PMID 26331848.

Zhi, Chunyi; Bando, Yoshio; Tang, Chengchun; Kuwahara, Hiroaki; Golberg, Dimitri (2009 Jul. 27). “Large-Scale Fabrication of Boron Nitride Nanosheets and Their Utilization in Polymeric Composites with Improved Thermal and Mechanical Properties”. Advanced Materials. 21 (28): 2889-2893. doi:10.1002/adma.200900323.

The use of electric fields to control wettability of a surface is called electrowetting. One application for electronically-controllable liquid contact angle is in variable focus lenses. See, e.g.:

U.S. Pat. Nos. 3,460,798; 3,536,592; 3,650,883; 3,924,876; 4,448,528; 4,922,135; 4,922,504; 5,037,434; 5,372,545; 5,717,453; 5,864,128; 5,886,332; 5,986,811; 6,014,259; 6,233,098; 6,288,846; 6,369,954; 6,437,920; 6,683,725; 6,909,555; 6,936,196; 6,965,480; 7,006,299; 7,167,313; 7,201,318; 7,221,514; 7,264,162; 7,298,559; 7,298,970; 7,310,080; 7,312,929; 7,339,575; 7,359,124; 7,369,321; 7,440,193; 7,443,596; 7,443,597; 7,460,309; 7,515,350; 7,545,575; 7,548,377; 7,570,434; 7,580,195; 7,589,822; 7,619,204; 7,645,628; 7,646,544; 7,672,059; 7,675,687; 7,688,509; 7,697,187; 7,701,642; 7,701,643; 7,702,660; 7,706,077; 7,729,057; 7,755,840; 7,755,841; 7,758,259; 7,767,069; 7,780,874; 7,791,814; 7,808,717; 7,813,047; 7,859,640; 7,898,742; 7,903,158; 7,905,407; 7,905,414; 7,940,467; 7,952,809; 7,982,964; 8,004,766; 8,027,096; 8,038,066; 8,045,136; 8,054,465; 8,059,260; 8,072,486; 8,072,578; 8,072,688; 8,107,056; 8,111,464; 8,111,466; 8,148,706; 8,164,598; 8,169,589; 8,169,713; 8,191,142; 8,213,022; 8,226,009; 8,231,249; 8,233,221; 8,238,033; 8,245,935; 8,245,936; 8,282,004; 8,292,798; 8,296,292; 8,342,207; 8,366,330; 8,390,934; 8,400,558; 8,400,593; 8,416,504; 8,460,376; 8,467,133; 8,472,120; 8,472,122; 8,477,425; 8,482,859; 8,488,246; 8,505,822; 8,514,474; 8,520,314; 8,545,555; 8,547,528; 8,553,197; 8,553,203; 8,570,659; 8,576,379; 8,605,361; 8,649,102; 8,668,338; 8,687,282; 8,699,142; 8,705,002; 8,711,328; 8,724,079; 8,729,515; 8,734,033; 8,736,808; 8,773,744; 8,783,874; 8,797,653; 8,811,781; 8,814,691; 8,816,360; 8,828,484; 8,837,054; 8,858,772; 8,861,092; 8,864,035; 8,873,152; 8,899,761; 8,964,298; 8,982,445; 9,056,039; 9,074,168; 9,097,890; 9,097,891; 9,128,281; 9,129,295; 9,134,464; 9,134,534; 9,164,202; 9,169,575; 9,182,591; 9,182,596; 9,207,367; 9,223,134; 9,223,230; 9,223,231; 9,229,227; 9,239,636; 9,285,589; 9,289,122; 9,298,108; 9,304,305; 9,304,319; 9,310,628; 9,312,130; 9,323,325; 9,329,689; 9,341,843; 9,348,238; 9,366,862; 9,414,908; 9,500,782; 9,630,183; 9,632,431; 9,665,016; 9,684,248; 9,699,370; 9,717,400; 9,739,911; 9,759,917; 9,857,692; 9,864,186; 9,875,406; 9,904,075; 9,939,630; RE39874; 10,007,196; 10,055,889; 10,078,160; 10,139,737; 10,160,022; 10,180,572; 10,209,534; 10,216,009; 10,222,708; 10,232,374; 10,234,447; 10,236,170; 10,239,057; 10,239,058; 10,240,187; 10,245,588; 10,248,001; 10,252,265; 10,252,907; 10,258,282; 10,260,095; 10,266,892; 10,267,726; 10,268,036; 10,268,888; 10,272,427; 10,273,535; 10,277,386; 10,280,456; 10,288,254; 10,294,567; 10,295,724; 10,295,819; 10,296,819; 10,297,572; 10,300,371; 10,308,931; 10,309,924; 10,309,926; 10,309,927; 10,309,947; 10,315,911; 10,324,041; 10,325,951; 10,329,544; 10,330,919; 10,330,920; 10,334,724; 10,335,791; 10,338,056; 10,343,161; 10,344,326; 10,350,594; 10,351,905; 10,352,983; 10,357,772; 10,357,773; 10,368,847; 10,369,565; 10,369,567; 10,369,570; 10,370,705; 10,371,872; 10,371,936; 10,376,878; 10,376,886; 10,377,538; 10,378,010; 10,379,112; 10,383,219; 10,384,204; 10,398,343; 10,398,832; 10,401,537; 10,403,204; 10,403,645; 10,403,760; 10,403,834; 10,406,522; 10,406,792; 10,407,676; 10,408,788; 10,409,089; 10,410,571; 10,410,962; 10,411,013; 10,413,912; 10,415,086; 10,416,082; 10,416,117; 10,421,070; 10,421,072; 10,423,254; 10,424,676; 10,427,156; 10,429,381; 10,429,629; 10,429,648; 10,429,715; 10,431,164; 10,434,507; 10,434,847; 10,436,726; 10,436,781; 10,437,123; 10,438,815; 10,438,982; 10,439,068; 10,439,074; 10,439,166; 10,441,357; 10,442,172; 10,442,774; 10,446,671; 10,447,347; 10,448,531; 10,450,598; 10,450,604; 10,450,605; 10,451,912; 10,452,218; 10,453,381; 10,453,401; 10,453,865; 10,456,209; 10,457,935; 10,459,485; 10,460,647; 10,460,984; 10,461,421; 10,464,062; 10,464,067; 10,466,243; 10,466,468; 10,466,565; 10,467,926; 10,468,625; 10,472,669; 10,473,668; 10,474,000; 10,477,192; 10,477,354; 10,480,022; 10,481,120; 10,481,388; 10,481,638; 10,482,743; 10,485,118; 10,488,362; 10,488,424; 10,488,887; 10,488,969; 10,490,116; 10,490,142; 10,493,456; 10,494,667; 10,494,670; 10,494,672; 10,495,656; 10,495,869; 10,495,941; 10,496,203; 10,497,082; 10,498,029; 10,501,739; 10,502,707; 10,503,040; 10,503,307; 10,504,204; 10,504,971; 10,509,220; 10,510,806; 10,513,630; 10,513,729; 10,514,137; 10,514,360; 10,514,809; 10,515,609; 10,516,118; 10,518,231; 10,518,241; 10,518,264; 10,519,439; 10,520,500; 10,520,786; 10,521,032; 10,522,397; 10,522,574; 10,522,691; 10,525,472; 10,526,218; 10,527,157; 10,527,626; 10,528,079; 10,528,166; 10,528,198; 10,529,138; 10,529,864; 10,532,211; 10,532,358; 10,533,998; 10,534,457; 10,535,325; 10,535,742; 10,535,837; 10,539,787; 10,539,829; 10,540,029; 10,541,279; 10,541,375; 10,543,466; 10,543,485; 10,543,516; 10,545,139; 10,545,622; 10,546,545; 10,546,958; 10,548,852; 10,549,273; 10,549,274; 10,551,382; 10,551,713; 10,553,690; 10,556,233; 10,558,031; 10,559,249; 10,559,341; 10,559,443; 10,559,499; 10,559,612; 10,559,760; 10,562,028; 10,563,240; 10,564,211; 10,564,767; 10,566,355; 10,567,152; 10,567,635; 10,569,271; 10,570,447; 10,571,772; 10,572,006; 10,572,211; 10,573,222; 10,573,261; 10,573,667; 10,573,761; 10,576,470; 10,576,471; 10,578,630; 10,579,181; 10,583,641; 10,585,090; 10,585,091; 10,586,495; 10,586,954; 10,589,248; 10,589,273; 10,590,461; 10,591,488; 10,591,783; 10,592,193; 10,596,572; 10,603,662; 10,603,988; 10,606,066; 10,607,989; 10,608,015; 10,609,404; 10,611,627; 10,612,079; 10,612,091; 10,613,586; 10,613,667; 10,619,196; 10,620,428; 10,620,429; 10,620,456; 10,620,490; 10,620,755; 10,621,956; 10,622,425; 10,622,426; 10,625,220; 10,627,866; 10,628,103; 10,629,004; 10,629,113; 10,629,831; 10,629,857; 10,632,467; 10,632,468; 10,633,644; 10,633,652; 10,634,899; 10,635,135; 10,635,137; 10,639,597; 10,642,314; 10,643,392; 10,644,039; 10,646,871; 10,647,981; 10,648,897; 10,650,766; 10,651,203; 10,653,332; 10,656,147; 10,656,407; 10,656,408; 10,658,433; 10,658,520; 10,661,278; 10,661,306; 10,662,467; 10,662,468; 10,668,471; 10,669,558; 10,669,592; 10,671,204; 10,672,601; 10,672,771; 10,673,280; 10,675,625; 10,675,626; 10,677,793; 10,678,089; 10,678,375; 10,679,545; 10,686,027; 10,686,157; 10,690,628; 10,693,013; 10,693,097; 10,694,399; 10,695,723; 10,695,737; 10,695,761; 10,695,762; 10,695,763; 10,697,007; 10,697,986; 10,699,650; 10,700,212; 10,700,427; 10,704,080; 10,705,082; 10,705,404; 10,707,238; 10,707,239; 10,707,578; 10,709,384; 10,710,078; 10,710,120; 10,712,344; 10,714,502; 10,718,936; 10,719,284; 10,720,662; 10,723,988; 10,724,981; 10,724,988; 10,725,020; 10,727,355; 10,730,048; 10,731,199; 10,733,946; 10,734,089; 10,734,529; 10,738,354; 10,739,307; 10,739,931; 10,741,587; 10,745,741; 10,745,762; 10,747,345; 10,747,372; 10,749,112; 10,751,715; 10,753,904; 10,753,986; 10,755,667; 10,756,311; 10,757,491; 10,757,808; 10,760,162; 10,761,664; 10,763,373; 10,766,033; 10,768,085; 10,768,345; 10,768,446; 10,770,910; 10,771,662; 10,771,705; 10,774,372; 10,774,374; 10,774,376; 10,775,505; 10,776,065; 10,777,685; 10,780,413; 10,780,727; 10,782,526; 10,782,734; 10,784,284; 10,787,701; 10,787,705; 10,788,452; 10,792,658; 10,792,660; 10,792,661; 10,792,807; 10,794,925; 10,795,476; 10,797,179; 10,799,865; 10,799,892; 10,800,652; 10,801,885; 10,802,196; 10,802,297; 10,802,368; 10,802,626; 10,803,815; 10,804,487; 10,807,093; 10,808,279; 10,808,282; 10,809,254; 10,809,784; 10,810,951; 10,811,482; 10,811,503; 10,811,539; 10,811,540; 10,812,992; 10,814,298; 10,814,324; 10,816,453; 10,816,456; 10,816,838; 10,816,862; 10,816,939; 10,817,087; 10,817,120; 10,821,438; 10,821,439; 10,822,245; 10,824,269; 10,824,284; 10,826,609; 10,829,728; 10,829,759; 10,832,404; 10,834,822; 10,835,900; 10,837,061; 10,837,883; 10,838,116; 10,839,766; 10,839,948; 10,843,922; 10,847,500; 10,848,079; 10,850,002; 10,850,272; 10,852,540; 10,852,838; 10,852,870; 10,857,537; 10,859,492; 10,859,813; 10,859,857; 10,860,100; 10,861,733; 10,880,953; 10,881,367; 10,881,674; 10,881,742; 10,882,053; 20010036669; 20010036674; 20020043463; 20020080920; 20020150683; 20020159156; 20020168671; 20020172969; 20020182747; 20030006140; 20030012483; 20030013203; 20030047688; 20030080085; 20030082081; 20030096405; 20030138819; 20030138941; 20030164295; 20030183525; 20030206351; 20030224528; 20030226604; 20030227100; 20040007377; 20040009530; 20040031688; 20040042721; 20040053403; 20040055536; 20040055891; 20040058450; 20040091392; 20040105525; 20040136876; 20040141237; 20040142491; 20040191127; 20040211659; 20040231987; 20040231990; 20050002112; 20050022895; 20050039661; 20050045238; 20050045539; 20050048581; 20050056569; 20050058773; 20050069458; 20050088754; 20050106742; 20050123243; 20050151709; 20050177223; 20050178286; 20050199720; 20050199725; 20050231810; 20050233198; 20050235869; 20050264531; 20050269743; 20050271548; 20050281682; 20060040375; 20060042950; 20060045501; 20060054503; 20060063207; 20060073687; 20060079728; 20060083473; 20060096078; 20060097155; 20060102477; 20060108012; 20060108209; 20060108224; 20060114296; 20060118782; 20060132542; 20060151754; 20060152817; 20060153745; 20060158632; 20060158729; 20060164490; 20060165565; 20060186048; 20060194331; 20060201795; 20060221458; 20060226013; 20060231398; 20060254933; 20070006926; 20070013804; 20070023292; 20070030573; 20070031097; 20070034270; 20070037172; 20070037294; 20070039832; 20070039866; 20070045117; 20070047095; 20070052781; 20070062583; 20070063048; 20070064212; 20070065946; 20070068573; 20070081133; 20070091455; 20070103580; 20070105239; 20070121213; 20070127006; 20070127102; 20070133079; 20070138016; 20070141593; 20070146894; 20070147816; 20070156021; 20070170059; 20070177276; 20070179200; 20070179201; 20070183934; 20070187242; 20070188882; 20070189998; 20070189999; 20070193864; 20070207061; 20070207064; 20070207487; 20070211235; 20070216893; 20070217956; 20070219623; 20070221484; 20070222922; 20070225800; 20070229754; 20070241068; 20070242105; 20070242111; 20070243110; 20070243634; 20070247607; 20070247724; 20070263293; 20070267294; 20070275415; 20070281304; 20070286773; 20080003142; 20080006535; 20080014589; 20080019015; 20080023330; 20080029372; 20080038810; 20080044893; 20080044914; 20080047701; 20080050834; 20080053205; 20080060995; 20080062499; 20080076673; 20080088551; 20080093220; 20080094074; 20080097143; 20080100905; 20080105549; 20080107542; 20080110753; 20080112059; 20080117231; 20080123182; 20080128397; 20080135411; 20080144186; 20080144187; 20080151214; 20080151257; 20080151267; 20080156983; 20080159586; 20080169195; 20080169197; 20080170982; 20080185057; 20080185296; 20080185339; 20080210558; 20080212161; 20080213853; 20080215705; 20080217822; 20080218873; 20080225378; 20080230386; 20080231963; 20080236473; 20080245430; 20080247052; 20080247920; 20080248463; 20080248499; 20080248590; 20080251383; 20080257438; 20080259463; 20080264506; 20080264797; 20080274513; 20080277477; 20080277480; 20080281471; 20080283414; 20080290294; 20080295456; 20080295687; 20080297030; 20080297880; 20080297911; 20080302431; 20080306589; 20080317982; 20080318324; 20090002806; 20090014394; 20090023610; 20090028755; 20090042319; 20090046082; 20090050601; 20090052049; 20090073569; 20090078326; 20090085894; 20090086331; 20090107907; 20090109513; 20090126373; 20090127113; 20090127123; 20090134027; 20090141334; 20090142564; 20090147167; 20090147371; 20090147372; 20090148348; 20090155902; 20090166426; 20090166543; 20090168010; 20090169819; 20090170186; 20090174765; 20090179171; 20090181864; 20090188794; 20090191334; 20090192044; 20090195120; 20090201588; 20090203063; 20090207622; 20090215192; 20090217508; 20090220948; 20090220974; 20090221073; 20090231564; 20090232509; 20090237575; 20090260988; 20090261241; 20090263834; 20090263870; 20090266516; 20090267167; 20090268303; 20090269243; 20090274580; 20090280251; 20090280475; 20090280476; 20090283407; 20090288710; 20090289213; 20090291433; 20090296067; 20090296069; 20090304944; 20090311713; 20090314366; 20100000620; 20100000866; 20100009430; 20100025207; 20100025242; 20100025250; 20100028920; 20100032293; 20100041046; 20100041086; 20100044216; 20100045995; 20100051460; 20100062508; 20100067847; 20100068764; 20100068780; 20100072078; 20100072414; 20100081578; 20100087012; 20100087633; 20100095762; 20100096266; 20100101960; 20100104459; 20100105866; 20100108765; 20100111854; 20100111855; 20100112286; 20100114348; 20100116640; 20100118307; 20100119557; 20100120130; 20100121466; 20100123007; 20100126860; 20100130369; 20100134779; 20100137163; 20100140093; 20100143243; 20100143963; 20100147955; 20100151439; 20100152651; 20100152880; 20100157413; 20100163109; 20100163576; 20100165429; 20100166612; 20100168900; 20100173134; 20100176200; 20100177386; 20100181195; 20100182584; 20100185174; 20100186524; 20100187728; 20100190263; 20100194408; 20100200094; 20100208194; 20100208195; 20100208328; 20100209916; 20100210029; 20100213074; 20100215961; 20100215968; 20100221713; 20100233021; 20100236927; 20100236928; 20100236929; 20100236930; 20100254021; 20100258441; 20100260626; 20100270156; 20100277742; 20100279321; 20100279374; 20100282608; 20100282609; 20100284091; 20100285573; 20100290049; 20100290130; 20100291578; 20100295987; 20100296094; 20100302646; 20100307917; 20100307922; 20100309560; 20100311599; 20100314448; 20100316531; 20100320088; 20100321478; 20100323388; 20100323405; 20100331205; 20110002043; 20110003279; 20110005931; 20110007161; 20110019170; 20110019186; 20110023970; 20110023973; 20110025998; 20110033315; 20110033887; 20110042220; 20110046013; 20110048543; 20110048951; 20110051104; 20110051105; 20110058149; 20110070440; 20110075257; 20110076692; 20110076734; 20110083964; 20110084014; 20110085131; 20110085219; 20110085243; 20110086377; 20110090494; 20110091864; 20110091989; 20110095201; 20110096276; 20110097763; 20110100823; 20110102735; 20110102738; 20110104025; 20110104725; 20110104747; 20110104816; 20110107822; 20110109823; 20110114190; 20110114490; 20110118132; 20110122504; 20110124524; 20110138838; 20110141539; 20110147215; 20110147216; 20110149292; 20110149377; 20110149407; 20110150765; 20110155565; 20110170105; 20110171748; 20110177962; 20110180571; 20110186433; 20110187917; 20110188127; 20110195258; 20110203930; 20110209998; 20110211262; 20110213499; 20110213664; 20110214082; 20110215040; 20110217738; 20110220504; 20110220505; 20110220510; 20110221656; 20110221657; 20110221658; 20110221659; 20110221668; 20110221669; 20110221670; 20110221671; 20110221672; 20110221793; 20110221896; 20110221897; 20110222745; 20110222841; 20110225536; 20110227812; 20110227813; 20110227820; 20110231757; 20110234757; 20110240471; 20110247934; 20110247938; 20110249232; 20110249266; 20110253909; 20110255175; 20110256542; 20110256577; 20110257494; 20110266151; 20110268151; 20110272575; 20110272598; 20110272644; 20110275143; 20110284110; 20110286896; 20110287977; 20110290647; 20110297547; 20110299171; 20110303531; 20110303541; 20110303542; 20110304987; 20110311980; 20110312622; 20110312841; 20120000777; 20120006681; 20120006684; 20120007608; 20120007778; 20120013990; 20120018306; 20120019529; 20120024708; 20120026596; 20120028843; 20120037400; 20120040102; 20120041553; 20120044299; 20120045798; 20120048882; 20120056081; 20120060937; 20120061587; 20120062445; 20120064534; 20120068801; 20120069236; 20120073993; 20120075168; 20120075389; 20120081777; 20120083046; 20120085645; 20120086454; 20120086949; 20120087014; 20120087015; 20120091003; 20120097257; 20120100304; 20120105839; 20120105952; 20120105955; 20120106238; 20120111129; 20120111506; 20120112070; 20120113525; 20120126143; 20120126449; 20120127062; 20120127582; 20120136147; 20120138121; 20120138158; 20120138462; 20120145890; 20120148451; 20120149128; 20120152858; 20120154886; 20120154925; 20120160680; 20120164633; 20120165238; 20120168309; 20120171682; 20120174650; 20120192991; 20120194418; 20120194419; 20120194420; 20120194492; 20120194549; 20120194550; 20120194551; 20120194552; 20120194553; 20120194563; 20120199655; 20120200488; 20120200499; 20120200601; 20120200817; 20120200939; 20120204577; 20120206322; 20120206323; 20120206334; 20120206335; 20120206485; 20120211109; 20120212398; 20120212399; 20120212400; 20120212406; 20120212414; 20120212484; 20120212499; 20120212713; 20120218172; 20120218301; 20120220497; 20120231226; 20120235538; 20120235883; 20120235884; 20120235885; 20120235886; 20120235887; 20120235900; 20120236030; 20120236031; 20120236299; 20120242678; 20120242697; 20120242698; 20120243093; 20120243106; 20120248195; 20120248229; 20120249797; 20120261264; 20120264646; 20120264932; 20120268712; 20120268804; 20120269481; 20120274894; 20120275030; 20120276334; 20120279298; 20120283140; 20120287512; 20120291870; 20120295340; 20120298205; 20120298235; 20120301564; 20120305400; 20120308771; 20120310339; 20120322162; 20120325665; 20130004371; 20130011332; 20130016515; 20130017544; 20130018611; 20130020202; 20130026040; 20130029347; 20130033476; 20130033593; 20130037149; 20130038944; 20130042893; 20130044045; 20130050432; 20130050807; 20130059366; 20130059761; 20130064713; 20130065017; 20130068622; 20130070204; 20130077178; 20130078164; 20130090248; 20130092539; 20130092543; 20130095508; 20130096035; 20130098771; 20130099256; 20130101753; 20130104981; 20130105318; 20130105319; 20130105709; 20130107144; 20130109596; 20130112559; 20130114120; 20130115703; 20130116128; 20130118900; 20130118901; 20130121005; 20130121884; 20130126358; 20130127980; 20130128336; 20130130936; 20130133338; 20130133710; 20130134039; 20130134040; 20130138359; 20130143312; 20130146115; 20130146455; 20130146461; 20130149710; 20130149740; 20130153416; 20130161193; 20130164742; 20130165328; 20130167958; 20130168250; 20130171546; 20130175169; 20130176628; 20130178374; 20130178968; 20130183210; 20130183659; 20130183717; 20130186447; 20130192270; 20130201316; 20130203606; 20130206597; 20130210639; 20130213812; 20130215492; 20130217103; 20130217113; 20130217583; 20130220810; 20130225450; 20130225452; 20130229668; 20130230875; 20130233425; 20130233712; 20130244906; 20130252246; 20130252262; 20130252847; 20130255789; 20130259464; 20130264010; 20130269751; 20130270114; 20130271153; 20130277218; 20130278631; 20130284956; 20130288254; 20130288292; 20130293246; 20130296192; 20130303394; 20130306479; 20130306480; 20130308088; 20130314303; 20130319861; 20130321929; 20130329200; 20130329201; 20130329208; 20130333762; 20130335805; 20140001202; 20140002789; 20140002790; 20140005066; 20140008222; 20140008307; 20140014517; 20140015548; 20140016087; 20140016089; 20140017687; 20140018441; 20140023697; 20140037858; 20140043547; 20140049806; 20140049808; 20140054174; 20140057339; 20140057363; 20140063054; 20140063055; 20140069812; 20140071653; 20140073514; 20140076436; 20140080203; 20140080717; 20140081396; 20140084216; 20140085573; 20140085709; 20140087955; 20140090981; 20140098010; 20140102571; 20140102900; 20140120604; 20140124037; 20140134623; 20140140891; 20140141409; 20140141460; 20140144518; 20140151232; 20140161686; 20140166484; 20140168022; 20140174926; 20140174933; 20140183044; 20140185127; 20140190830; 20140190832; 20140192218; 20140193807; 20140194305; 20140197028; 20140197304; 20140200511; 20140202863; 20140203169; 20140205761; 20140208832; 20140212627; 20140216559; 20140216932; 20140220673; 20140224654; 20140226127; 20140231257; 20140231259; 20140234873; 20140235457; 20140239628; 20140240586; 20140242662; 20140246319; 20140248621; 20140249057; 20140251477; 20140251807; 20140251811; 20140253870; 20140256595; 20140262783; 20140273191; 20140287423; 20140287937; 20140287966; 20140291152; 20140295421; 20140295572; 20140299472; 20140302430; 20140302490; 20140302580; 20140305510; 20140322706; 20140323317; 20140329307; 20140330244; 20140330256; 20140330257; 20140332380; 20140332410; 20140335069; 20140339082; 20140339318; 20140342373; 20140343387; 20140353157; 20140374259; 20140378339; 20150001078; 20150004684; 20150008123; 20150008128; 20150008129; 20150011404; 20150014170; 20150017737; 20150021182; 20150021189; 20150024326; 20150024415; 20150027889; 20150029229; 20150034485; 20150038344; 20150049296; 20150050664; 20150053562; 20150060284; 20150062528; 20150063605; 20150065360; 20150065393; 20150068903; 20150072132; 20150072900; 20150075985; 20150075986; 20150075988; 20150075989; 20150075991; 20150093816; 20150096890; 20150101938; 20150104798; 20150107995; 20150110689; 20150111237; 20150112164; 20150112165; 20150118696; 20150118761; 20150122651; 20150124310; 20150124311; 20150130996; 20150131161; 20150136606; 20150144489; 20150147573; 20150148238; 20150148549; 20150151298; 20150151307; 20150158028; 20150164589; 20150165436; 20150165763; 20150174574; 20150174577; 20150174578; 20150184219; 20150192865; 20150198528; 20150203416; 20150204817; 20150205272; 20150212043; 20150218619; 20150232942; 20150238959; 20150238975; 20150241689; 20150248021; 20150248022; 20150253284; 20150253487; 20150253588; 20150258520; 20150259754; 20150260311; 20150260983; 20150267242; 20150268235; 20150285792; 20150290613; 20150293347; 20150298124; 20150298125; 20150301204; 20150306598; 20150306599; 20150308018; 20150309316; 20150314293; 20150323496; 20150323555; 20150330597; 20150330943; 20150336098; 20150338372; 20150338373; 20150338637; 20150344876; 20150352544; 20150352547; 20150352552; 20150353351; 20150376421; 20150378267; 20150378434; 20160003791; 20160011429; 20160016170; 20160016172; 20160016403; 20160018633; 20160018745; 20160020017; 20160030951; 20160033415; 20160038940; 20160051992; 20160053253; 20160054483; 20160061596; 20160068901; 20160074863; 20160074915; 20160082437; 20160083872; 20160084796; 20160085240; 20160086785; 20160089668; 20160091489; 20160096172; 20160096174; 20160097047; 20160097087; 20160098498; 20160101420; 20160103252; 20160107951; 20160108432; 20160108433; 20160109338; 20160114320; 20160115436; 20160116427; 20160116438; 20160121326; 20160122792; 20160125780; 20160129437; 20160129445; 20160130640; 20160139069; 20160144332; 20160144333; 20160146823; 20160147067; 20160151784; 20160158748; 20160158752; 20160158757; 20160160259; 20160161343; 20160161768; 20160161861; 20160167051; 20160168633; 20160168715; 20160171686; 20160175839; 20160175859; 20160177375; 20160184823; 20160186166; 20160186267; 20160187034; 20160187642; 20160187654; 20160189432; 20160193407; 20160193604; 20160194697; 20160194702; 20160195492; 20160199832; 20160199837; 20160201699; 20160202173; 20160207044; 20160209648; 20160215318; 20160216231; 20160217327; 20160222427; 20160228893; 20160231268; 20160237489; 20160246072; 20160246073; 20160251778; 20160257918; 20160258020; 20160259171; 20160265047; 20160266105; 20160271623; 20160272954; 20160273032; 20160273133; 20160274351; 20160274380; 20160281135; 20160281154; 20160281158; 20160291023; 20160296929; 20160296934; 20160296935; 20160299101; 20160299170; 20160303562; 20160305906; 20160310949; 20160312165; 20160312275; 20160312387; 20160313571; 20160318021; 20160318023; 20160320378; 20160325276; 20160326520; 20160327515; 20160338347; 20160339424; 20160341637; 20160349088; 20160367946; 20160367986; 20160367989; 20160369266; 20160370266; 20160370317; 20160371434; 20160375440; 20170001866; 20170003282; 20170003454; 20170007998; 20170010205; 20170010456; 20170018626; 20170021366; 20170031078; 20170036207; 20170036210; 20170043343; 20170044439; 20170044525; 20170047497; 20170052146; 20170053908; 20170056887; 20170058410; 20170059514; 20170059523; 20170067047; 20170073729; 20170074871; 20170075043; 20170078400; 20170086676; 20170092564; 20170095184; 20170096750; 20170101674; 20170102016; 20170102344; 20170102345; 20170102358; 20170102391; 20170113224; 20170113231; 20170120240; 20170120249; 20170121675; 20170121756; 20170122870; 20170128947; 20170130258; 20170131279; 20170137290; 20170138901; 20170141793; 20170152081; 20170152550; 20170159105; 20170165667; 20170168566; 20170173580; 20170173584; 20170176773; 20170184533; 20170184583; 20170186666; 20170189169; 20170209865; 20170211127; 20170212109; 20170218416; 20170218442; 20170218455; 20170224280; 20170227771; 20170232189; 20170234628; 20170235036; 20170235126; 20170239659; 20170241949; 20170245788; 20170250063; 20170260521; 20170266653; 20170276679; 20170276963; 20170285343; 20170292124; 20170304785; 20170307486; 20170307606; 20170315078; 20170320059; 20170326546; 20170326551; 20170326552; 20170327377; 20170331899; 20170336637; 20170337337; 20170343254; 20170344114; 20170354969; 20170355595; 20170357086; 20170363465; 20170363906; 20170363930; 20170365224; 20170365234; 20170365648; 20170365693; 20170367190; 20170369927; 20170370836; 20170371182; 20170371190; 20170373093; 20170373249; 20180001286; 20180002725; 20180003947; 20180004047; 20180005566; 20180005567; 20180005588; 20180005600; 20180006061; 20180006272; 20180007343; 20180011361; 20180011447; 20180011569; 20180012536; 20180012538; 20180013004; 20180013080; 20180015437; 20180017818; 20180018053; 20180018565; 20180018752; 20180018918; 20180019289; 20180019425; 20180023045; 20180023112; 20180024067; 20180024096; 20180024680; 20180025918; 20180026037; 20180026140; 20180026218; 20180026228; 20180031927; 20180031943; 20180033362; 20180033399; 20180033696; 20180033833; 20180033978; 20180034912; 20180037690; 20180038699; 20180039084; 20180039117; 20180040274; 20180040642; 20180040647; 20180045965; 20180046214; 20180047609; 20180047946; 20180051310; 20180051327; 20180051332; 20180052355; 20180052535; 20180053459; 20180053917; 20180054897; 20180056288; 20180056586; 20180056636; 20180059056; 20180059721; 20180059841; 20180061344; 20180061638; 20180061639; 20180061995; 20180064216; 20180067352; 20180067373; 20180068609; 20180069064; 20180071730; 20180072033; 20180074013; 20180074553; 20180074554; 20180076332; 20180076394; 20180076401; 20180077408; 20180078669; 20180080020; 20180081227; 20180081283; 20180081465; 20180082118; 20180083074; 20180084232; 20180085756; 20180085859; 20180090618; 20180095067; 20180095100; 20180095502; 20180095559; 20180097040; 20180099275; 20180099282; 20180104693; 20180104694; 20180104695; 20180105874; 20180106759; 20180108760; 20180109835; 20180110975; 20180111126; 20180113297; 20180113545; 20180113547; 20180113564; 20180113566; 20180114506; 20180117399; 20180117402; 20180117403; 20180117404; 20180117405; 20180117406; 20180117407; 20180117408; 20180117409; 20180117410; 20180117411; 20180117412; 20180117413; 20180117441; 20180117442; 20180117443; 20180120174; 20180120335; 20180120977; 20180121013; 20180122889; 20180124181; 20180126380; 20180126381; 20180126768; 20180128778; 20180129074; 20180129084; 20180130861; 20180135011; 20180136114; 20180136532; 20180136758; 20180136766; 20180138201; 20180138416; 20180138440; 20180142378; 20180145277; 20180147576; 20180148328; 20180148756; 20180149785; 20180151593; 20180151630; 20180151742; 20180151852; 20180157144; 20180158885; 20180159067; 20180161769; 20180161782; 20180164577; 20180166041; 20180169905; 20180172222; 20180172594; 20180174647; 20180174862; 20180175322; 20180178174; 20180178217; 20180179589; 20180180169; 20180180951; 20180180960; 20180181165; 20180182822; 20180182899; 20180182901; 20180184520; 20180185846; 20180185848; 20180188230; 20180188849; 20180190826; 20180193840; 20180195100; 20180196326; 20180196629; 20180197888; 20180207640; 20180207641; 20180210600; 20180211620; 20180214137; 20180214873; 20180217076; 20180217402; 20180217800; 20180223345; 20180224961; 20180224992; 20180226034; 20180231542; 20180231555; 20180237696; 20180237850; 20180239181; 20180240421; 20180241241; 20180243743; 20180245150; 20180245993; 20180246058; 20180246609; 20180247958; 20180250672; 20180252925; 20180257070; 20180257075; 20180259482; 20180264427; 20180267333; 20180268953; 20180272295; 20180272296; 20180272350; 20180273933; 20180274026; 20180275088; 20180275785; 20180276843; 20180277533; 20180278693; 20180278694; 20180280897; 20180280979; 20180282805; 20180282806; 20180284423; 20180284424; 20180284556; 20180291414; 20180291415; 20180291416; 20180291417; 20180291418; 20180292642; 20180297027; 20180298318; 20180299458; 20180299958; 20180303667; 20180305681; 20180307346; 20180307451; 20180308866; 20180311636; 20180311666; 20180315750; 20180318068; 20180318826; 20180327837; 20180329367; 20180329576; 20180331229; 20180333724; 20180335679; 20180337218; 20180337289; 20180339923; 20180342176; 20180343304; 20180344221; 20180344222; 20180344223; 20180344224; 20180345279; 20180345288; 20180350997; 20180355350; 20180355407; 20180361381; 20180362969; 20180364487; 20180369814; 20180372739; 20180375940; 20190002283; 20190002973; 20190004576; 20190009275; 20190011443; 20190011612; 20190011691; 20190014677; 20190015831; 20190015832; 20190016578; 20190016587; 20190017962; 20190022655; 20190024227; 20190024262; 20190024648; 20190025177; 20190025587; 20190027501; 20190030531; 20190030537; 20190030539; 20190033573; 20190033913; 20190035935; 20190039072; 20190049434; 20190049715; 20190051727; 20190059795; 20190060900; 20190060907; 20190060923; 20190062803; 20190062809; 20190064038; 20190064503; 20190069989; 20190070602; 20190070603; 20190072901; 20190074278; 20190075243; 20190079317; 20190081271; 20190082999; 20190083983; 20190085375; 20190085387; 20190086399; 20190086815; 20190091690; 20190094226; 20190094521; 20190094981; 20190096979; 20190098090; 20190102136; 20190106570; 20190107709; 20190107765; 20190107876; 20190109904; 20190110778; 20190111433; 20190112503; 20190112730; 20190113430; 20190113661; 20190115406; 20190115474; 20190115478; 20190120830; 20190121162; 20190121215; 20190126279; 20190126280; 20190129541; 20190134630; 20190137380; 20190137437; 20190137667; 20190138060; 20190139515; 20190139688; 20190139941; 20190142311; 20190143291; 20190143340; 20190144913; 20190144914; 20190148013; 20190148428; 20190151850; 20190152771; 20190153524; 20190154678; 20190163433; 20190164517; 20190165179; 20190168223; 20190169684; 20190169700; 20190172196; 20190176153; 20190177790; 20190177791; 20190179149; 20190181273; 20190183397; 20190184397; 20190184694; 20190185915; 20190187034; 20190187360; 20190187455; 20190187535; 20190188471; 20190194734; 20190194735; 20190194736; 20190194751; 20190196632; 20190197264; 20190201890; 20190201895; 20190201902; 20190203275; 20190205077; 20190206899; 20190209910; 20190212233; 20190212601; 20190212603; 20190214435; 20190214608; 20190216184; 20190217289; 20190217297; 20190217300; 20190217301; 20190220128; 20190221670; 20190221674; 20190223289; 20190223301; 20190224670; 20190224678; 20190230373; 20190232279; 20190233572; 20190233573; 20190234961; 20190235335; 20190237120; 20190237586; 20190240665; 20190241951; 20190241965; 20190243488; 20190244573; 20190244574; 20190245146; 20190250312; 20190255564; 20190256910; 20190256924; 20190256928; 20190262829; 20190266955; 20190275516; 20190276820; 20190278141; 20190278409; 20190280019; 20190281222; 20190283026; 20190288092; 20190293598; 20190293920; 20190294278; 20190299212; 20190300873; 20190302835; 20190302915; 20190304763; 20190310456; 20190310490; 20190314820; 20190321819; 20190324026; 20190326367; 20190326420; 20190329258; 20190329259; 20190330701; 20190331638; 20190331639; 20190333569; 20190333969; 20190337690; 20190338230; 20190338258; 20190338331; 20190338405; 20190339743; 20190341460; 20190342564; 20190342606; 20190344272; 20190345488; 20190348011; 20190348448; 20190348481; 20190348538; 20190351411; 20190351418; 20190352687; 20190352708; 20190353973; 20190353975; 20190354241; 20190355751; 20190355758; 20190358604; 20190358623; 20190360041; 20190361501; 20190362683; 20190362814; 20190366333; 20190366344; 20190366811; 20190369044; 20190369048; 20190369068; 20190371249; 20190374108; 20190374944; 20190376120; 20190376902; 20190376963; 20190377445; 20190378237; 20190378918; 20190380871; 20190381506; 20190384079; 20190384111; 20190384963; 20190388890; 20190388894; 20190388895; 20190390250; 20190391427; 20190393079; 20200001063; 20200001300; 20200001302; 20200007232; 20200010827; 20200012089; 20200013893; 20200016594; 20200016597; 20200017813; 20200018992; 20200020885; 20200024539; 20200026064; 20200026144; 20200026375; 20200030767; 20200030794; 20200030802; 20200033991; 20200034105; 20200035728; 20200038857; 20200041445; 20200043382; 20200048606; 20200055053; 20200055378; 20200057059; 20200057421; 20200061620; 20200061621; 20200064298; 20200064337; 20200066405; 20200070161; 20200070171; 20200071487; 20200073100; 20200074940; 20200078788; 20200089035; 20200089368; 20200098830; 20200098997; 20200099002; 20200100372; 20200101456; 20200101460; 20200103720; 20200104001; 20200108387; 20200108396; 20200110123; 20200110481; 20200110484; 20200111790; 20200114135; 20200114355; 20200114356; 20200114357; 20200114359; 20200114360; 20200114361; 20200114362; 20200114363; 20200114575; 20200115671; 20200115680; 20200116668; 20200116750; 20200117068; 20200117069; 20200117241; 20200117304; 20200117305; 20200118480; 20200119053; 20200122135; 20200124840; 20200125192; 20200126501; 20200126961; 20200133421; 20200135265; 20200138996; 20200139362; 20200141931; 20200142180; 20200142563; 20200144424; 20200145600; 20200147548; 20200147609; 20200147613; 20200149099; 20200150508; 20200150602; 20200150826; 20200152671; 20200152710; 20200152897; 20200155750; 20200156015; 20200156065; 20200157619; 20200157684; 20200159083; 20200161435; 20200165480; 20200166509; 20200166676; 20200166742; 20200168850; 20200169683; 20200171483; 20200171499; 20200171500; 20200171501; 20200172898; 20200174005; 20200175931; 20200175932; 20200176686; 20200179927; 20200179933; 20200179935; 20200181604; 20200181695; 20200181710; 20200183186; 20200185420; 20200185665; 20200191739; 20200191796; 20200192089; 20200193301; 20200193927; 20200194590; 20200197927; 20200197941; 20200201102; 20200202789; 20200206740; 20200208614; 20200209231; 20200209250; 20200210024; 20200212150; 20200215547; 20200216892; 20200218485; 20200219467; 20200222899; 20200225232; 20200230601; 20200233250; 20200235323; 20200241282; 20200241283; 20200241667; 20200243569; 20200243626; 20200249230; 20200249456; 20200254451; 20200254456; 20200254458; 20200255893; 20200256843; 20200257337; 20200257402; 20200258914; 20200261911; 20200263227; 20200263246; 20200264418; 20200265650; 20200266250; 20200267874; 20200269243; 20200269248; 20200269249; 20200274929; 20200275561; 20200276579; 20200278721; 20200280607; 20200285337; 20200285339; 20200290009; 20200290046; 20200290050; 20200292810; 20200292998; 20200293150; 20200294401; 20200295006; 20200295195; 20200295222; 20200296825; 20200298231; 20200298238; 20200299351; 20200301229; 20200302889; 20200308682; 20200310106; 20200310215; 20200312889; 20200312943; 20200313115; 20200316230; 20200316605; 20200316606; 20200319135; 20200324290; 20200325514; 20200326753; 20200328375; 20200330994; 20200332317; 20200332346; 20200332353; 20200333901; 20200335529; 20200340854; 20200342825; 20200343277; 20200343750; 20200347840; 20200348505; 20200348576; 20200349898; 20200356166; 20200357309; 20200357925; 20200358186; 20200358188; 20200360876; 20200363321; 20200363568; 20200363681; 20200368747; 20200368778; 20200373435; 20200377861; 20200377956; 20200379058; 20200380933; 20200382730; 20200384470; and 20200384472.

Ashraf, Ali., Yanbin Wu, Michael Cai Wang, Keong Yong, Tao Sun, Yuhang Jing, Richard T. Haasch, Narayana R. Aluru, and SungWoo Nam. “Doping-induced tunable wettability and adhesion of graphene.” Nano letters 16, no. 7 (2016): 4708-4712.

Bedworth, Peter V., and Jacob Louis Swett. “Methods for releasing graphene from a metal substrate by electrowetting.” U.S. Pat. No. 9,169,575, issued Oct. 27, 2015.

Bratko, Dusan, Christopher D. Daub, Kevin Leung, and Alenka Luzar. “Effect of field direction on electrowetting in a nanopore.” Journal of the American Chemical Society 129, no. 9 (2007): 2504-2510.

Bruijn, D. S. “Electrowetting-controlled. diode-like behavior of suspended graphene membranes.” Master's thesis, University of Twente, 2018.

Carpenter, Katherine, and Vaibhav Bahadur. “Electrofreezing of water droplets under electrowetting fields.” Langmuir 31, no. 7 (2015): 2243-2248,

Celebi, Alper Tuna, Murat Barisik, and Ali Beskok. “Electric field controlled transport of water in graphene nano-channels.” The Journal of Chemical Physics 147, no. 16 (2017): 164311.

Chen, Longquan, and Elmar Bonaccurso. “Electrowetting—From statics to dynamics.” Advances in colloid andinterface science 210 (2014): 2-12.

Cheng, Mark Ming-Cheng, Xuebin Tan, and Zhixian Zhou. “Electrowetting on dielectric using graphene.” U.S. Pat. No. 9,630,183, issued Apr. 25, 2017.

Cui, Wenbin, Hongbin Ma, Bohan Tian, Yulong Ji, and Fengmin Su. “Electrowetting on a multi-walled carbon nanotube membrane with different droplet sizes in an electric field.” Journal of materials science 51, no. 8 (2016): 4031-4036.

Dollekamp, Edwin, Pantelis Bampoulis, Daniël P. Faasen, Harold J W Zandvliet, and E. Stefan Kooij. “Charge Induced Dynamics of Water in a Graphene—Mica Slit. Pore.” Langmuir 33, no. 43 (2017): 11977-11985.

Eaker, Collin B., Ishan D. Joshipura, Logan R. Maxwell, Jason Heikenfeld, and Michael D. Dickey. “Electrowetting without external voltage using paint-on electrodes.” Lab on a Chip 17, no. 6 (2017): 1069-1075.

Goniszewski, Stefan, M. Adabi, O. Shaforost, S. M. Hanham, L. Hao, and N. Klein. “Correlation of p-doping in CVD Grapheme with Substrate Surface Charges.” Scientific reports 6, no. 1 (2016): 1-9.

Han, Zhaojun, Bengkang lay, Cherming Tan, Maziar Shakerzadeh, and Kostya Ostrikov. “Electrowetting control of Cassie-to-Wenzel transitions in superhydrophohic carbon nanotube-based nanocomposites.” ACS nano 3, no. 10 (2009): 3031-3036.

He, Xiaodong, Wenbin Qiang, Chao Du, Qunfeng Shao, Xiaoping Zhang, and Youquan Deng. “Modification of lubricant infused porous surface for low-voltage reversible electrowetting.” Journal of Materials Chemistry A 5, no. 36 (2017): 19159-19167,

Jurado, L. Andres, and Rosa M. Espinosa-Marzal. “Insight into the electrical double layer of an ionic liquid on grapheme.” Scientific reports 7, no. 1 (2017): 1-12.

Khan, Afzal, Mohammad Rezwan Habib, Rishi Ranjan Kumar, Sk Masiul Islam, V. Arivazhagan, Muhammad Salman, Deren Yang, and Xuegong Yu. “Wetting behaviors and applications of metal-catalyzed CVD grown graphene.” Journal of Materials Chemistry A 6, no. 45 (2018): 22437-22464.

Kim, Jae-Hun, Jae-Hyoung Lee, Ali Mirzaei, Hyoun Woo Kim, Boon Teoh Tan, Ping Wu, and Sang Sub Kim. “Electrowetting-on-dielectric characteristics of ZnO nanorods.” Scientific reports 10, no. 1 (2020): 1-12.

Liu, Yuan, Yurui Gao, and Xiao Cheng Zeng. “Rich topologies of monolayer ices via unconventional electrowetting.” Nanoscale Horizons 5, no. 3 (2020): 514-522.

Liu, Then, Tong Cui, GuoZhu Li, and Frank Endres. “Interfacial Nanostructure and Asymmetric Electrowetting of Ionic Liquids.” Langmuir 33, no. 38 (2017): 9539-9547.

Lomax, Deborah J., Pallav Kant, Aled T. Williams, Ho lie V. Patten, Yuqin Zou, Anne Juel, and Robert A W Dryfe. “Ultra-low voltage electrowetting using graphite surfaces.” Soft Matter 12, no. 42 (2016): 8798-8804.

Ostrowski, Joseph H J, and Joel D. Eaves. “The tunable hydrophobic effect on electrically doped graphene.” The Journal of Physical Chemistry B 118, no. 2 (2014): 530-536.

Ounnunkad, Kontad, Hollie V. Patten, Matěj Velický, Anna K. Farquhar, Paula A. Brooksby, Alison J. Downard, and Robert A W Dryfe. “Electrowetting on conductors: anatomy of the phenomenon.” Faraday Discussions 199 (2017): 49-61.

Perry, Guillaume:, Yannick Coffinier, Rabah Boukherroub, and Vincent Thomy. “Investigation of the anti-biofouling properties of graphene oxide aqueous solutions by electrowetting characterization.” Journal of Materials Chemistry A 1, no. 39 (2013): 12355-12360.

Pu, Jibin, Shanhong Wan, Zhihin Lu, Guang-an Zhang, Liping Wang, Xiaoqian Zhang, and QunJi Xue. “Controlled water adhesion and electrowetting of conducting hydrophobic graphene/carbon nanotubes composite films on engineering materials.” Journal of Materials Chemistry A 1, no. 4 (2013): 1254-1260.

Shahini, Ali, Hai Jin, Zhixian Zhou, Yang Zhao, Pai-Yen Chen, Jing Hua, and Mark Ming-Cheng Cheng. “Toward individually tunable compound eyes with transparent graphene electrode.” Bioinspiration & Biomimetics 12, no. 4 (2017): 046002.

Shahini, Ali, Jinjun Xia, Zhixian Zhou, Yang Zhao, and Mark Ming-Cheng Cheng. “Versatile miniature tunable liquid lenses using transparent graphene electrodes.” Langmuir 32, no. 6 (2016): 1658-1665.

Shen, Hsien-Hua, Lung-Yuan Chung, and Da-Deng Yao. “Improving the dielectric properties of an electrowetting-on-dielectric microfluidic device with a low-pressure chemical vapor deposited Si3N4 dielectric layer.” Biomicrofluidics 9, no. 2 (2015): 022403.

Singh, Eklavya, Abhay V. Thomas, Rahul Mukherjee, Xi Mi, Farzad Houshmand, Yoav Peles, Yunfeng Shi, and Nikhil Koratkar. “Graphene drape minimizes the pinning and hysteresis of water drops on nanotextured rough surfaces.” ACS nano 7, no. 4 (2013): 3512-3521.

Song, Fenhong, Bing Ma, Eng Fan, Qicheng Chen, and Ben Q. Li. “Molecular Dynamics Simulation on the Electrowetting Behaviors of the Ionic Liquid [BMIM][BF4] on a Solid Substrate.” Langmuir 35, no. 30 (2019): 9753-9760.

Supekar, Omkar D., Mo Zohrabi, Juliet T. Gopinath, and Victor M. Bright. “Enhanced response time of electrowetting lenses with shaped input voltage functions.” Langmuir 33, no. 19 (2017): 4863-4869.

Sur, Aritra, Yi Lu, Carmen Pascente, Paul Ruchhoeft, and Dong Liu. “Pool boiling heat transfer enhancement with electrowetting.” International Journal of Heat and Mass Transfer 120 (2018): 202-217.

Tabassian, Rassoul, Jung-Hwan Oh, Sooyeun Kim, Donggyu Kim, Seunghwa Ryu, Seung-Min Cho, Nikhil Koratkar, and II-Kwon Oh. “Graphene-coated meshes for electroactive flow control devices utilizing two antagonistic functions of repellency and permeability.” Nature communications 7, no. 1 (2016): 1-9.

Taherian Tabasi, Fereshte, and Nico van der Vegt. “Asymmetric behavior in electrowetting of electrolyte solutions on graphene at the nanoscale: A molecular dynamics simulation.” APS 2015 (2015): Y16-013.

Taherian, Fereshte, Frédéric Leroy, and Nico F A van der Vegt. “Interfacial Tension Does Not Drive Asymmetric Nanoscale Electrowetting on Graphene.” Langmuir 31, no. 16 (2015): 4686-4695.

Taherian, Fereshte, Frédéric Leroy, Lars-Oliver Heim, Elmar Bonaccurso, and Nico F A van der Vegt. “Mechanism for asymmetric nanoscale electrowetting of an ionic liquid on graphene.” Langmuir 32, no. 1 (2016): 140-150.

Tan, X. B., J. Yang, P. Zeng, E. G. R. Kim, C. Huard, and M. M. C. Cheng. “Electrowetting on flexible, transparent and conducting single-layer graphene.” In 2012 IEEE 25th International Conference on Micro Electra Mechanical Systems (MEMS), pp. 1037-1040. IEEE, 2012.

Tan, X. B., P. Zeng, W. W. Yi, and M. M. C. Cheng. “Graphene based digital microfluidics.” In 2013 IEEE 26th International Conference on Micro Electro Mechanical Systems (MEMS), pp. 1195-1198. IEEE, 2013.

Tan, Xuebin, Zhixian Zhou, and Mark Ming-Cheng Cheng. “Electrowetting on dielectric experiments using graphene.” Nanotechnology 23, no. 37 (2012): 375501.

Tan, Xuebin. “The Application Of Graphene Films In Biosensing And Electrowetting.” (2014).

Tang, Biao, Wan Shao, Jan Groenewold, Hao Li, Yancong Feng, Xuezhu Xu, Lingling Shui, Jitesh Barman, and Guofu Zhou. “Transition of interfacial capacitors in electrowetting on a graphite surface by ion intercalation.” Physical Chemistry Chemical Physics 21, no. 48 (2019): 26284-26291.

Teng, Peicheng, Dongliang Tian, Haiyan Fu, and Shutao Wang. “Recent progress of electrowetting for droplet manipulation: from wetting to superwetting systems.” Materials Chemistry Frontiers 4, no. 1 (2020): 140-154.

Ugsornrat, Kessararat, Patiya Pasakon, Chanpen Karuwan, Chakrit Sriprachuabwong, Thitima Maturos, Tawee Pogfay, Anurat Wisitsoraat, and Adisorn Tuantranont. “Low-cost and disposable electrowetting-on-dielectric lab on a chip with an integrated electrochemical detector fabricated by screen-printing process.” IEEE Sensors Journal 19, no. 19 (2019): 8597-8604.

Wang, Ying, and Ya-Pu Zhao. “Electrowetting on curved surfaces.” Soft Matter 8, no. 9 (2012): 2599-2606.

Williams, Camille. “Enhancing Liquid Lens Using Electroweaing And Graphene Material.” Research Journal 2015: 83.

Yang, Fan, Raymond A. Shaw, Colin W. Gurganus, Su Kong Chong, and Yoke Khin Yap. “Ice nucleation at the contact line triggered by transient electrowetting fields.” Applied Physics Letters 107, no. 26 (2015): 264101.

Yuan, Quanzi, and Ya-Pu Zhao. “Precursor film in dynamic wetting, electrowetting, and electro-elasto-capillarity.” Physical Review Letters 104, no. 24 (2010): 246101.

Zeng, Jian, Shiwei Zhang, Kairui Tang, Gong Chen, Wei Yuan, and Yong Tang. “3-D manipulation of a single nano-droplet on graphene with an electrowetting driving scheme: critical condition and tunability.” Nanoscale 10, no. 34 (2018): 16079-16086.

Zhang, Guohui, Marc Walker, and Patrick R. Unwin. “Low-voltage voltammetric electrowetting of graphite surfaces by ion intercalation/deintercalation.” Langmuir 32, no. 30 (2016): 7476-7484.

Zhang, Zhong-qiang, Hong-fei Ye, Guang-gui Cheng, Yong-gang Zheng, Jian-ning Ding, and Zhi-yong Ling. “Boundary slip and interfacial friction properties of confined-water flow on graphene under electrowetting.” Carbon 70 (2014): 322.

Zhao, Ya-Pu, and Ying Wang. “Fundamentals and applications of electrowetting.” Reviews of Adhesion and Adhesives 1, no. 1 (2013): 114-174.

### SUMMARY OF THE INVENTION

The present described invention allows for electrically tunable surface properties.

The present technology employs an applied electric field to tune adsorption, wetting, and adhesive behavior on a 2D material outer surface by way of an applied electric field between a conductive gate below the surface of the object and the 2D material outer layer. The 2D material outer layer and the gate layer are separated by a dielectric layer. Both the energetics and kinetics of adsorption on the surface can be tuned by the applied electric field. Likewise, the adsorption, wetting and adhesion of solids to the surface can also be changed via this applied electric field.

The mechanism of operation of the technology is shown in FIGS. 1A-1D, wherein a voltage between the gate and 2D material outer layer (e.g., graphene) builds up either positive or negative charge (electrical doping) that modifies the interaction with adsorbed molecules. One potential of this is that the gate voltage can align/orient adsorbed molecules on the surface of the 2D material. This effect works with physiosorption, like the case of water on graphene, but can also work with chemisorption, albeit with less easy reversibility (e.g., may require heating for desorption).

As shown in FIGS. 1A-1D, the gate voltage is hypothesized to modify the energetics and orientation of water adsorption in a back-gate GFET. When the gate-graphene voltage is less than the charge neutral point, V_{GS}-V_{CNP}<0, the Fermi level shifts down, electrically p-doping the graphene. This should make adsorption that chemically n-dopes graphene favored, which leads to water molecules adsorbing with the OH legs upward. Inversely, when V_{GS}-V_{CNP}>0, the Fermi level shifts up, electrically n-doping the graphene. This thereby should make adsorption that chemically p-dopes graphene favored, like water molecules adsorbing with the OH legs downward.

The effect on the substrate can modify the adsorption of an absorbent, including on a 2D material or film (e.g., metal organic framework, zeolite) on the surface (FIG. 11E). The outer gate voltage can be at ground during operation, with the gate voltage referenced to ground, so no voltage difference with the surrounding fluid is necessary.

This technology can also align molecules underneath the 2D material, like surfactants (FIG. 11A, 11B), liquid crystals (FIG. 11C, 11D), to change the adsorption and surface properties on top via adsorption and wetting transparency. This invention can also change the interaction of an adsorbent underneath the 2D material or on top of the 2D material by way of the applied electric field (FIG. 11E).

This technology is distinct from what is currently described as “electrowetting”, where a voltage is applied between the surface and a drop of water. According to the present technology, the voltage potential that tunes the surface property is applied between a layer internal to the surface and the surface. The potential of the outer surface can be at ground with respect to the fluid and still show tunable surface properties with a changing gate-to-2D material voltage. Moreover, this technology can work with gases, while electrowetting only works for liquids.

Sato et al and Baldwin et al found the doping of graphene was effected by the gate voltage.^{58,59} The present technology is distinguished, because these works never considered how this effect could be used to modify the surface properties for purposes beyond engineering the graphene field effect transistor electrical properties. They did not discuss how this technology could modify wetting in any way, or adsorption for technological purposes beyond electrically doping the graphene. Prior work by Hong et al and Ashraf et al looked at electrical and chemical doping of graphene, respectively on the contact angle. These works did not consider the effect on adsorption. Moreover, they did not develop a method to get large changes in the contact angle and it was not reversible. These references did not consider adding a material onto the surface, like a surfactant, self-assembled monolayer, liquid crystal, metal organic framework, to widen the range of contact angles to a useful range. Chiu et al demonstrated that water doping graphene can be used to store information, but did not consider applications beyond memory, like wetting control or adsorption control.⁶⁰

In the case of water adsorbing on a graphene film, an electric field applied between the graphene and a backgate metallization with a separating dielectric, the electric field direction will control the orientation of water molecule adsorption. Gate voltages electrically dope the graphene more, which will lead to faster adsorption kinetics and greater adsorption quantities compared to adsorption at the point of minimum electrical doping, the so-called charge neutral point. These concepts are described primarily with graphene but encompass more broadly many types of 2D materials (materials that are only a few atomic layers thick).

The present technology enables time-varying control of adsorption and wetting behavior on a free surface, for applications like enhanced condensation rates and self-cleaning.^{61-63,5,64} While the literature has extensively reported on electrowetting and begun to explore chemical and electrical-doping on wetting,^{65,66} there have been almost no studies on the effect of electrical-doping of 2D materials on adsorption. The newly discovered phenomenon of electro-doping control of adsorption works through the change in the DOS-induced coulombic and van der Waals energetic changes of the 2D material changing the energetics of adsorption. This phenomenon is completely distinct from electrowetting, which works by the strength of the electric field going through a droplet, while electroadsorption works via electrical doping of the 2D materia1.^{67,68,69}

Electric-doping control of adsorption, i.e., electroadsorption, is very different from electrowetting in the underlying physics and the device limitations. Electrowetting can change the contact angle on a droplet by the electric field fringing near the contact line applies a force that pulls the contact line outwards, lower droplet contact angles with increasing electric fields. Another important distinction is that electrowetting requires a voltage to be applied between the surface and somewhere inside the droplet to be controlled. By contrast, elctroadsorption can operate on a free surface with that free surface at any voltage, as the electrical doping is done via a back-gate electrode.

The present technology can reversibly change surfaces from hydrophilic to hydrophilic. This, in turn, could permit enhanced condensation heat transfer and ambient water harvesting. The enhanced condensation would operate via periodic alternation between film-wise condensation (when hydrophilic) to increase condensate collection and dropwise condensation (when hydrophobic) to optimally clear the adsorbed water phase.⁷⁰ This could allow more compact two-phase heat exchangers and lower the inefficiencies in thermal power generation condensers. This technology may also enable-self-cleaning of surfaces. This technology may also enable steering of droplets through gradients in the electric-doping. The technology further provides advanced options for water harvesting and adsorption heating/cooling systems.

The adsorption energy may change monotonically with the applied electric field.

The electroadsorption effect may be reversed by shifting the electric-doping.

The electroadsorption effect might be augmented via the help of surfactant coating.

The adsorption change with electric doping of a 2D material may be correlated with the dipole moment for physiosorbed molecules. 1D and 0D materials may also be correspondingly employed.

Water condensation on a surface begins with the adsorption of water vapor molecules onto the surface. This is followed by the creation of hydrogen bonds among water molecules, which coalesce to form droplets and finally wet the surface. Adsorption and Wettability play an important role in applications like ambient air water harvesting^{1,2} and condensation-evaporation in thermal power generation^{3,4}, still reversibly controlling adsorption has yet to be demonstrated. Many of the methods to modify wetting use permanent surface functionalization ^{5,6}. In contrast, making surfaces with the ability to reversibly change the wetting in real time could open up pathways toward creating new surface cleaning methods ^{7,8}, more energy efficient adsorption refrigeration^{9,10} and water harvesting systems¹¹.

The 2D nature of graphene along with its stability at different temperature ranges allows for graphene to be used as a coating to modify bulk surface phenomena like adsorption⁵⁶ and wetting⁵⁷. The ability to change the carrier type (electrons and holes) and concentration in graphene via an applied electric field makes graphene an ideal candidate for creating surface coatings with selective adsorption properties.

The water adsorption behavior of graphene can be tuned by electrically shifting the Fermi level, and hence the energetics of adsorption. In order to test this hypothesis, water adsorption onto back-gated graphene field effect transistors (GFETs) was studied as a function of electrical-doping via a quartz crystal microbalance (QCM) and current-voltage (IV) curve measurements. The measured IV curves and isotherms showed that water adsorption onto graphene depends on the doping of graphene and increases with IVGS-VCNPI. Whether graphene is n- or p-doped due to water vapor adsorption depends on the polarity of the gate voltage. For electrically n-doped graphene, water molecules tend to adsorb onto graphene with the hydrogens facing graphene and move the Fermi level lower (p-doping). On the other hand, if the gate voltage induces p-doping, water molecules will adsorb with the oxygen facing graphene and move the Fermi level higher (n-doping). The adsorption isotherms showed higher uptakes for electrically doped than non-electrically doped graphene. Not only do larger gate voltages increase the water adsorption, they accelerated the adsorption process as well. These findings could be used to tune the hydrophilicity/hydrophobicity of a surface.

The effect of the substrate on graphene wetting has remained controversial. Several groups have conducted experiments that both support and refute the graphene transparency hypothesis. Most experimental studies on graphene wetting transparency used water contact angle measurements, which has repeatability challenges due to the hysteresis of advancing and receding contact angles in addition to sensitivity to airborne contaminants. In contrast, the adsorption isotherms of graphene supported by gold, platinum, and aluminum substrates was measured in prior studies by the inventors. From the adsorption isotherms measured at two temperatures, the heat of adsorption is extracted versus uptake and substrate. Additionally, the excess interfacial free energy for each substrate is calculated to compare the wettability of the surfaces. Similar control experiments were also performed on the metal substrates. By studying the adsorption of water molecules on supported graphene, it was shown that the interaction of graphene with water molecules is affected by the supporting substrate in the three metals studied. The adsorption isotherms of graphene supported by Pt, Au, and Al had relatively close uptakes to the bare metals (slightly lower uptake with a similar isotherm shape).

The graphene coated surfaces have a slightly less energetic adsorption than the bare metal, which agrees with the trend in wetting studies that observe a slight increase in the contact angle of the graphene coated surface compared to the bare substrates. This adsorption transparency is attributed to the nature of (van der Waals) forces involved in water adsorption on these metals and the extreme thinness of graphene. This technique is also available for consideration of the adsorption of other 2D materials and supporting substrates.

The adsorption energy of a gas onto 2D materials with respect to an applied electric field may be studied by measuring the adsorption isotherms at two relatively close temperatures for each applied voltage. Using the Clausius-Clapeyron equation, the average adsorption energy between the two temperatures may be determined.

The ability to reverse the electroadsorption effect by shifting the applied gate voltage can be analyzed by use of an Environmental Scanning Electron Microscopy (ESEM) to visualize the adsorption of water vapor. GFET samples are mounted in two different orientations: horizontal and vertical. At constant vapor pressures, the gate voltage is changed to see if desorption take place.

The ability to augment the eletroadsorption effect can be analyzed using a surfactant coating on graphene. Contact angle measurements are used to determine if changing the gate voltage in a surfactant coated 2D material can lead to changing the hydrophilicity/hydrophobicity of the surface.

The relationship of the dipole moment physiosorbed molecule absorption to changes in electric doping of a 2D material may also be analyzed.

The substrate roughness may be a significant factor. The surface roughness may be modified via chemical etching and mechanical roughening.¹⁴⁵ Roughness may increase the wetting because of the Wenzel relation for wetting liquids.¹⁴⁶ This additional roughness may improve the mechanical interfacial strength.¹⁴⁷ Prior literature has reported that roughness reduces the interfacial conductance because there are multiple scattering events at the interface that impede thermal transport.^{148,149} Therefore, an important tradeoff may occur at the interface between mechanical strength versus enhanced heat transfer that our research will elucidate.

The technology also embodies a 2D material upon which can be coated an additional material. That additional material can be a film of surfactant that contains a hydrophobic end and hydrophilic end, so that the applied gate voltage can change the wetting properties to water. One way is to coat a thin layer of surfactant. These surfactants can be nonionic (including Alkyl polyglycoside, Cetomacrogol 1000, Cetostearyl alcohol, Cetyl alcohol, Cocamide DEA, Cocamide MEA, Decyl glucoside, Decyl polyglucose, Glycerol monostearate,IGEPAL CA-630, Isoceteth-20, Lauryl glucoside, Maltoside, Monolaurin, Mycosubtilin, Narrow-range ethoxylate, Nonidet P-40, Nonoxynol-9, Nonoxynols, NP-40, Octaethylene glycol monododecyl ether, N-Octyl beta-D-thioglucopyranoside, Octyl glucoside, Oleyl alcohol, PEG-10 sunflower glycerides, Pentaethylene glycol monododecyl ether, Polidocanol,Poloxamer, Poloxamer 407, Polyethoxylated tallow amine, Polyglycerol polyricinoleate, Polysorbate, Polysorbate 20, Polysorbate 80, Sorbitan, Sorbitan monolaurate, Sorbitan monostearate, Sorbitan tristearate, Stearyl alcohol, Surfactin, Triton X-100, Tween 80), anionic (including 2-Acrylamido-2-methylpropane sulfonic acid, Alkylbenzene sulfonates, Ammonium lauryl sulfate, Ammonium perfluorononanoate, Chlorosulfolipid, Docusate, Disodium cocoamphodiacetate, Magnesium laureth sulfate, MBAS assay, Perfluorobutanesulfonic acid, Perfluorodecanoic acid, Perfluorononanoic acid, Perfluorooctanesulfonic acid, Perfluorooctanoic acid, Phospholipid, Potassium lauryl sulfate, Soap, Soap substitute, Sodium alkyl sulfate, Sodium dodecyl sulfate, Sodium laurate, Sodium laureth sulfate, Sodium lauroyl sarcosinate, Sodium myreth sulfate, Sodium nonanoyloxybenzenesulfonate, Sodium pareth sulfate, Sodium stearate, Sodium sulfosuccinate esters, Sulfolipid), cationic (including Behentrimonium chloride,Benzalkonium chloride, Benzethonium chloride, Benzododecinium bromide, Bronidox, Carbethopendecinium bromide, Cetalkonium chloride, Cetrimonium bromide, Cetrimonium chloride, Cetylpyridinium chloride, Didecyldimethylammonium chloride, Dimethyldioctadecylammonium bromide, Dimethyldioctadecylammonium chloride, Dioleoyl-3-trimethylammonium propane, Domiphen bromide, Lauryl methyl gluceth-10 hydroxypropyl dimonium chloride, Octenidine dihydrochloride, Olaflur, N-Oleyl-1,3-propanediamine, Pahutoxin, Stearalkonium chloride, Tetramethylammonium hydroxide, Thonzonium bromide) or amphoteric (including sultaines CHAPS (3-[(3-cholamidopropyl)dimethylammonio]-1-propanesulfonate), cocamidopropyl hydroxysultaine, cocamidopropyl betaine, phospholipids phosphatidylserine, phosphatidylethanolamine, phosphatidylcholine, sphingomyelins, Lauryldimethylamine oxide, myristamine oxide).

The gate voltage changes whether the hydrophillic or hydrophobic end of the surfactant molecule is creating a free surface, which enables modification of the surface wetting properties. Liquid crystal thin films with variable end groups that change outer wettability depending on the orientation is another embodiment (including lyotropic types, metallotropic types, biological types, mineral types, thermotropic types, MBBA, cholesteric liquid crystal, cholesteryl benzoate, cholesteryl nonanoate, cholesteryl oleyl carbonate). Another way is to bond a self-assembled monolayer to the surface, though many may not have large effects if they are strongly adhered to the surface.

An additional material could alternatively be a nanoporous material, like metal organic framework or zeolite that is deposited underneath a porous 2D material. The technology also embodies applications that have pores through the 2D material-dielectric-backgate. In certain embodiments, the system functions as a voltage controlled nanoporous membrane (FIG. 11E). The applied voltage could tune the transport behavior through this kind of sieve.

In other embodiments this technology could also produce selective filters or adsorbers or adsorbent catalytic surfaces (FIG. 12D). By changing the potential on a membrane that contains a conductive gate layer, an insulator, and a 2D material adjacent to an adsorbent, the applied voltage can tune adsorption isotherms, selectivity and kinetics. The adsorbents applied on the outer surface include metal organic frameworks (COMOC-2, COMOC-4, Cu₃(BTC)₂, CuBTC, DUT-5, HKUST-1, MIL-47, MOF-5, MOF-199, MOF-253, NOTT-101, NOTT-202, TUDMOF-1, Zeolitic imidazolate framework, MOF-74, MOF-101, MOF-177, MOF-235, IRMOF-16, UiO-66, UiO-67, UiO-68, MIL-53, MIL-53(Al)-NH2, MIL-88A, MIL-88-Fe, MIL-88B-4CH3, MIL-100-Fe, MIL-101, LIC-1, ZIF-8, ZIF-90, CPL-2, F-MOF-1, MOP-1), zeolites (faujasite, linde type A, silver-exchanged zeolite Na, zeolite Y, zeolite 13X), silica gel (type A, type B, type C, silica alumina gel), especially adsorbents that can be made in very thin films/monolayers on the surface. The electric field near the surface of the 2D material could help to strain the adsorbent and change the charge distribution inside the adsorbent, change adsorption performance.

This electrically controlled wetting technology has implications to reducing fog on windows (including windows for sensors like LIDAR and cameras), mirrors in buildings and vehicles, ice on airplane wings, and condensation heat transfer found in HVAC and power plants. It also has many potential applications to phase change heat transfer, for instance by tuning condensation from filmwise to dropwise to clear droplets for heat transfer applications (FIG. 12C). Applications to space include reducing fogging internal to cabins along cold walls, or dehumidfying cabin air for reuse.

With a computer-controlled region selective wettability control, many novel applications are possible (FIG. 12D). For instance, applications like wiper-less water clearing from windows and wings are possible. By having an array of backgate contacts that tune the surface energy of different regions separately, a gradient in wetting properties can be achieved spatially that enables steering of droplets over the surface. The device would function analogous to a display except instead of controlling the brightness of a pixel, the backgate voltage controls the energy of wetting and adsorption. There can be active or passive control.

In one embodiment, the electric field on each pixel is controlled to enable a front of changing surface energy to move across the surface. The motion the hydrophobic/hydrophilic boundary across the surface can push water droplets away from the hydrophobic region towards the hydrophilic region. These waves can be controlled to invisibly wipe a windshield without any physically moving object. For applications that require transparency, like a windshield, the window should have a transparent conductor backgate, insulator and 2D material. For applications requiring transparency, transparent conductors, like indium oxide or graphene, could serve as a backgate.

The dielectric could be spray-deposited glass and the top gate can be a 2D material or graphene with surfactant. The surfactant underneath the glass would have its orientation set by the electric field between the 2D material and the gate, which would set whether the hydrophilic or hydrophobic endgroup faces towards the 2D material. The adsorption and wetting on top of the graphene will be strongly influenced by the contact angle underneath the graphene, due to wetting and contact angle transparency.

Alternate embodiments, may also have surfactant below the surface and on top of the surface, to provide more robust covering of the 2D material, where the orientation of the surfactant on top of the graphene will be set by the orientation of the surfactant below the graphene.

This technology can also enable the motion of droplets for various applications in the medical, chemical and pharmaceutical field. Another water or ice shedding mode could operate by applying an oscillatory electric field, such that droplets alternate from being more wetting to more non-wetting, generating vibrations in the droplets that if tuned can resonate and help release them from a surface, especially when the application with airflow over the surface, like a vehicle exterior, and allow them to move along a surface with less force required. Similar effects also apply to the prevention of condensation and to ice shedding. These techniques to remove droplets can also serve to more rapidly shed droplets in condensation heat transfer systems.

Applications of this technology to ambient water harvesting, where water vapor in air is condensed out on a cold surface, also exist. During ambient water harvesting using collection on a cold surface, you want droplets to form and then to be quickly shed. In this application a time-changing surface wetting could be very helpful, as a hydrophilic surface would be beneficial for the initial condensate formation, while the hydrophobic surface would be beneficial for getting droplets to roll off the surface to open new spaces for new droplets to condense (FIG. 12B). In one embodiment, the surface can initially be hydrophilic for condensation to form, and then switch to hydrophobic, so droplets can roll off more easily (FIG. 12C), that could help improve the speed of water production. Similar applications exist in condensation heat transfer.

The surface could also change wettability such that at some point the surface is superhydrophobic or omniphobic. In some embodiments, this could be achieved through incorporating roughness or surface texturing necessary for superhydrophobic or omniphobic properties, but allow the surface wetting on this texturing to be modified, so that way the surface wetting could be altered to more hydrophilic.

In certain embodiments the gate underlayer and/or the 2D material can be designed such that it has two contacts, so that a gradient of gate voltages is applied to a surface between the two contacts (FIG. 12A). The benefit of this would be a smooth gradient in surface properties between the two gate contacts. If this gradient is desired, a high resistance gate conductor may be desired to avoid large currents and heating from the applied voltage.

Embodiments may also want to incorporate sensing, in which case, the outer 2D layer can have source and drain contacts, so the conductance of the 2D layer can be sensed. The conductance can be used to sense the level of various adsorbates due to their induced doping upon adsorption.

Another potential embodiment is for self-cleaning or anti-fouling. Where a tightly packed difficult to penetrate film is adsorbed and held in place with the electric field, and can be periodically regenerated by desorbing and resorbing. Other self-cleaning can facilitate a dew forming, that can then roll off (FIG. 12C).

The rate of catalysis is often controlled by an adsorption step, so tuning the adsorption could also be useful for catalysis (FIG. 11E). In these embodiments, catalytically active nanoparticles may also be coated deposited on top of the 2D material. Alternate embodiments may have catalytically active sites embedded inside a nanoporous film covering the 2D material.

The layers needed to produce a device of this technology are a conductive layer of material, if it is not already conductive. On top of this, a thin dielectric film is applied. On top of this a 2D material is deposited. The individual layers (conductive, dielectric, 2D material layers) can be deposited through various means, like chemical vapor deposition, physical vapor deposition, solution processing, transfer printing, among others. In some embodiments, an additional layer of an adsorbent, like metal organic frameworks or zeolite, can be applied. In some embodiments, porous layers would be desired, like for certain filtration applications. The dielectric and/or back gate could also be made to be nanoporous, if desired for the application, like in the case of a filter.

Various possible modes of fabricating the devices are shown in FIG. 13. A substrate is provided. If the substrate is not conductive, it may be coated with a conductive material such as Cu, Al, Ag, Au, graphene, and transparent conductors. Methods used for coating may include PVD, CVD, inkjet, electrospray, gravure printing, and nanopore generation. A dielectric is deposited on the conductive surface of the substrate, such as Al₂O₃, SiO₂, liquid crystals, surfactants, a self-assembled monolayer, absorbents (MOF, zeolite, silica gel), or combinations, which may be deposited by e.g., PVD, CVD, inkjet, electrospray, gravure printing, or SolGel. A 2D material is then formed on the dielectric, which may be any of the aforementioned 2D materials, and especially graphene and Mo2S. The 2D material may be deposited by transfer printing, PVD, CVD, inkjet, electrospray, gravure printing, pulsed laser deposition, nanopore generation, etc. Additional films of surfactant, adsorbents (MOF, zeolite, silica gel), liquid crystals may be disposed on the 2D material.

The technology may further provide control over chemical reactions, by selectively controlling concentration or orientation of molecules at a surface, e.g., a catalytic surface, in a gaseous, liquid or mixed environment.

The technology may selectively provide optical effects, such as lens curvature of a liquid droplet on a surface (with a liquid-gas interface, or a boundary of two immiscible liquids).

The technology may selectively provide optical polarization effects, such as by controlling orientation of liquid crystal molecules at the surface, in a reflective or transmissive polarizer. See, en.wikipedia.org/wiki/Liquid_crystal, incorporated herein by reference.

The technology may selectively provide control over fluorescence or phosphorescence, by ordering fluorescent or phosphorescent molecules at the surface of the 2D material. This ordering may orient absorption and/or emission vector, control stimulated emission (lasing or masing), or other property of the molecule in the relaxed or excited state. See en.wikipedia.org/wiki/Fluorescence; en.wikipedia.org/wiki/Phosphorescence.

The technology may be used as part of a purification technique, such as by selectively forming an ordered monolayer of an ambient molecule on the 2D material surface (or in conjunction with a layer over the 2D material surface), wherein the lowest energy configuration will tend to prevail, especially if the surface condition is cycled by oscillating the electrical field so that molecules are absorbed and released until a regular ordered array surfacer layer is achieved. As part of a purification process, the layer may be absorbed from a source medium and later released into a purified medium.

The technology may be used as a detector for chromatography processes, for example by detecting optical properties or phonon resonance (optical or acoustic/vibrational) properties of the 2D surface under an oscillating electric field as a flow of medium passes over the surface. en.wikipedia.org/wiki/Phonon, en.wikipedia.org/wiki/Plasmon, en.wikipedia.org/wiki/Surface_plasmon_resonance.

The technology may used in stereoscopic displays, and multiuser autostereoscopic projection displays with user eye tracking for feedback and dynamic steering of left and right images on a per-user basis. en.wikipedia.org/wiki/Stereo_display, en.wikipedia.org/wiki/Autostereoscopy .

In some cases, the electric field may be created by a thermoelectric, piezoelectric, electrooptic, or electrochemical effect, such that the change in the surface of the 2D material is transduced from another form of energy, such as heat, mechanical/vibration, light, or chemical energy. Advantageously, the surface change is responsive to a spatial pattern, such that the 2D surface has regiospecific properties. In an electrical embodiment, the electric field may be imposed according to a pixelized electrode arrangement.

optical polarization effects, such as by controlling orientation of liquid crystal molecules at the surface, in a reflective or transmissive polarizer.

It is an object to provide a device having a 2D material, formed on a dielectric layer, having a conductive material under the dielectric layer, wherein an electrostatic field from the conductive material modifies a property of the 2D material with respect to molecules.

It is also an object to provide a method of controlling a property of a surface, comprising: providing a device having a 2D material having the surface, formed on a dielectric layer, having a conductive material under the dielectric layer; and controlling an electrostatic field at the 2D material to modify the property of the surface with respect to molecules.

The dielectric layer may be an insulator, and the conductive material may be a metal.

The property may comprise an absorption or wetting of the 2D material surface with a polar molecule, e.g., water.

The 2D material may comprise graphene, MoS₂, or a boron compound.

The 2D material may be a chemical vapor deposited film, a solution deposited film, or an atomic layer deposited film.

The dielectric may be a chemical vapor deposited layer, a spray coating, or a chemical vapor deposited layer.

A nanoporous material, a metal organic framework, or a zeolite, may be provided over the 2D material.

Catalytic nanoparticles may be provided proximate to the 2D material.

A transport across a porous membrane may be dependent on the electrostatic field.

An electronic control may be provided to establish the electrostatic field. The electrostatic field may be dynamically changing.

The molecules may be physiosorbed, or chemisorbed.

The device may further comprise an electronic sensor configured to sense conductivity through the 2D material.

The device may further comprise a heater configured to heat the 2D material, e.g., to heat the 2D material to desorb the molecules.

The method may further comprise catalyzing a chemical reaction proximate to the 2D material.

The method may further comprise catalyzing a chemical reaction with catalytic nanoparticles proximate to the 2D material.

The method may further comprise controlling a transport across a porous membrane is dependent on the electrostatic field.

The method may further comprise electronically controlling the electrostatic field.

The method may further comprise electronically controlling a dynamically changing electrostatic field.

The method may further comprise sensing conductivity through the 2D material.

The method may further comprise heating the 2D material, e.g., to desorb the molecules.

The method may further comprise removing condensation from the surface, by changing the surface from hydrophobic, to momentarily hydrophilic, to convert a condensation film to droplets, by altering the electrostatic field.

The method may further comprise spatially controlling the electric field on the surface to direct motion of a fluid droplet on the surface.

The method may further comprise oscillating the electrostatic field to clear droplets or ice from the surface.

The surface may be associated with a catalyst, the method further comprising controlling a rate of a chemical reaction by varying the electrostatic field.

The property may be an absorption of a molecule to the surface, a wettability of the surface with a fluid, a catalytic activity of the surface wherein a chemical reaction of the molecule is catalyzed at the surface, an adhesion of ice to the surface, an absorption of a molecule, relate to a boiling of a fluid at the surface, or relate to a condensation of a fluid on the surface. The property may comprise absorption of a molecule to the surface, wherein a chemical reaction of the molecule is catalyzed at the surface. The property may comprise absorption of a molecule, further comprising controlling the electrostatic field to absorb the molecule, and subsequently regenerating the surface by heating to desorb the molecule.

It is also an object to provide a system, comprising: a conductive substrate; a dielectric material on the conductive substrate; a 2D material, formed on the dielectric material; and an automated control, configured to control an electrostatic field surrounding the 2D material, to thereby alter a surface property of the 2D material. The property may be selected from the group consisting of absorption of a molecule and wetting with a fluid. The property may be reversible.

It is a further object to provide a device having a controlled property with respect to surrounding molecules, comprising: a substrate having a conductive surface; a dielectric layer formed on the conductive surface; and a 2D material, formed on the dielectric layer, wherein an electrostatic field from the conductive material modifies a property of the 2D material with respect to the surrounding molecules.

The dielectric layer may be an insulator, and the conductive material may be a metal.

The surrounding molecules may be polar molecules, and the property may be an absorption or wetting of the 2D material surface with the polar molecules. The polar molecules comprise water. The surrounding molecules may be physiosorbed or chemisorbed.

The device may further comprise an electronic sensor configured to sense electrical conductivity through the 2D material.

It is a further object to provide a method of controlling a surface property, comprising: providing a device having a 2D material having a surface, formed on a dielectric layer, having a conductive material under the dielectric layer configured to impose an electric field on the 2D layer; and controlling an electrostatic field on the 2D material to modify the property of the surface with respect to surrounding molecules.

The dielectric layer may be an insulator, the conductive material a metal, and the 2D material may be selected from the group consisting of graphene, molybdenum disulfide, and a boron compound.

A material may be provided over the 2D material, e.g., at least one of a nanoporous material, a metal organic framework, a zeolite, catalytic nanoparticles, a surfactant, and a liquid crystal.

All patents and other publications; including literature references, issued patents, published patent applications, and co-pending patent applications; cited throughout this application are expressly incorporated herein by reference for all purposes, including, but not limited to, describing and disclosing, for example, the methodologies described in such publications that might be used in connection with the technology described herein.

The description of embodiments of the disclosure is not intended to be exhaustive or to limit the disclosure to the precise form disclosed. While specific embodiments of, and examples for, the disclosure are described herein for illustrative purposes, various equivalent modifications are possible within the scope of the disclosure, as those skilled in the relevant art will recognize. For example, while method steps or functions are presented in a given order, alternative embodiments may perform functions in a different order, or functions may be performed substantially concurrently. The teachings of the disclosure provided herein can be applied to other procedures or methods as appropriate. The various embodiments described herein can be combined to provide further embodiments. Aspects of the disclosure can be modified, if necessary, to employ the compositions, functions and concepts of the above references and application to provide yet further embodiments of the disclosure. Moreover, due to biological functional equivalency considerations, some changes can be made in protein structure without affecting the biological or chemical action in kind or amount. These and other changes can be made to the disclosure in light of the detailed description. All such modifications are intended to be included within the scope of the appended claims.

Specific elements of any of the foregoing embodiments can be combined or substituted for elements in other embodiments. Furthermore, while advantages associated with certain embodiments of the disclosure have been described in the context of these embodiments, other embodiments may also exhibit such advantages, and not all embodiments need necessarily exhibit such advantages to fall within the scope of the disclosure.

The technology described herein is further illustrated by the following examples which in no way should be construed as being further limiting.

### BRIEF DESCRIPTION OF THE DRAWINGS

FIG. 1A shows schematic of the water molecules orientation vs the gate voltage position when V_{GS}>V_{CNP}.

FIG. 1B shows schematic of the water molecules orientation vs the gate voltage position when V_{GS}<V_{CNP}.

FIG. 1C shows interdependency of water molecules orientation and the doping status of graphene. Where the graphene is electrically n-doped, water molecule adsorbs with the OH band downward resulting in a slight p-doping of graphene.

FIG. 1D shows interdependency of water molecules orientation and the doping status of graphene. Where the graphene is electrically p-doped, water molecule adsorbs with the OH band upward resulting in a slight n-doping of graphene.

FIG. 2 shows a schematic overview of a graphene field effect transistor on a quartz crystal microbalance (QCM) preparation process.

FIG. 3A shows schematic band structure of graphene upon changing the gate voltage for originally undoped-graphene.

FIG. 3B shows schematic band structure of graphene upon changing the gate voltage for intrinsically p-doped graphene

FIG. 3C shows schematic band structure of graphene upon changing the gate voltage for intrinsically n-doped graphene

FIG. 4A shows adsorption isotherms of water on graphene at three different gate voltage: 0V, +20V, −20V. The isotherms show higher uptakes for non-zero gate voltages where the gate voltage induces electrons/holes to the graphene. The IV curves prior to water adsorption shows no hysteresis after annealing.

FIG. 4B shows the corresponding IV curve of each test prior to the water adsorption (at high vacuum).

FIG. 5 shows the IV curves measured at high vacuum by sweeping in both directions.

FIG. 6A shows the IV curves measured after water vapor exposure for the adsorption tests with the gate voltage at +20V. The sweep direction was from +20V to −20V.

FIG. 6B shows the IV curves measured after water vapor exposure for the adsorption tests with the gate voltage at −20V. The sweep direction was from −20V to +20V.

FIG. 6C shows the IV curves measured after water vapor exposure for the adsorption tests with the gate voltage at 0V. The sweep direction was from +20V to −20V.

FIG. 6D shows the IV curves measured after water vapor exposure for the adsorption tests with the gate voltage at 0V. The sweep direction was from +20V to −20V.

FIG. 7A shows the highest occupied molecular orbital of H₂O.

FIG. 7B shows the lowest unoccupied molecular orbital of H₂O.

FIG. 8A shows the shift in the charge neutral point on the left and the doping density on the right upon water exposure at four different gate voltages: +20V (triangle up), −20V (triangle down), 0V with +20V as the starting sweep voltage (circle), and 0V with −20V as the starting sweep voltage (square).

FIG. 8B shows the Fermi level shift induced by water adsorption at four different gate voltages: +20V (triangle up), −20V (triangle down), 0V with +20V as the starting sweep voltage (circle), and 0V with −20V as the starting sweep voltage (square).

FIG. 9A shows the effect of gate voltage on the doping rate as a function of exposure time tested at four different gate voltages: +20V (triangle up), −20V (triangle down), 0V with +20V as the starting sweep voltage (circle), and 0V with −20V as the starting sweep voltage (square).

FIG. 9B shows the effect of gate voltage on the doping rate as a function of exposure pressure tested at four different gate voltages: +20V (triangle up), −20V (triangle down), 0V with +20V as the starting sweep voltage (circle), and 0V with −20V as the starting sweep voltage (square).

FIG. 10 (see U.S. Pat. No. 7,702,660), expressly incorporated herein by reference), shows a block diagram that illustrates a computer system.

FIG. 11A shows a device with a surfactant molecule underneath the surface controlled by the gate voltage.

FIG. 11B shows a device with surfactant on top of the device controlled by the gate voltage.

FIG. 11C shows a liquid crystal underneath the 2D material controlled by the gate voltage.

FIG. 11D shows a liquid crystal above the 2D material controlled by the gate voltage.

FIG. 11E shows an adsorbent underneath a nanoporous 2D material, where adsorption selectivity, isotherms, and kinetics are tuned by the gate voltage.

FIG. 12A shows an application where a gradient in surface properties is generated laterally by a changing voltage difference spatially between the 2D material and the gate.

FIG. 12B shows an application where a temporally changing 2D material-gate voltage changes the wetting in time. This can allow transition from more hydrophilic to hydrophobic, and vice-versa.

FIG. 12C shows filmwise condensation being converted to dropwise via an applied 2D material-gate voltage.

FIG. 12D shows an array of surface property tunable regions actuated via separately applied voltages.

FIG. 13 shows potential manufacturing method including potential materials and techniques.

### DETAILED DESCRIPTION OF THE PREFERRED EMBODIMENTS

Experimental Methods

Apparatus

An apparatus with the ability to measure the adsorption isotherms under different gases, and the electronic properties of 2D materials, was designed and constructed. The environmental vacuum chamber was equipped with a custom sample holder to measure the IV curve (Keithley SMU 2614B) and a dry pumping station (Pfeiffer HiCube 80 Eco) that reaches a base pressure of 1×10⁻⁶ Torr (MKS 390 Micro-Ion® ATM). The chamber was temperature controlled via a recirculation bath (Haake K20, Glass Encapsulated Thermistors 55004). Deionized water (DI) (Sigma-Aldrich 38796) was degassed through multiple freeze-pump-thaw cycles and was used as the vapor source for water adsorption. A modified 5 MHz AT-cut Quartz Crystal Microbalance (QCM) (Stanford Research Systems QCM200) was implemented for the adsorption uptake measurements. Vapor pressure was measured using two heated capacitance manometers (Kurt J. Lesker HCG045-OT-1-1 and HCG045-FT-1-1). All the sensors were monitored via MATLAB and a data acquisition logger (Keithley DAQ6510).

Sample Preparation

A back gated Graphene Field Effect Transistor (GFET) was fabricated on top of a 5 MHz AT cut QCM. The top electrode of the QCM also serves as the back gate for the transistor. The gate dielectric was a 100 nm Al₂O₃ deposited via Atomic Layer Deposition (ALD) with Trimethylaluminium (TMA) and Oxygen plasma at 200° C. (Oxford Flex AL). Prior to the ALD deposition, the samples were sonicated for 15 min in acetone, methanol and isopropyl alcohol, respectively. QCMs with Au electrodes were used to avoid the back electrodes degradation during the GFET fabrication process. For a better adhesion between the dielectric and the back gate, 100 nm of Ti was deposited on the top electrode of the QCM via E-beam evaporation (AJA International).

After the dielectric deposition, Poly Methyl Methacrylate (PMMA) backed Chemical Vapor Deposited (CVD) graphene (Graphenea Monolayer Graphene on Polymer Film) was transferred onto the QCM. The samples were dried in air for 30 min, followed by baking on a hotplate at 150° C. for 1 hr. Then, the samples were kept under low vacuum (0.1 Torr) for 24 hours to remove the trapped water between the substrate and graphene. This results in a better bond between the dielectric and the graphene, and also minimizes the effect of trapped water on the interaction of adsorbates with graphene. To remove PMMA from the graphene, the samples were soaked in acetone at 50° C. for lhr followed by soaking in isopropyl alcohol for another hour and then dried with N₂. To further remove PMMA trace residuals, the samples were annealed at 300° C. and 1×10⁻⁸ Torr for 2 hours with a ramping temperature of 5° C./min. After the graphene deposition, the source and drain (5 nm Cr+100 nm Au) were deposited on top of graphene via E-beam evaporation (AJA International), creating a 0.24 inch by 0.24 inch channel that overlaps with the top electrode of the QCM. The entire fabrication process was conducted in a class 100 clean room.

Before each test, the sample was annealed (ex-situ) at 150° C. for lhr under 95%Ar-5%H₂ at 0.1 mbar. Then, it was transferred to the test chamber and was pumped down for 18 hr under high vacuum before each adsorption test. This procedure was done to help the graphene to return to its original Charge Neutral Point (CNP). Although it would be ideal to anneal the sample in-situ, i.e. without exposing to air after annealing, the limitations in the electronics of the custom QCM holder prevented reaching an annealing temperature more than 120° C., which was not sufficient to restore the original CNP. Besides the external heating, current annealing was also adapted, where a high current was applied between the source and the drain to heat up the graphene and desorb water. This technique was initially effective, however, using a gate voltage to enhance the source-drain current results in breaking the dielectric after multiple tests.

Results and Discussions

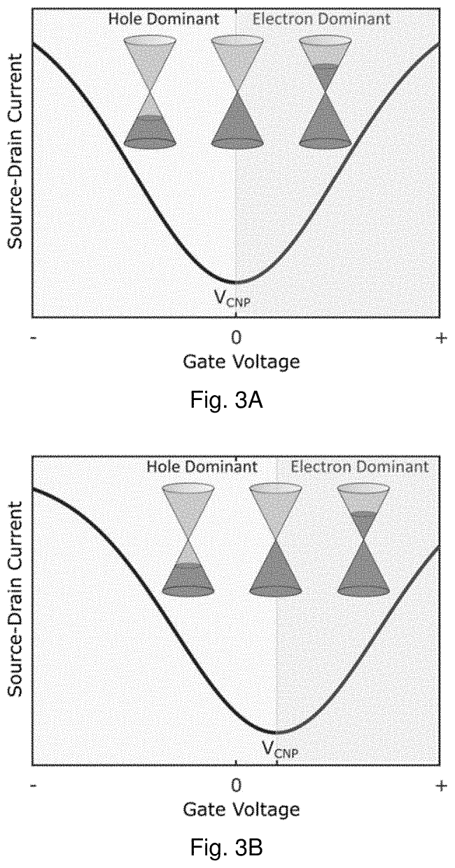

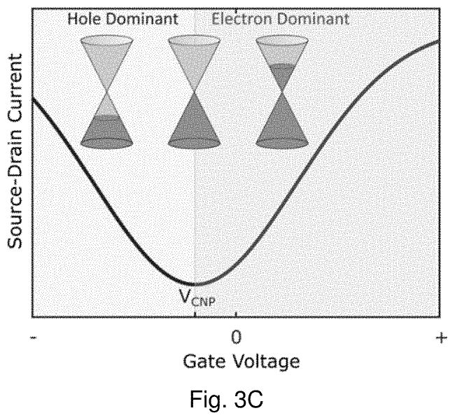

The graphene IV curve from a GFET device is a characterization of the doping level. The gate voltage with the minimum conductance represents the CNP, which indicates whether the graphene is p or n doped. A pristine (undoped) graphene has its minimum conductance at the zero-gate voltage where its mobility is maximum, and the carrier density is zero (the Dirac Point). In a back gated GFET, an applied gate voltage greater than V_{CNP} (the voltage at the minimum conductance, i.e., the charge neutral point) inserts electrons into the conduction band (V_{GS}-V_{CNP}>0, the red line), shifts the Fermi level upward and n-dopes the graphene. Conversely, an applied gate voltage smaller than V_{CNP} (V_{GS}-V_{CNP}<0, the blue line), extracts electrons from the valence band and creates holes, which results in shifting the Fermi level downward and p-doping the graphene as shown in FIGS. 3A-3C. Thus, in the case of no applied gate voltage, a p-doped graphene has a V_{CNP}>0 and a n-doped graphene has a V_{CNP}<0.

Adsorption Isotherms at Different Gate Voltages

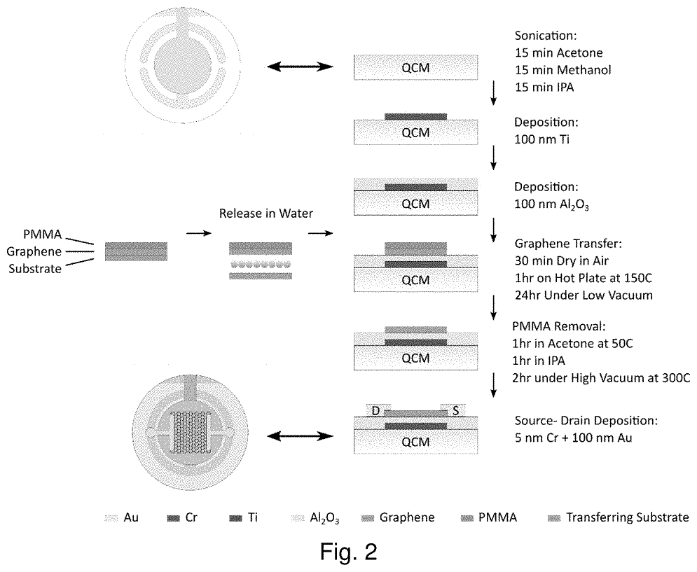

The GFET was successfully made on a QCM in order to measure the mass of adsorbed water at different gate voltages. In this set of experiments, graphene was exposed to water vapor while the gate voltage was kept at a constant value during water adsorption. The fabrication is shown in FIG. 2. The quartz crystal microbalance (QCM) is prepared as follows. The quartz crystal is prepared by sonication in acetone (15 min.), methanol (15 min.) and isopropyl alcohol (IPA 15 min.). A 100 nm titanium film is deposited on the prepared crystal. A 100 nm layer of aluminum oxide (Al₂O₃) dielectric is deposited over the titanium layer. A graphene layer is transferred onto the dielectric by providing a graphene layer on a substrate coated with poly methyl methacrylate (PMMA), which is released from the substrate in water and the PMMA-graphene layer transferred on the dielectric, dried 30 min. in air, 1 hr. on a hot plate at 150C, and 24 hr under low vacuum. The PMMA is removed by immersing 1 hr in 50C acetone, 1 hr in IPA, and 2 hr under high vacuum at 300C. Source and drain are deposited at the edge of the graphene layer as 5 nm Cr and 100 nm Au.

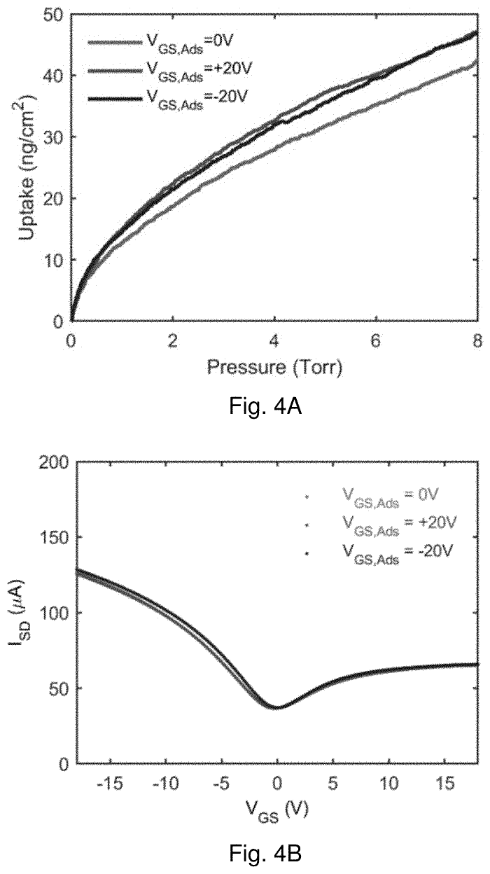

FIGS. 4A and 4B show adsorption isotherms of water onto graphene at three different gate voltages: 0V, +20V, −20V. FIG. 4A shows that the isotherms show higher uptakes for non-zero-gate voltages than zero-gate voltage. FIG. 4B shows the corresponding IV curves prior to each test while under high vacuum. The IV curves prior to water adsorption show no hysteresis after annealing.

IV curves were only measure at the beginning (high vacuum) and at the end of the experiment. FIG. 4A. shows the adsorption isotherms of water on graphene at three different gate voltages, 0V, +20V, and −20V. It is shown that non-zero gate voltages result in higher uptakes as the pressure increases. However, there is no significant change in the uptake depending on the polarity of the gate. The reasoning behind this observation will be later discussed by a new set of experiments.

The water adsorption onto graphene increased ˜15% and the doping levels increased by a factor of three with a gate-to-graphene voltage of +20 or −20V compared to 0V for sub-monolayer adsorption. This change in uptake is attributed to the increase in density of state of graphene upon electrical-doping, which changes the Coulombic and van der Waals interactions. The water adsorption onto graphene is either n- or p-doping depending on the applied gate-to-graphene voltage. The ambi-doping nature of water onto graphene is due to the polar nature of water molecules, so the doping depends on the orientation of the water molecules.

Note that the sample was annealed before each experiment to return graphene to its original charge neutral point. FIG. 4B. shows the IV curves measured prior to each experiment at high vacuum. It can be seen that the no hysteresis exists in the charge neutral point. With the charge neutral point at zero gate voltage, the three applied gate voltages during water adsorption, 0V, +20V, and −20V, will induce no doping, n-doping, and p-doping, respectively. Note that this could be changed as water induces doping.

Hysteresis in IV Curves

In a pristine graphene, the Fermi level is at the Dirac point where the number of carriers (electrons and holes) are equal i.e., the total charge of graphene at this point is zero. A negative applied gate voltage will move the electrons from the graphene to the gate (create holes within graphene) and a positive applied gate voltage will move the electrons from the gate to the graphene. Thus, sweeping the gate voltage from a negative value to a positive value will change the doping type from p-doping to n-doping, and vice-versa for a positive gate voltage.

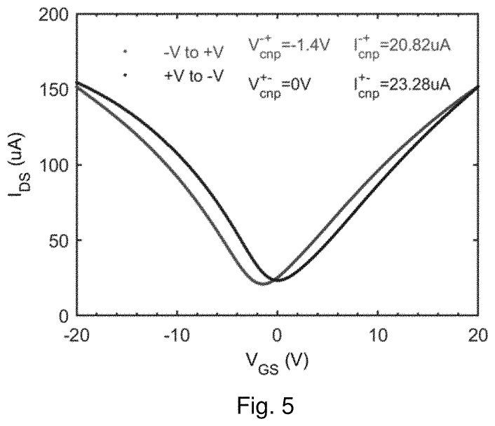

FIG. 5 shows the IV curves measured for a sample under high vacuum by sweeping the gate voltage in both directions, +20V to −20V and −20V to +20V while the source-drain voltage was kept at 0.1V. The sweeping direction should not affect the position of the charge neutral point, however, there is a hysteresis in the charge neutral point. This hysteresis comes from the charge transfer by nearby adsorbates, such as water, or charge injection into the trap sites on the dielectric substrate¹⁵⁰. Although GFETs normally create a uniform electric field through the gate, impurities could result in the hysteresis. The hysteresis changes subject to the sweeping voltage range/rate and the surrounding condition¹⁵⁰⁻¹⁵³. Although both mechanisms cause the hysteresis affect graphene on the seconds time scale, a higher sweep rate decreases the hysteresis caused by the charge transfer while a slower rate decreases the hysteresis caused by the capacitive gating¹⁵⁰.

In all the IV measurements, the gate voltage was swept with a 0.1V increment/decrement at a ˜8V/sec rate (the maximum achievable by the source meter). This rate gave the minimum hysteresis which shows that the first mechanism causing the hysteresis was more dominant.

Effect of Water Vapor Exposure on Doping

The effect of a gate voltage on the water adsorption onto graphene was investigated by analysis of the IV curves. In each test, the gate voltage was kept at a constant value (+20V, −20V, and 0V) during water adsorption. IV scans were conducted every minute during water vapor exposure. To avoid further adsorption/desorption during the voltage sweep, the chamber was evacuated for 1 minute before each IV measurement (pressure minimum of 5 mTorr). Since it was shown that the voltage sweep direction could affect the charge neutral point for the adsorption tests with an applied +20V gate voltage, the voltage for the IV measurements was swept from +20V to −20V and then back to +20V. Conversely, for the −20V adsorption test, the voltage was swept from −20V to +20V, then back to −20V. Two adsorption tests were performed for the zero-gate voltage: One with a +20V to −20V to +20V sweep and the other one with a −20V to +20V to −20V sweep. The purpose of running two tests at zero gate voltage was to see if the first sweep direction affects the water adsorption on graphene. For all measurements, the source-drain voltage was kept at 0.1V.

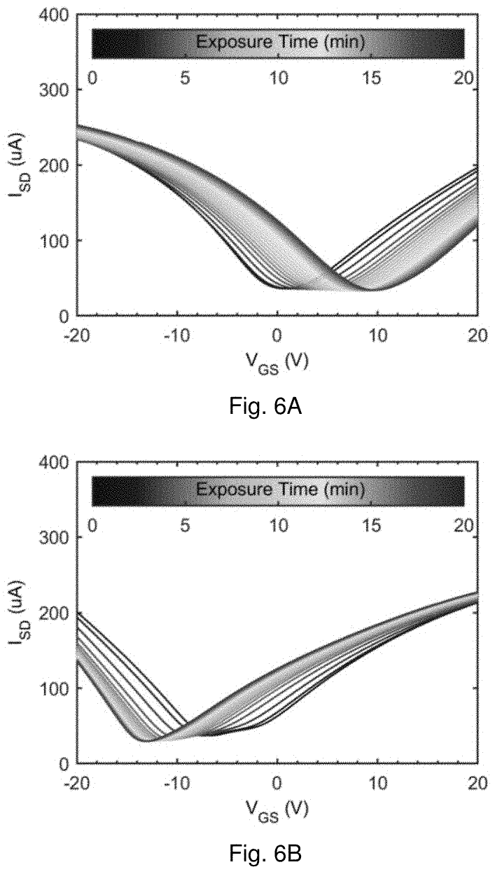

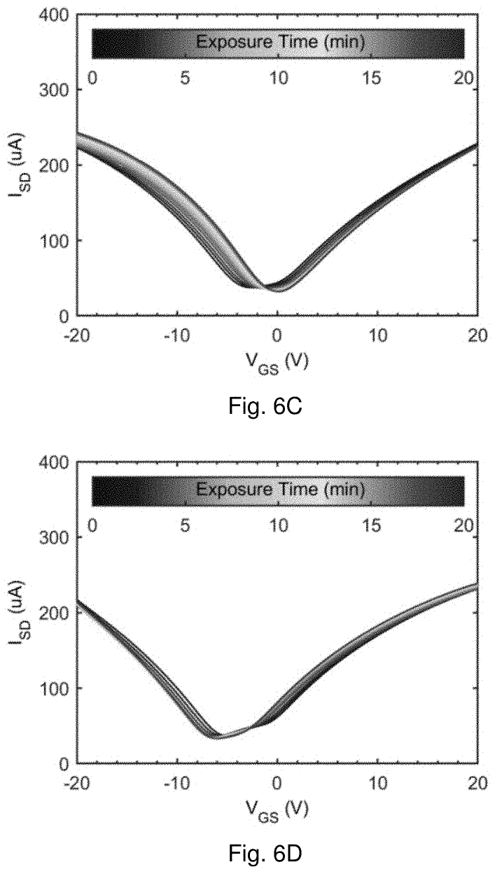

FIGS. 6A-6B show the IV curves, upon water vapor exposure, for tests with different applied gate voltages. In the test with an applied gate voltage of +20V during the adsorption the graphene was initially n-doped, and the adsorption of water molecules made the graphene less n-doped, eventually leading to p-doping (FIG. 6A). On the other hand, when the applied gate voltage was kept at −20V during the adsorption where the graphene was initially p-doped, the adsorption of water molecules induce n-doping and making the graphene less p-doped (FIG. 6B).

FIGS. 6A-6D shows 3 IV curves measured under vacuum after x minutes (x=0, 1, 2, . . . , 20) of water vapor exposure with the gate voltage at (FIG. 6A) +20V, (FIG. 6B) −20V, and (FIGS. 6C and 6D) 0V. The gate voltage sweep in FIG. 6A and 6C was +20V→−20V→+20V, and in FIGS. 6B and 6D) was −20V→+20V→−20V. The chemical doping due to adsorption of water vapor is larger for the +20V and −20V tests (FIGS. 6A and 6B) than the 0V tests (FIGS. 6C and 6D), as indicated by their greater shift of their charge neutral. It is also noted that the direction of the charge neutral point shift is opposite for the +20V and −20V tests (FIGS. 6A and 6B), demonstrating that water can ambi-dope graphene. The 0V tests also demonstrate small and opposite shifts in the change neutral point due to hysteresis from the vacuum applied gate sweep voltage.

Tests with a larger absolute applied gate voltage show more doping (|V_{GS}-V_{CNP}|), which is proportional to the water uptake. Water molecules consist of one oxygen atom covalently bonded with two hydrogen atoms in a tetrahedral structure. The higher electronegativity in oxygen creates an electrical dipole moment in water molecules with negative charges on the oxygen atom and positive charges on the hydrogen atoms. This dipole moment in the water molecules affects its adsorption on a surface.

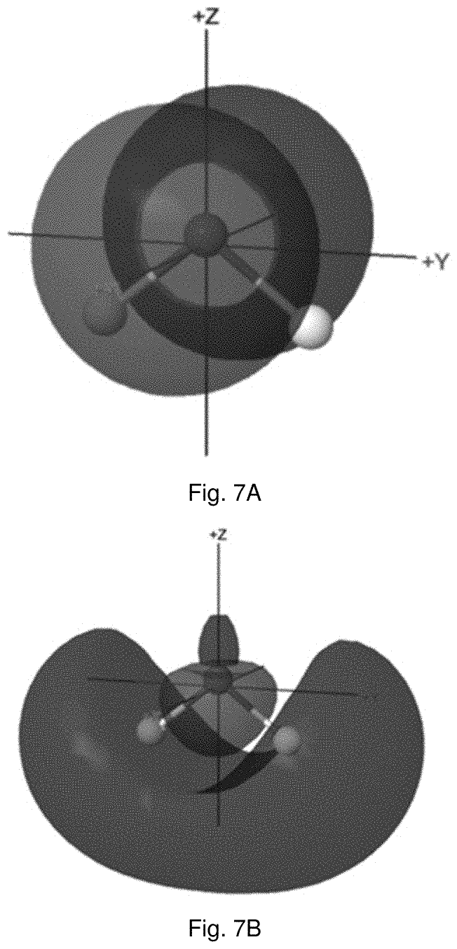

Many dopants clearly fall in two categories, electron-donor molecules that n-dope graphene and electron-acceptor molecules that p-dope^{58,154}, however the doping induced by water adsorption onto graphene depends on the orientation of the adsorbed water molecule which is controlled by the electric field at the supporting substrate^{155,156}. Density-functional theory (DFT) calculations showed the orientation of water molecules with one O—H bond parallel to the surface and the other one pointing towards the surface is the most energy favorable orientation for water adsorption on a perfect graphene¹⁵⁴. However, this orientation can be altered on a supported graphene. Depending on the orientation of the adsorbed water molecule, it can either p-dope or n-dope graphene. In a water molecule, the HOMO (Highest Occupied Molecular Orbital) is completely located on the O atom and the LUMO (Lowest Unoccupied Molecular Orbital) is mostly located on the H atoms (FIG. 7A). Due to the relative position of the HOMO and the LUMO of a water molecule with respect to the Dirac point, if the O atom points to graphene (O—H bond pointing up), the HOMO plays the dominant role and donates some charges from water to graphene through a small mixing with graphene orbitals above the Fermi level (creating n-doping). If the H atom points to graphene (O—H bond pointing down), there is a small charge transfer to the water molecule from graphene through small mixing with the graphene orbitals below the Dirac point (creating p-doping)¹⁵⁴.

Therefore, in the case of an applied gate voltage greater than the voltage at the charge neutral point (V_{G}>V_{CNP}), where graphene is n-doped and electrons are the dominant charge carriers in graphene, water molecules tend to adsorb on graphene with the positive side of the dipole (H atoms towards graphene) which transfers charge from the graphene to the water molecules and creates p-doping in graphene. This is aligned with moving the CNP in FIG. 6A. in the positive direction where V_{GS}=+20V, which is greater than V_{CNP}. Inversely, when V_{GS}<V_{CNP}, the graphene is p-doped and holes are the dominant charge carriers. Consequently, water molecules adsorb on graphene with the OH bonds upward and the charge transfers from the water to the graphene, n-doping the graphene. This agrees with FIG. 6B, where V_{GS}=−20V, which is less than V_{CNP}, and the CNP moves in the negative direction.

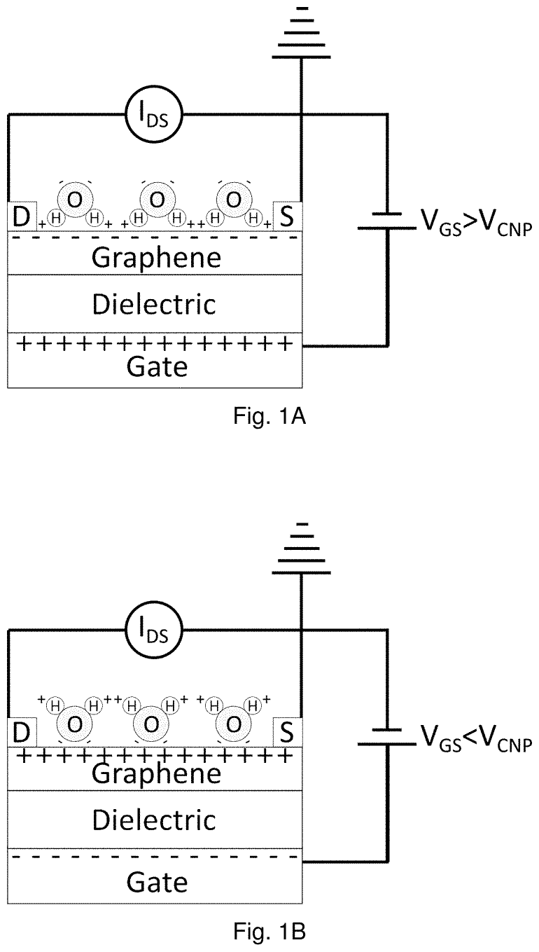

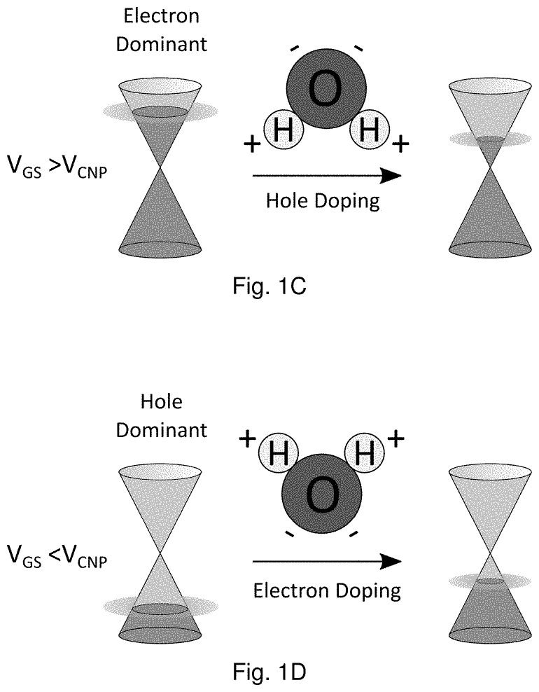

FIGS. 1A-1E illustrate the mechanism for water molecules changing the doping. In the two adsorption tests where the gate voltage was kept at zero potential during water exposure, the graphene is affected by the last voltage applied during the IV measurements. This is probably due to adsorbed water molecules that were aligned according to the last applied gate voltage. Although both cases showed smaller shift of the CNP, the initial doping was aligned with its prior test. In the zero gate voltage test with +20V starting/ending sweep, water molecules adsorbed with the OH bonds downward, resulting in p-doping graphene and in the other zero gate voltage test where the voltage was swept from −20V and ended at −20V, water molecules adsorbed with the oxygen atoms pointing to graphene, creating n-doping. This larger shift of the CNP during the tests with non-zero gate voltages shows that an applied gate voltage can enhance the water adsorption on graphene, however, due to the dipolar nature of the water molecules, the polarity of the gate does not affect the adsorption significantly.

Effect of the Gate Voltage on Doping Upon Water Exposure

Although IV curves provide a simple visualization of the CNP position, other useful information such as the carrier density and the mobility of graphene can be derived from the IV curves. The doping density corresponds to the extent of adsorbed water on graphene. The graphene carrier density induced by the gate voltage can be derived through

n=(c_{g}/e)(V_{GS}-V_{CNP}) (5)

where c_{g}=C_{g}/A, is the gate capacitance per unit area and e is the elementary charge⁵⁸. The gate capacitance, C_{g}, for 100 nm of Al₂O₃ was measured to be 86 nF (Keithley 4200-SCS). Therefore, the doping density induced by the water adsorption is

Δn(t)=(c_{g}/e)ΔV_{CNP}(t) (6)

where ΔV_{CNP}(t)=V_{CNP}(t)−V_{CNP,0} and V_{CNP,0} is the voltage of the CNP before water exposure. Moreover, the Fermi level shift induced by the adsorption can be calculated through,

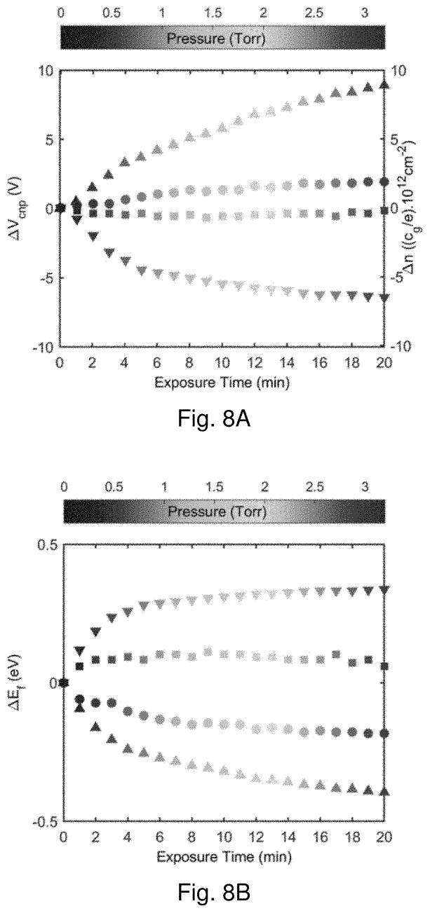

ΔE_{f}(t)=Δn(t)/|Δn(t)|·hᵥν_{f}\sqrt{π|Δn(t)|/e} (7)

where h_{b} and ν_{f} are the reduced Plank constant and the Fermi velocity of graphene, respectively. FIGS. 8A and 8B show the shift in the charge neutral point, the corresponding doping density, and the shift in the Fermi level upon water vapor exposure to graphene.

FIGS. 8A-8B show the difference between the applied gate voltage and the charge neutral point versus water vapor exposure time for gate voltages of +20V (Δ), −20V (∇), 0V (∘), and 0V (□).The shift of the V_{CNP} upon water exposure at the different gate voltages is shown in FIG. 8A. FIG. 8B shows the shift of the Fermi level due to water adsorption. The IV curves were measured under vacuum. The IV gate-graphene voltage was swept +20V→−20V→+20V for Δ and ∘ measurements, and swept −20V→+20V→−20V for ∇ and □ measurements. The doping densities and Fermi level shifts were greater for the +20V and −20V tests than those at 0V. The chemical doping due to adsorption was opposite for the +20V and −20V tests. The doping difference between the two 0V tests was due to hysteresis from the gate sweep.

GFET IV curves illustrate the current through a graphene channel as function of the gate-graphene voltage (FIG. 1). The gate-graphene voltage (V_{GS}) with the minimum conductance represents the charge neutral point (V_{CNP}). A pristine (undoped) graphene has its minimum conductance at zero-gate voltage, where its mobility is maximum and the carrier density is minimum (the Dirac Point). For V_{GS}-V_{CNP}>0, the Fermi level shifts upward, and n-dopes graphene. Conversely, when V_{GS}-V_{CNP}<0, the applied electric field extracts electrons from the valence band to create holes, which results in shifting the Fermi level downward, p-doping the graphene.

To measure the mass of adsorbed water vs the applied gate voltage, i.e., as a function of shifting the Fermi level, the GFETs were fabricated on QCMs. Adsorption isotherms were measured in an environmental vacuum chamber using the shift in the resonance frequency of the QCM upon water vapor exposure. In a temperature-controlled environment, the resonance frequency of a QCM depends on the magnitude of the adsorbed mass, the effect of the hydrostatic pressure on the elastic modulus of quartz, and the viscoelastic coupling to the gas. Corrections for pressure and viscoelastic coupling were made to calculate the mass adsorbed.

The three applied gate voltages during water adsorption, 0V, +20V, and −20V, induced no doping, n-doping, and p-doping, respectively. The non-zero-gate voltages led to higher uptakes. However, switching the gate voltage polarity resulted in similar uptakes. For example, at ˜3 Torr where approximately a monolayer of adsorbed water was expected, the uptake was ˜15% higher at gate voltages of +20V and −20V than at 0V. DFT calculations have shown higher adsorption energy of gases, including water vapor, on doped graphene compared to undoped graphene, where according to the Langmuir model, the higher adsorption energy should result in higher adsorption uptake. This change in uptake for the doped graphene is attributed to the change in the Coulombic and van der Waals interactions due to the increase in density of state (DOS) of graphene upon doping.

To gain insight into the doping of graphene due to water adsorption under an applied electric field, an additional set of experiments measured the electronic properties of graphene during adsorption. In these experiments, the gate voltage was kept at a constant value (+20V, −20V, or 0V), while IV scans were periodically conducted after x minutes of water vapor exposure (x=0, 1, 2, . . . , 20). To avoid further adsorption/desorption during IV scans, the chamber was evacuated for 1 min prior to each scan (maximum pressure of 5 mTorr). The gate voltage during IV scans started and ended at the adsorption gate voltage. For the adsorption tests with an applied +20V gate, the IV gate voltage was swept from +20V to −20V and then back to +20V. Conversely, for the −20V adsorption test, the gate voltage was swept from −20V to +20V, then back to −20V. Adsorption tests were performed for the zero-gate voltage with both sweep procedures (+20V→−20V→+20V and −20V→+20V→−20V). The purpose of running two adsorption tests at zero-gate voltage was to see how the sweep direction affects water adsorption onto graphene and if the graphene-water interface remembers the last applied gate voltage. For all measurements, the drain-source voltage was kept at 0.1V, which is in the ohmic region.

FIGS. 6A-6D show the IV curves after water vapor exposure with different applied gate voltages. During the adsorption with an applied gate voltage of +20V, the graphene was initially n-doped due to the applied gate voltage; however, the adsorption of water molecules shifted the V_{CNP} in the positive direction and made the graphene less n-doped (FIG. 6A), i.e., water adsorption induced holes in graphene. On the other hand, when the applied gate voltage was kept at −20V during adsorption, the graphene was initially p-doped due to the applied gate voltage; however, the adsorption of water molecules moved the V_{CNP} in the negative direction and made the graphene less p-doped (FIG. 6B), i.e., water adsorption induced electrons in graphene. FIGS. 6C and 6D show the IV curves after water vapor exposure while the gate voltage was kept at 0V during adsorption. In FIG. 6C, the sweeps started and ended at +20V and in FIG. 6D they started and ended at −20V.

FIGS. 8A and 8B shows the voltage driving electrical doping, the shift in the V_{CNP}, the induced doping, and the shift in the Fermi level versus water vapor exposure time. For these calculations, the IV curves were fit to an asymmetric Lorentzian. The shift in the Fermi level was calculated based on:

ΔE_{F}(t)=(−Δn(t))/|Δn(t)|·ℏv_{f}√(π|(Δn(t)|) (1)

where ℏ and ν_{f} are the reduced Planck's constant and the Fermi velocity of graphene, respectively. The doping induced by the molecular adsorption at time t, Δn(t), is equal to:

Δn(t)=(c_{g}/e)[V_{CNP}(t)−V_{CNP}(0)] (2)

where c_{g} is the gate capacitance per unit area, e is the elementary charge, and V_{CNP}(t) represent the charge neutral point voltage at time t.

It is observed that a larger applied gate voltage during water adsorption results in higher doping density, Δn, which is proportional to the water uptake. Nonetheless, the polarity of the gate does not significantly change the amount of adsorbed water, but it does affect the carrier type. This observation demonstrates that electrically doping graphene can result in more hydrophilic surfaces. Moreover, an applied gate voltage at V_{CNP} will make the graphene as hydrophobic as possible. This agrees with the numerical and experimental contact angle measurements of water on electrically doped graphene, where an undoped graphene results in greater water contact angle.

Many dopants fall clearly into one of these two categories: electron-donor molecules that n-dope graphene and electron-acceptor molecules that p-dope; however, the doping induced by water adsorption onto graphene depends on the orientation of the adsorbed water molecule, which is controlled by the electric field at the supporting substrate. The higher electronegativity of oxygen compared to hydrogen in water molecules creates an electrical dipole moment with partial negative charge on the oxygen atom and partial positive charges on the hydrogen atoms. This dipole moment in water molecules affects its adsorption onto graphene.

Depending on the orientation of the adsorbed water molecule, it can either p-dope or n-dope graphene. In a water molecule, the HOMO (Highest Occupied Molecular Orbital) is completely located on the O atom and the LUMO (Lowest Unoccupied Molecular Orbital) is mostly located on the H atoms. Due to the relative positions of the HOMO and the LUMO of a water molecule with respect to the Dirac point, if the O atom points to graphene (O—H bond pointing up), the HOMO plays the dominant role and donates charge from water to graphene through a small mixing with graphene orbitals above the Fermi level, inducing n-doping. If the H atoms point to graphene (O—H bond pointing down), there is a small charge transfer from graphene to the water molecule through a small mixing with the graphene orbitals below the Dirac point that induces p-doping. When the applied gate voltage is greater than the V_{CNP} (V_{GS}>V_{CNP}) the graphene is n-doped and electrons are the dominant charge carriers in graphene, so that water molecules tend to adsorb onto graphene with the positive side of the dipole (H atoms towards graphene), which induces p-doping. Conversely, when the gate voltage is less than the V_{CNP}, the water molecules adsorb onto graphene with the OH bonds upward, which n-dopes graphene.

It is observed that a larger applied gate voltage during water adsorption results in adsorbing more water molecules, i.e., makes the surface more hydrophilic. Nonetheless, the polarity does not significantly change the amount of adsorbed water, but it does affect the carrier type. When the applied gate voltage was bigger than the voltage at the charge neutral point, it created more holes in the valence band (and reduced the number of free electrons in the conduction band) of graphene. On the other hand, when the applied gate voltage was smaller than the voltage at the charge neutral point, it led to more electrons in the conduction band (and less holes in the valance band) of graphene. This observation shows that doping graphene can result in creating more hydrophilic surfaces. In other words, an applied gate voltage closer to V_{CNP} can make graphene more hydrophobic. This agrees with the contact angle measurements of water on electrically doped graphene where an undoped graphene results in larger contact angle of water⁶⁵.

Effect of the Gate Voltage on Doping Rate

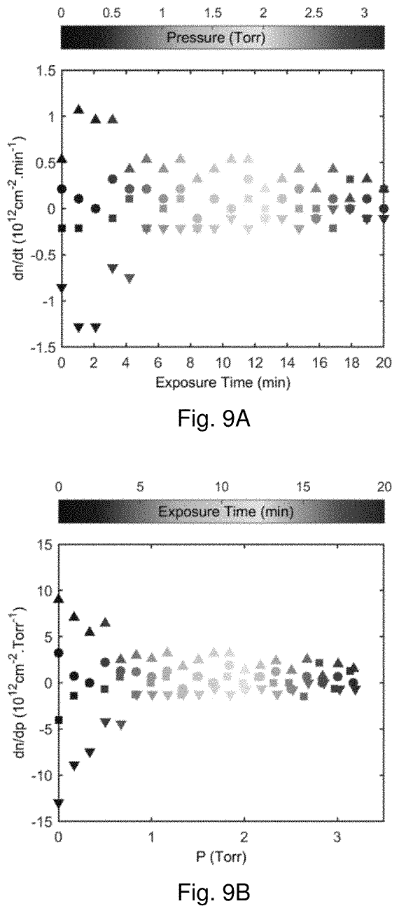

FIGS. 9A and 9B capture the effect of a gate voltage on the kinetics of water adsorption onto graphene in terms of the doping rate vs time (FIG. 9A) and vs pressure (FIG. 9B) upon water exposure. When the gate voltage is larger in magnitude compared to V_{CNP}, i.e., a bigger |V_{GS}-V_{CNP}|, it results in a faster adsorption of water on graphene. This shows that when the Fermi level is further from the Dirac point (either direction), it is more likely for a water molecule to adsorb on graphene because more carriers, independent of the type, will attract more water molecules.

FIG. 9A shows the doping rate versus exposure time for different gate voltages. FIG. 9B shows the change in doping per change in water vapor pressure. Symbols for different gate voltages are the same as in FIGS. 8A and 8B. The kinetics of adsorption are larger in magnitude for the +20V and −20V than the 0V tests.

Conclusions

That electrical doping of graphene can tune water adsorption has been demonstrated. A back-gate graphene field effect transistor was fabricated on a QCM to induce p-doping/n-doping to the graphene by an applied gate voltage. Water adsorption on graphene was studied through adsorption isotherms and IV characterizations. The adsorption isotherms showed an increase in the water uptake for electrically doped graphene. However, the uptake was insensitive to the polarity of the gate. The IV curves measured prior and after water adsorption showed the same trend in the uptake, however, the polarity of the gate changed the type of the induced doping caused by water adsorption. For the gate voltages greater than V_{CNP}, water molecules adsorbed with hydrogen legs down and induced p-doping to the graphene. On the other hand, for voltages less than V_{CNP}, water adsorption tends to induce n-doping in graphene by adsorbing with the hydrogen legs up. Moreover, the calculated induced doping rate by water adsorption showed that an applied electric field can accelerate water adsorption on graphene.

Alternate embodiments of electric field control of surface energetics and kinetics can add an additional material on top of the 2D material, that can further refine the control of adsorption of different molecules. This can be via a surfactant molecule that will align with different functional groups facing outward depending on the applied voltage.

Alternatively, a nanoporous film can coat the surface, and adsorption in that material can be controlled via the adsorbed film.

Alternatively, pores through the device combined with the applied electric field tunability could modify membrane filtration transport. Droplets could also be electrically converted from filmwise to droplets to get a desirable effect, like droplet shedding, or motion of droplets. An array of individually gated regions on a surface, could provide motion control of droplets, as the droplets want to move to more hydrophobic surfaces. In this way, droplets for biomedical or other applications can be steered depending on different conditions. This could be useful for cell sorting or mixing reagents in microfluidics, for instance.

These devices were demonstrated using clean room processes, but alternative embodiments could incorporate liquid/solution-based device fabrication. The dielectrics and 2D material layers could be deposited via spray coated, chemical vapor deposited, or solution casting, for instance. Subsequent films of surfactant can be sprayed, or exist in the solution of interest. Small pinholes from the 2D material to gate can be tolerated if only the wetting properties of interest, though in the experiments discussed above, these were not tolerated because electrical properties were of interest, which would be interfered with in case of pinhole shorts across the dielectrics. The conductive gate electrode could itself be made of a 2D material.

The device formed by the electrical field modulated 2D material film may be interfaced with a computational device. The device may have an electrical field defined by an analog to digital converter or similar driver with an amplifier to achieve the desired voltage range. In devices where an array of film regions, or with spatially modulated patterns, the conductor below the dielectric may be pattered as a set of lines or pads, to define an array or addressable array. For example, the dielectric may be a planarized oxide dielectric over as an integrated circuit which generates fields which influence the 2D material.

The 2D material is preferably graphene, but may also be other types of 2D materials, such as Graphyne, Borophene, Germanene, Silicene, Si2BN, Stanene, Plumbene, Phosphorene, Antimonene, Bismuthene, Metals, Sodium Chloride (NaCl), 2D alloys, 2D supracrystals, Graphane, Hexagonal boron nitride, Borocarbonitrides, Germanane, Transition metal dichalcogenides (TMDs), and MXenes.

Hardware

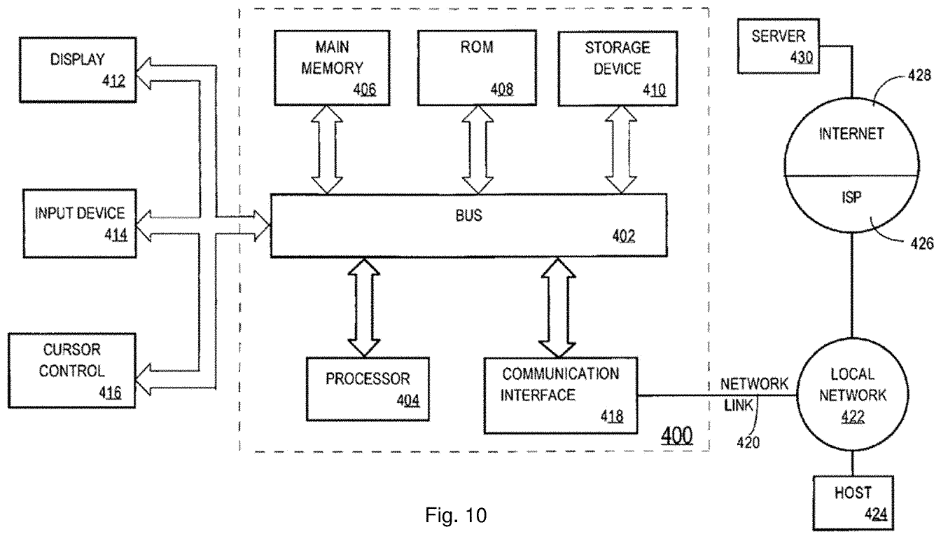

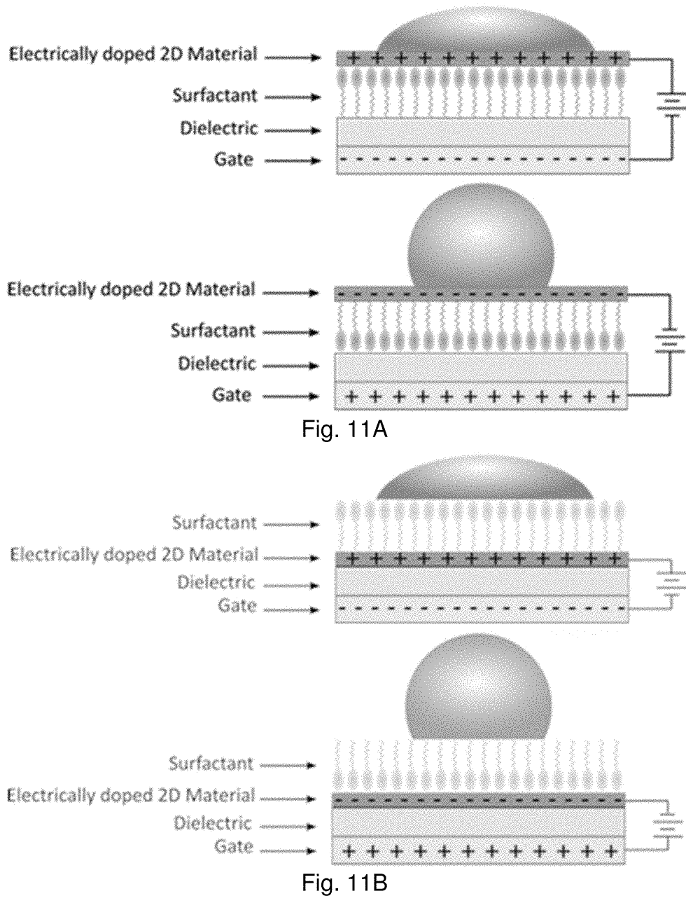

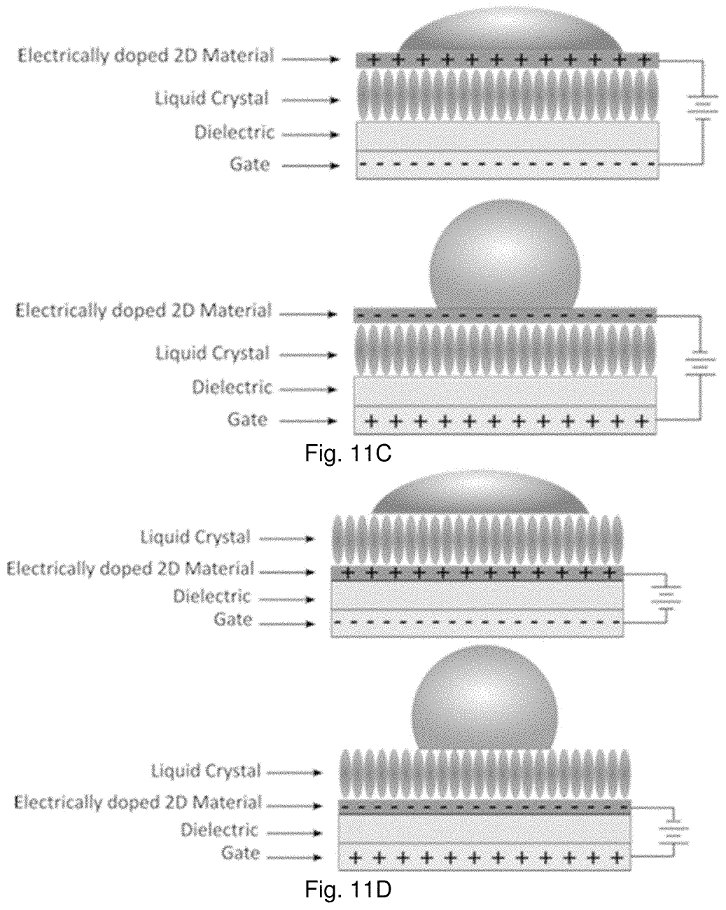

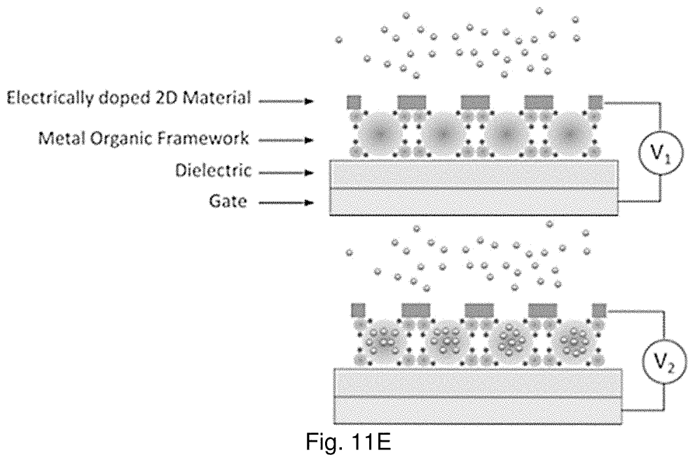

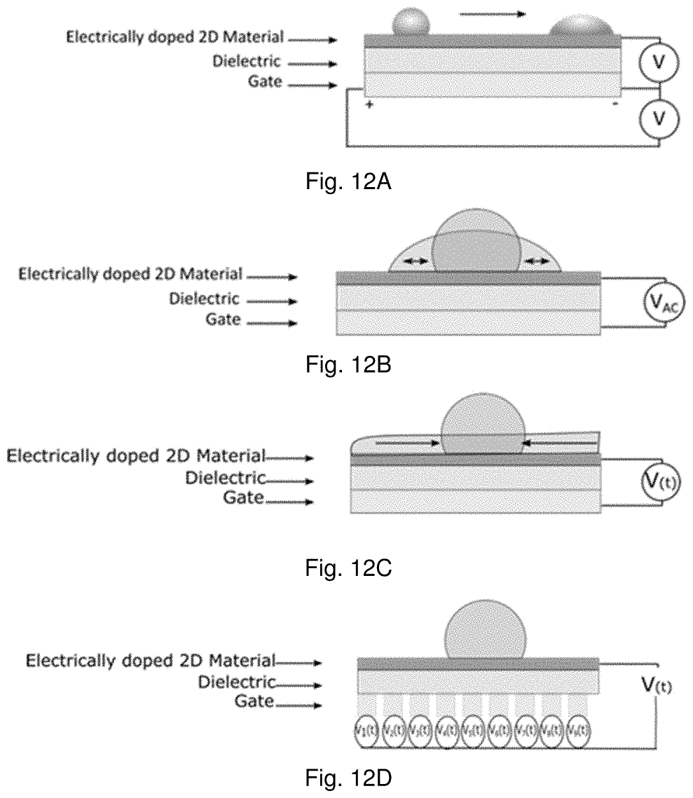

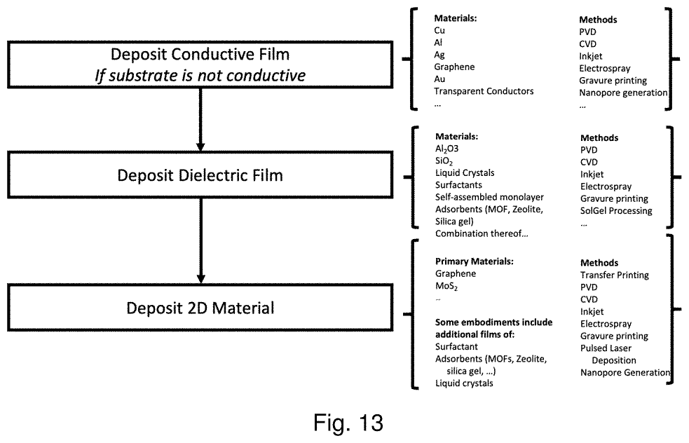

FIG. 10 (see U.S. Pat. 7,702,660, expressly incorporated herein by reference), shows a block diagram that illustrates a computer system 400, that may be used to control the surface modification system. Computer system 400 includes a bus 402 or other communication mechanism for communicating information, and a processor 404 coupled with bus 402 for processing information. Computer system 400 also includes a main memory 406, such as a random access memory (RAM) or other dynamic storage device, coupled to bus 402 for storing information and instructions to be executed by processor 404. Main memory 406 also may be used for storing temporary variables or other intermediate information during execution of instructions to be executed by processor 404. Computer system 400 further includes a read only memory (ROM) 408 or other static storage device coupled to bus 402 for storing static information and instructions for processor 404. A storage device 410, such as a magnetic disk or optical disk, is provided and coupled to bus 402 for storing information and instructions. The computer system may also employ non-volatile memory, such as FRAM and/or MRAM.

The computer system may include a graphics processing unit (GPU), which, for example, provides a parallel processing system which is architected, for example, as a single instruction-multiple data (SIMD) processor. Such a GPU may be used to efficiently compute transforms and other readily parallelized and processed according to mainly consecutive unbranched instruction codes.

Computer system 400 may be coupled via bus 402 to a display 412, such as a liquid crystal display (LCD), for displaying information to a computer user. An input device 414, including alphanumeric and other keys, is coupled to bus 402 for communicating information and command selections to processor 404. Another type of user input device is cursor control 416, such as a mouse, a trackball, or cursor direction keys for communicating direction information and command selections to processor 404 and for controlling cursor movement on display 412. This input device typically has two degrees of freedom in two axes, a first axis (e.g., x) and a second axis (e.g., y), that allows the device to specify positions in a plane.

According to one embodiment of the invention, those techniques are performed by computer system 400 in response to processor 404 executing one or more sequences of one or more instructions contained in main memory 406. Such instructions may be read into main memory 406 from another machine-readable medium, such as storage device 410. Execution of the sequences of instructions contained in main memory 406 causes processor 404 to perform the process steps described herein. In alternative embodiments, hard-wired circuitry may be used in place of or in combination with software instructions to implement the invention. Thus, embodiments of the invention are not limited to any specific combination of hardware circuitry and software.

The term “machine-readable medium” as used herein refers to any medium that participates in providing data that causes a machine to operation in a specific fashion. In an embodiment implemented using computer system 400, various machine-readable media are involved, for example, in providing instructions to processor 404 for execution. Such a medium may take many forms, including but not limited to, non-volatile media, volatile media. Non-volatile media includes, for example, semiconductor devices, optical or magnetic disks, such as storage device 410. Volatile media includes dynamic memory, such as main memory 406. All such media are tangible to enable the instructions carried by the media to be detected by a physical mechanism that reads the instructions into a machine. Common forms of machine-readable media include, for example, hard disk (or other magnetic medium), CD-ROM, DVD-ROM (or other optical or magnetoptical medium), semiconductor memory such as RAM, PROM, EPROM, FLASH-EPROM, any other memory chip or cartridge, a carrier wave as described hereinafter, or any other medium from which a computer can read. Various forms of machine-readable media may be involved in carrying one or more sequences of one or more instructions to processor 404 for execution.

For example, the instructions may initially be carried on a magnetic disk of a remote computer. The remote computer can load the instructions into its dynamic memory and send the instructions over the Internet through an automated computer communication network. An interface local to computer system 400, such as an Internet router, can receive the data and communicate using an Ethernet protocol (e.g., IEEE-802.X) to a compatible receiver, and place the data on bus 402. Bus 402 carries the data to main memory 406, from which processor 404 retrieves and executes the instructions. The instructions received by main memory 406 may optionally be stored on storage device 410 either before or after execution by processor 404.

Computer system 400 also includes a communication interface 418 coupled to bus 402. Communication interface 418 provides a two-way data communication coupling to a network link 420 that is connected to a local network 422. For example, communication interface 418 may be a local area network (LAN) card to provide a data communication connection to a compatible LAN. In any such implementation, communication interface 418 sends and receives electrical, electromagnetic or optical signals that carry digital data streams representing various types of information.

Network link 420 typically provides data communication through one or more networks to other data devices. For example, network link 420 may provide a connection through local network 422 to a host computer 424 or to data equipment operated by an Internet Service Provider (ISP) 426. ISP 426 in turn provides data communication services through the world wide packet data communication network now commonly referred to as the “Internet” 428. Local network 422 and Internet 428 both use electrical, electromagnetic or optical signals that carry digital data streams. The signals through the various networks and the signals on network link 420 and through communication interface 418, which carry the digital data to and from computer system 400, are exemplary forms of carrier waves transporting the information.

Computer system 400 can send messages and receive data, including memory pages, memory sub-pages, and program code, through the network(s), network link 420 and communication interface 418. In the Internet example, a server 430 might transmit a requested code for an application program through Internet 428, ISP 426, local network 422 and communication interface 418. The received code may be executed by processor 404 as it is received, and/or stored in storage device 410, or other non-volatile storage for later execution.

The computer system may be an embedded computer system of an additive manufacturing system, or a separate system, and may be located remote or local. In one embodiment, the computer system is a Raspberry Pi 3 Model B+, executing a real time operating system, such as FreeRTOS. The computer system may also be a laptop computer, e.g., an HP Z-Book 17 G5.

Although the invention(s) have been described with reference to specific embodiments, it will be understood by those skilled in the art that various changes may be made and equivalents may be substituted for elements thereof without departing from the true spirit and scope of the invention. In addition, modifications may be made without departing from the essential teachings of the invention. The invention is described by way of various embodiments and features. This disclosure is intended to encompass all consistent combinations, subcombinations, and permutations of the different options and features, as if expressly set forth herein individually.

### REFERENCES

(1) Kim, H.; Yang, S.; Rao, S. R.; Narayanan, S.; Kapustin, E. A.; Furukawa, H.; Umans, A. S.; Yaghi, O. M.; Wang, E. N. Water Harvesting from Air with Metal-Organic Frameworks Powered by Natural Sunlight. Science 2017, 356 (6336), 430-434. doi.org/10.1126/science.aam8743.

(2) Zhong, L.; Zhu, H.; Wu, Y.; Guo, Z. Understanding How Surface Chemistry and Topography Enhance Fog Harvesting Based on the Superwetting Surface with Patterned Hemispherical Bulges. J. Colloid Interface Sci. 2018, 525, 234-242. doi.org/10.1016/j.jcis.2018.04.061.

(3) Miljkovic, N.; Enright, R.; Nam, Y.; Lopez, K.; Dou, N.; Sack, J.; Wang, E. N. Jumping-Droplet-Enhanced Condensation on Scalable Superhydrophobic Nanostructured Surfaces. Nano Lett. 2013, 13 (1), 179-187. doi.org/10.1021/n1303835d.

(4) Oh, J.; Zhang, R.; Shetty, P. P.; Krogstad, J. A.; Braun, P. V.; Miljkovic, N. Thin Film Condensation on Nanostructured Surfaces. Adv. Funct. Mater. 2018, 28 (16), 1707000. doi.org/10.1002/adfm.201707000.

(5) Wilke, K. L.; Preston, D. J.; Lu, Z.; Wang, E. N. Toward Condensation-Resistant Omniphobic Surfaces. ACS Nano 2018,12 (11), 11013-11021. doi.org/10.1021/acsnano.8b05099.

(6) Kalmutzki, M. J.; Diercks, C. S.; Yaghi, O. M. Metal-Organic Frameworks for Water Harvesting from Air. Adv. Mater. 2018, 30 (37), 1704304. doi.org/10.1002/adma.201704304.

(7) Fürstner, R.; Barthlott, W.; Neinhuis, C.; Walzel, P. Wetting and Self-Cleaning Properties of Artificial Superhydrophobic Surfaces. Langmuir 2005, 21 (3), 956-961. doi.org/10.1021/la0401011.

(8) Jung, Y. C.; Bhushan, B. Mechanically Durable Carbon Nanotube-Composite Hierarchical Structures with Superhydrophobicity, Self-Cleaning, and Low-Drag. ACS Nano 2009, 3 (12), 4155-4163. doi.org/10.1021/nn901509r.

(9) Bagheri, M. H.; Schiffres, S. N. Ideal Adsorption Isotherm Behavior for Cooling Applications. Langmuir 2018, 34 (5), 1908-1915. doi.org/10.1021/acs.langmuir.7b03989.

(10) Jiang, Y.; Bagheri, M. H.; Loibl, R. T.; Schiffres, S. N. Thermodynamic Limits of Adsorption Heat Pumps: A Facile Method of Comparing Adsorption Pairs. Appl. Therm. Eng. 2019, 160, 113906. doi.org/10.1016/j.applthermaleng.2019.113906.

(11) LaPotin, A.; Kim, H.; Rao, S. R.; Wang, E. N. Adsorption-Based Atmospheric Water Harvesting: Impact of Material and Component Properties on System-Level Performance. Acc. Chem. Res. 2019, 52 (6), 1588-1597. doi.org/10.1021/acs.accounts.9b00062.

(12) Department of Energy Releases Water-Energy Nexus Report www.energy.gov/articles/department-energy-releases-water-energy-nexus-report (accessed 2021 Apr. 2).

(13) Ensuring the Resiliency of Our Future Water and Energy Systems www.energy.gov/articles/ensuring-resiliency-our-future-water-and-energy-systems (accessed 2021 Apr. 2).

(14) Commodities flowcharts.llnl.gov/commodities (accessed 2021 Apr. 2).

(15) Varanasi, K. K.; Hsu, M.; Bhate, N.; Yang, W.; Deng, T. Spatial Control in the Heterogeneous Nucleation of Water. Appl. Phys. Lett. 2009, 95 (9), 094101. doi.org/10.1063/1.3200951.

(16) Ellsworth, M. J.; Campbell, L. A.; Simons, R. E.; Iyengar, M. K.; Schmidt, R. R.; Chu, R. C. The Evolution of Water Cooling for IBM Large Server Systems: Back to the Future. In 2008 11th Intersociety Conference on Thermal and Thermomechanical Phenomena in Electronic Systems; 2008; pp 266-274. doi.org/10.1109/ITHERM.2008.4544279.

(17) Bar-Cohen, A.; Albrecht, J. D.; Maurer, J. J. Near-Junction Thermal Management for Wide Bandgap Devices. In 2011 IEEE Compound Semiconductor Integrated Circuit Symposium (CSICS); 2011; pp 1-5. doi.org/10.1109/CSICS.2011.6062454.

(18) Garven, M.; Calame, J. P. Simulation and Optimization of Gate Temperatures in GaN-on-SiC Monolithic Microwave Integrated Circuits. IEEE Trans. Compon. Packag. Technol. 2009, 32 (1), 63-72. doi.org/10.1109/TCAPT.2008.2004586.

(19) Yoonjin Won; Jungwan Cho; Agonafer, D.; Asheghi, M.; Goodson, K. E. Fundamental Cooling Limits for High Power Density Gallium Nitride Electronics. IEEE Trans. Compon. Packag. Manuf. Technol. 2015, 5 (6), 737-744. doi.org/10.1109/TCPMT.2015.2433132.

(20) Yang, B.; Wang, P.; Bar-Cohen, A. Thermoelectric Mini-Contact Cooler for Hot-Spot Removal in High Power Devices. In 56th Electronic Components and Technology Conference 2006; 2006; p 6 pp.-. doi.org/10.1109/ECTC.2006.1645775.

(21) Foulkes, T.; Oh, J.; Birbarah, P.; Neely, J.; Miljkovic, N.; Pilawa-Podgurski, R. C. N. Active Hot Spot Cooling of GaN Transistors with Electric Field Enhanced Jumping Droplet Condensation. In 2017 IEEE Applied Power Electronics Conference and Exposition (APEC); 2017; pp 912-918. doi.org/10.1109/APEC.2017.7930805.

(22) Moghaddam, S.; Rada, M.; Shooshtari, A.; Ohadi, M.; Joshi, Y. Evaluation of Analytical Models for Thermal Analysis and Design of Electronic Packages. Microelectron. J. 2003, 34 (3), 223-230. doi.org/10.1016/S0026-2692(02)00192-1.

(23) Faghri, A. Heat Pipe Science And Technology; Global Digital Press, 1995.

(24) Hale, R. S.; Ranjan, R.; Hidrovo, C. H. Capillary Flow through Rectangular Micropillar Arrays. Int. J. Heat Mass Transf. 2014, 75, 710-717. doi.org/10.1016/j.ijheatmasstransfer.2014.04.016.

(25) Hale, R. S.; Bahadur, V. Characterization of Microfluidic Operations Underlying an Electrowetting Heat Pipe. In 2017 16th IEEE Intersociety Conference on Thermal and Thermomechanical Phenomena in Electronic Systems (ITherm); 2017; pp 610-614. doi.org/10.1109/ITHERM.2017.7992543.

(26) Chatterjee, A.; Derby, M. M.; Peles, Y.; Jensen, M. K. Enhancement of Condensation Heat Transfer with Patterned Surfaces. Int. J. Heat Mass Transf. 2014, 71, 675-681. doi.org/10.1016/j.ijheatmasstransfer.2013.12.069.

(27) Peters, T. B.; McCarthy, M.; Allison, J.; Dominguez-Espinosa, F. A.; Jenicek, D.; Kariya, H. A.; Staats, W. L.; Brisson, J. G.; Lang, J. H.; Wang, E. N. Design of an Integrated Loop Heat Pipe Air-Cooled Heat Exchanger for High Performance Electronics. IEEE Trans. Compon. Packag. Manuf. Technol. 2012, 2 (10), 1637-1648. doi.org/10.1109/TCPMT.2012.2207902.

(28) Ghajar, M.; Darabi, J.; Crews, N. A Hybrid CFD-Mathematical Model for Simulation of a MEMS Loop Heat Pipe for Electronics Cooling Applications. J. Micromechanics Microengineering 2005, 15 (2), 313-321. doi.org/10.1088/0960-1317/15/2/010.

(29) Oshman, C.; Li, Q.; Liew, L.-A.; Yang, R.; Bright, V. M.; Lee, Y. C. Flat Flexible Polymer Heat Pipes. J. Micromechanics Microengineering 2013, 23 (1), 015001. doi.org/10.1088/0960-1317/23/1/015001.

(30) Udell, K. S. Heat Transfer in Porous Media Considering Phase Change and Capillarity—the Heat Pipe Effect. Int. J. Heat Mass Transf. 1985, 28 (2), 485-495. doi.org/10.1016/0017-9310(85)90082-1.

(31) Boreyko, J. B.; Chen, C.-H. Vapor Chambers with Jumping-Drop Liquid Return from Superhydrophobic Condensers. Int. J. Heat Mass Transf. 2013, 61, 409-418. doi.org/10.1016/j.ijheatmasstransfer.2013.01.077.

(32) Wiedenheft, K. F.; Guo, H. A.; Qu, X.; Boreyko, J. B.; Liu, F.; Zhang, K.; Eid, F.; Choudhury, A.; Li, Z.; Chen, C.-H. Hotspot Cooling with Jumping-Drop Vapor Chambers. Appl. Phys. Lett. 2017, 110 (14), 141601. doi.org/10.1063/1.4979477.

(33) Plawsky, J. L. Transport Phenomena Fundamentals, Third Edition; CRC Press, 2014.

(34) Pham, Q. N.; Shao, B.; Kim, Y.; Won, Y. Hierarchical and Well-Ordered Porous Copper for Liquid Transport Properties Control. ACS Appl. Mater. Interfaces 2018, 10 (18), 16015-16023. doi.org/10.1021/acsami.8b02665.

(35) Clegg, N.; Kota, K.; He, X.; Ross, S. Achieving Ultra-Omniphilic Wettability on Copper Using a Facile, Scalable, Tuned Bulk Micromanufacturing Approach. J. Micro Nano-Manuf. 2017, 5 (3), 031003-031003-031007. doi.org/10.1115/1.4036446.

(36) Attinger, D.; Frankiewicz, C.; Betz, A. R.; Schutzius, T. M.; Ganguly, R.; Das, A.; Kim, C.-J.; Megaridis, C. M. Surface Engineering for Phase Change Heat Transfer: A Review. MRS Energy Sustain. 2014, 1. doi.org/10.1557/mre.2014.9.

(37) Mueller, S.; Hodes, M.; Lyons, A. Capillary-Driven Evaporation-Enhanced Heat Sink. IEEE Trans. Compon. Packag. Manuf. Technol. 2013, 3 (10), 1683-1692. doi.org/10.1109/TCPMT.2013.2253157.

(38) Lee, M.; Park, C. Mechanical-Capillary-Driven Two-Phase Loop: Numerical Modeling and Experimental Validation. Int. J. Heat Mass Transf. 2018, 125, 972-982. doi.org/10.1016/j.ijheatmasstransfer.2018.04.144.

(39) Rahman, M. M.; Ölçeroğlu, E.; McCarthy, M. Role of Wickability on the Critical Heat Flux of Structured Superhydrophilic Surfaces. Langmuir 2014, 30 (37), 11225-11234. doi.org/10.1021/la5030923.

(40) YD, S.; Maroo, S. C. Origin of Surface-Driven Passive Liquid Flows. Langmuir 2016, 32 (34), 8593-8597. doi.org/10.1021/acs.langmuir.6b02117.

(41) Zou, A.; Maroo, S. C. Critical Height of Micro/Nano Structures for Pool Boiling Heat Transfer Enhancement. Appl. Phys. Lett. 2013, 103 (22), 221602. doi.org/10.1063/1.4833543.

(42) Gunay, A. A.; Sett, S.; Oh, J.; Miljkovic, N. Steady Method for the Analysis of Evaporation Dynamics. Langmuir 2017, 33 (43), 12007-12015. doi.org/10.1021/acs.langmuir.7b02821.

(43) Fazeli, A.; Mortazavi, M.; Moghaddam, S. Hierarchical Biphilic Micro/Nanostructures for a New Generation Phase-Change Heat Sink. Appl. Therm. Eng. 2015, 78, 380-386. doi.org/10.1016/j.applthermaleng.2014.12.073.

(44) Li, Y.; Alibakhshi, M. A.; Zhao, Y.; Duan, C. Exploring Ultimate Water Capillary Evaporation in Nanoscale Conduits. Nano Lett. 2017, 17 (8), 4813-4819. doi.org/10.1021/acs.nanolett.7b01620.

(45) Mehrvand, M.; Putnam, S. A. Probing the Local Heat Transfer Coefficient of Water-Cooled Microchannels Using Time-Domain Thermoreflectance. J. Heat Transf. 2017, 139 (11), 112403. doi.org/10.1115/1.4036691.

(46) Haque, M. R.; Betz, A. R. Heat Transfer Enhancement by Insertion of Vortex Generators in Electronic Chip Cooling: A Numerical Study; ASME, 2017; p V001T05A001. doi.org/10.1115/ICNMM2017-5523.

(47) Kandlikar, S. G. Controlling Bubble Motion over Heated Surface through Evaporation Momentum Force to Enhance Pool Boiling Heat Transfer. Appl. Phys. Lett. 2013, 102 (5), 051611. doi.org/10.1063/1.4791682.

(48) Sahu, V.; Joshi, Y. K.; Fedorov, A. G.; Bahk, J.-H.; Wang, X.; Shakouri, A. Experimental Characterization of Hybrid Solid-State and Fluidic Cooling for Thermal Management of Localized Hotspots. IEEE Trans. Compon. Packag. Manuf. Technol. 2015, 5 (1), 57-64. doi.org/10.1109/TCPMT.2014.2332516.

(49) Knight, R. W.; Hall, D. J.; Goodling, J. S.; Jaeger, R. C. Heat Sink Optimization with Application to Microchannels. IEEE Trans. Compon. Hybrids Manuf. Technol. 1992, 15 (5), 832-842. doi.org/10.1109/33.180049.

(50) McCarthy, M.; Gerasopoulos, K.; Maroo, S. C.; Hart, A. J. Materials, Fabrication, and Manufacturing of Micro/Nanostructured Surfaces for Phase-Change Heat Transfer Enhancement. Nanoscale Microscale Thermophys. Eng. 2014, 18 (3), 288-310. doi.org/10.1080/15567265.2014.926436.

(51) Iverson, B. D.; Davis, T. W.; Garimella, S. V.; North, M. T.; Kang, S. S. Heat and Mass Transport in Heat Pipe Wick Structures. J. Thermophys. Heat Transf. 2007, 21 (2), 392-404. doi.org/10.2514/1.25809.

(52) Bigham, S.; Moghaddam, S. Microscale Study of Mechanisms of Heat Transfer during Flow Boiling in a Microchannel. Int. J. Heat Mass Transf. 2015, 88, 111-121. doi.org/10.1016/j.ijheatmasstransfer.2015.04.034.

(53) Krishnan, S.; Hernon, D.; Hodes, M.; Mullins, J.; Lyons, A. M. Design of Complex Structured Monolithic Heat Sinks for Enhanced Air Cooling. IEEE Trans. Compon. Packag. Manuf. Technol. 2012, 2 (2), 266-277. doi.org/10.1109/TCPMT.2011.2175448.

(54) Rattner, A. S. General Characterization of Jet Impingement Array Heat Sinks With Interspersed Fluid Extraction Ports for Uniform High-Flux Cooling. J. Heat Transf. 2017, 139 (8), 082201. doi.org/10.1115/1.4036090.

(55) Fronk, B. M.; Rattner, A. S. High-Flux Thermal Management With Supercritical Fluids. J. Heat Transf. 2016, 138 (12), 124501-124501-124504. doi.org/10.1115/1.4034053.

(56) F. Machado, B.; Serp, P. Graphene-Based Materials for Catalysis. Catal. Sci. Technol. 2012, 2 (1), 54-75. doi.org/10.1039/C1CY00361E.

(57) Preston, D. J.; Mafra, D. L.; Miljkovic, N.; Kong, J.; Wang, E. N. Scalable Graphene Coatings for Enhanced Condensation Heat Transfer. Nano Lett. 2015, 15 (5), 2902-2909. doi.org/10.1021/n1504628s.

(58) Sato, Y.; Takai, K.; Enoki, T. Electrically Controlled Adsorption of Oxygen in Bilayer Graphene Devices. Nano Lett. 2011, 11 (8), 3468-3475. doi.org/10.1021/nl202002p.

(59) Baldwin, J. W.; Matis, B. R.; Burgess, J. S.; Bulat-Jara, F.; Friedman, A. L.; Houston, B. H. Surface Doping and Bandgap Tunability in Hydrogenated Graphene. U.S. Pat. No. 9,312,130B2, Apr. 12,2016.

(60) Chiu, U.-T.; Lee, B.-F.; Hu, S.-K.; Yu, T.-F.; Lee, W.-Y.; Chao, L. Graphene Memory Based on a Tunable Nanometer-Thin Water Layer. J. Phys. Chem. C 2019, 123 (17), 10842-10848. doi.org/10.1021/acs.jpcc.8b10804.

(61) Krupenkin, T.; Taylor, J. A.; Wang, E. N.; Kolodner, P.; Hodes, M.; Salamon, T. R. Reversible Wetting-Dewetting Transitions on Electrically Tunable Superhydrophobic

Nanostructured Surfaces. Langmuir ACS J. Surf Colloids 2007, 23 (18), 9128-9133. doi.org/10.1021/la7008557.

(62) Xia, F.; Zhu, Y.; Feng, L.; Jiang, L. Smart Responsive Surfaces Switching Reversibly between Super-Hydrophobicity and Super-Hydrophilicity. Soft Matter 2009, 5 (2), 275-281. doi.org/10.1039/B803951H.

(63) Wang, S.; Liu, K.; Yao, X.; Jiang, L. Bioinspired Surfaces with Superwettability: New Insight on Theory, Design, and Applications. Chem. Rev. 2015, 115 (16), 8230-8293. doi.org/10.1021/cr400083y.

(64) Li, X.; Jiang, Y.; Jiang, Z.; Li, Y.; Wen, C.; Lian, J. Reversible Wettability Transition between Superhydrophilicity and Superhydrophobicity through Alternate Heating-Reheating Cycle on Laser-Ablated Brass Surface. Appl. Surf. Sci. 2019, 492, 349-361. doi.org/10.1016/j.apsusc.2019.06.145.

(65) Hong, G.; Han, Y.; Schutzius, T. M.; Wang, Y.; Pan, Y.; Hu, M.; Jie, J.; Sharma, C. S.; Muller, U.; Poulikakos, D. On the Mechanism of Hydrophilicity of Graphene. Nano Lett. 2016, 16 (7), 4447-4453. doi.org/10.1021/acs.nanolett.6b01594.

(66) Ashraf, A.; Wu, Y.; Wang, M. C.; Yong, K.; Sun, T.; Jing, Y.; Haasch, R. T.; Alum, N. R.; Nam, S. Doping-Induced Tunable Wettability and Adhesion of Graphene. Nano Lett. 2016, 16 (7), 4708-4712. doi.org/10.1021/acs.nanolett.6b02228.

(67) Azizi, A.; Daeumer, M. A.; Schiffres, S. N. Additive Laser Metal Deposition onto Silicon. Addit. Manuf. 2019, 25, 390-398. doi.org/10.1016/j.addma.2018.09.027.

(68) Azizi, A.; Schiffres, S. N. Laser Metal Additive Manufacturing on Graphite. In Solid Freeform Fabrication Symposium; Austin, Tex., 2018; pp 1-10.

(69) Bagheri, M. H.; Loibl, R. T.; Boscoboinik, J. A.; Schiffres, S. N. Adsorption Transparency of Supported Graphene. Carbon 2019 155, 508. doi.org/10.1016/j.carbon.2019.08.083.

(70) Vargas, V. C.; Bejan, A. Optimisation of Film Condensation with Periodic Wall Cleaning. 8.

(71) Li, H.; Chen, Y.; Wang, H.; Wang, H.; Li, Y.; Harran, I.; Li, Y.; Guo, C. First-Principles Study of Mechanical and Thermodynamic Properties of Ti—Ga Intermetallic Compounds. J. Alloys Compd. 2017, 700, 208-214. doi.org/10.1016/j.jallcom.2017.01.052.

(72) Fleischer, R. L. High-Strength, High-Temperature Intermetallic Compounds. J. Mater. Sci. 1987, 22 (7), 2281-2288. doi.org/10.1007/BF01082105.

(73) Lucas, M. S.; Muñoz, J. A.; Mauger, L.; Li, C. W.; Sheets, A. O.; Turgut, Z.; Horwath, J.; Abernathy, D. L.; Stone, M. B.; Delaire, O.; Xiao, Y.; Fultz, B. Effects of Chemical Composition and B2 Order on Phonons in Bcc Fe—Co Alloys. J. Appl. Phys. 2010, 108 (2), 023519. doi.org/10.1063/1.3456500.

(74) Muñoz, J. A.; Lucas, M. S.; Delaire, O.; Winterrose, M. L.; Mauger, L.; Li, C. W.; Sheets, A. O.; Stone, M. B.; Abernathy, D. L.; Xiao, Y.; Chow, P.; Fultz, B. Positive Vibrational Entropy of Chemical Ordering in FeV. Phys. Rev. Lett. 2011, 107 (11). doi.org/10.1103/PhysRevLett.107.115501.

(75) Kittel, C. Introduction to Solid State Physics, 8th ed.; John Wiley & Sons, 2005.

(76) Chen, G. Nanoscale Energy Transport and Conversion; Oxford University Press, New York, 2005.

(77) Ashcroft, N. W.; Mermin, N. D. Solid State Physics (Saunders College, Philadelphia, 1976). Google Sch. 2010, 461.

(78) Swartz, E. T.; Pohl, R. O. Thermal Boundary Resistance. Rev. Mod. Phys. 1989, 61 (3), 605-668.

(79) Monachon, C.; Weber, L.; Dames, C. Thermal Boundary Conductance: A Materials Science Perspective. Annu. Rev. Mater. Res. 2016, 46 (1), 433-463. doi.org/10.1146/annurev-matsci-070115-031719.

(80) Chen, Z.; Wei, Z.; Chen, Y.; Dames, C. Anisotropic Debye Model for the Thermal Boundary Conductance. Phys. Rev. B 2013, 87 (12). doi.org/10.1103/PhysRevB.87.125426.

(81) Duda, J. C.; Hopkins, P. E.; Smoyer, J. L.; Bauer, M. L.; English, T. S.; Saltonstall, C. B.; Norris, P. M. On the Assumption of Detailed Balance in Prediction of Diffusive Transmission Probability during Interfacial Transport. Nanoscale Microscale Thermophys. Eng. 2010, 14 (1), 21-33.

(82) Reddy, P.; Castelino, K.; Majumdar, A. Diffuse Mismatch Model of Thermal Boundary Conductance Using Exact Phonon Dispersion. Appl. Phys. Lett. 2005, 87 (21), 211908. doi.org/10.1063/1.2133890.

(83) Klemens, P. G.; Williams, R. K. Thermal Conductivity of Metals and Alloys. Int. Met. Rev. 1986, 31 (1), 197-215. doi.org/10.1179/imtr.1986.31.1.197.

(84) Kolenak, R.; Kostolný, I.; Sahul, M. Direct Bonding of Silicon with Solders Type Sn—Ag—Ti. Solder. Surf. Mt. Technol. 2016, 28 (3), 149-158. doi.org/10.1108/SSMT-11-2015-0040.

(85) Smith, R. W. Process of Using an Active Solder Alloy. U.S. Pat. No. 6,047,876A, Apr. 11, 2000.

(86) Tang, Y.; Li, G. Thermodynamic Study of Sn—Ag—Ti Active Filler Metals. Phys. Procedia 2012, 25, 30-35. doi.org/10.1016/j.phpro.2012.03.045.

(87) Neshpor, V. S. The Thermal Conductivity of the Silicides of Transition Metals. J. Eng. Phys. 1968, 15 (2), 750-752. doi.org/10.1007/BF00829703.

(88) La Via, F.; Roccaforte, F.; Makhtari, A.; Raineri, V.; Musumeci, P.; Calcagno, L. Structural and Electrical Characterisation of Titanium and Nickel Silicide Contacts on Silicon Carbide. Microelectron. Eng. 2002, 60 (1), 269-282. doi.org/10.1016/S0167-9317(01)00604-9.

(89) Beyers, R.; Sinclair, R. Metastable Phase Formation in Titanium-silicon Thin Films. J. Appl. Phys. 1985, 57 (12), 5240-5245. doi.org/10.1063/1.335263.

(90) Sonoda, T.; Nakao, S.; Ikeyama, M. Effects of Substrate Temperature on Ti—Si—C Thin Film Deposited by Sputtering Using Elemental Targets. J. Phys. Conf. Ser. 2013, 417, 012063. doi.org/10.1088/1742-6596/417/1/012063.

(91) Wiand, R. C. Brazing of Diamond. U.S. Pat. No. 4,776,862A, Oct. 11, 1988.

(92) Li, W.-C.; Lin, S.-T.; Liang, C. Interfacial Segregation of Ti in the Brazing of Diamond Grits onto a Steel Substrate Using a Cu—Sn—Ti Brazing Alloy. Metall. Mater. Trans. A 2002, 33 (7), 2163-2172. doi.org/10.1007/s11661-002-0048-y.

(93) Predel, B. Ga—Zr (Gallium-Zirconium). In Ga—Gd—Hf—Zr; Landolt-Börnstein—Group IV Physical Chemistry; Springer, Berlin, Heidelberg; pp 1-2. doi.org/10.1007/10501684_1417.

(94) Predel, B. Ga—V (Gallium-Vanadium). In Ga—Gd—Hf—Zr; Landolt-Börnstein—Group IV Physical Chemistry; Springer, Berlin, Heidelberg; pp 1-3. doi.org/10.1007/10501684_1412.

(95) Balaji Kale, G.; Bhanumurthy, K.; Parakash Garg, S.; Materials Science International Team, M.; Effenberg, G. Ga—Ta Binary Phase Diagram Evaluation ⋅ Phase Diagrams, Crystallographic and Thermodynamic Data: Datasheet from MSI Eureka in SpringerMaterials; MSI Materials Science International Services GmbH.

(96) Kruth, J. P.; Froyen, L.; Van Vaerenbergh, J.; Mercelis, P.; Rombouts, M.; Lauwers, B. Selective Laser Melting of Iron-Based Powder. J. Mater. Process. Technol. 2004, 149 (1-3), 616-622. doi.org/10.1016/j.jmatprotec.2003.11.051.

(97) J. P. Kruth; X. Wang; T. Laoui; L. Froyen. Lasers and Materials in Selective Laser Sintering. Assem. Autom. 2003, 23 (4), 357-371. doi.org/10.1108/01445150310698652.

(98) Thijs, L.; Verhaeghe, F.; Craeghs, T.; Humbeeck, J. V.; Kruth, J.-P. A Study of the Microstructural Evolution during Selective Laser Melting of Ti-6Al-4V. Acta Mater. 2010, 58 (9), 3303-3312. doi.org/10.1016/j.actamat.2010.02.004.

(99) Beuth, J.; Klingbeil, N. The Role of Process Variables in Laser-Based Direct Metal Solid Freeform Fabrication. JOM 2001, 53 (9), 36-39. doi.org/10.1007/s11837-001-0067-y.

(100) Gockel, J.; Beuth, J.; Taminger, K. Integrated Control of Solidification Microstructure and Melt Pool Dimensions in Electron Beam Wire Feed Additive Manufacturing of Ti-6Al-4V. Addit. Manuf. 2014, 1-4, 119-126. doi.org/10.1016/j.addma.2014.09.004.

(101) Roy, N. K.; Dibua, O. G.; Jou, W.; He, F.; Jeong, J.; Wang, Y.; Cullinan, M. A. A Comprehensive Study of the Sintering of Copper Nanoparticles Using Femtosecond, Nanosecond, and Continuous Wave Lasers. J. Micro Nano-Manuf. 2017, 6 (1), 010903-010903-010921. doi.org/10.1115/1.4038455.

(102) Gao, F.; Yin, Q.; Wang, J.; Zhou, G.; Gu, Z. Synthesis and Characterization of One-Dimensional Cu—Sn Nanowire Diffusion Couples for Nanowire Assembly and Interconnection. In 2016 IEEE 66th Electronic Components and Technology Conference (ECTC); 2016; pp 2329-2334. doi.org/10.1109/ECTC.2016.101.

(103) Yin, Q.; Gao, F.; Gu, Z.; Wang, J.; Stach, E. A.; Zhou, G. Interface Dynamics in One-Dimensional Nanoscale Cu/Sn Couples. Acta Mater. 2017, 125, 136-144. doi.org/10.1016/j.actamat.2016.11.051.

(104) Yin, Q.; Gao, F.; Gu, Z.; A. Stach, E.; Zhou, G. In Situ Visualization of Metallurgical Reactions in Nanoscale Cu/Sn Diffusion Couples. Nanoscale 2015, 7 (11), 4984-4994. doi.org/10.1039/C4NR06757F.

(105) Saiz, E.; Tomsia, A. P. Atomic Dynamics and Marangoni Films during Liquid-Metal Spreading. Nat. Mater. 2004, 3 (12), 903-909. doi.org/10.1038/nmat1252.

(106) Eustathopoulos, N.; Nicholas, M. G.; Drevet, B. Wettability at High Temperatures, 1st ed.; Pergamon materials series; Pergamon: Amsterdam; New York, 1999.

(107) Saiz, E.; Tomsia, A. P.; Cannon, R. M. Ridging Effects on Wetting and Spreading of Liquids on Solids. Acta Mater. 1998, 46 (7), 2349-2361. doi.org/10.1016/S1359-6454(98)80016-5.

(108) Landry, K.; Rado, C.; Voitovich, R.; Eustathopoulos, N. Mechanisms Of Reactive Wetting: The Question Of Triple Line Configuration. Acta Mater. 1997, 45 (7), 3079-3085. doi.org/10.1016/S1359-6454(96)00372-2.

(109) Mullin, J. W. Crystallization, Third Ed.; Butterworth Heinemann: Oxford, 1997.

(110) Khairallah, S. A.; Anderson, A. Mesoscopic Simulation Model of Selective Laser Melting of Stainless Steel Powder. J. Mater. Process. Technol. 2014, 214 (11), 2627-2636. doi.org/10.1016/j.jmatprotec.2014.06.001.

(111) Khairallah, S. A.; Anderson, A. T.; Rubenchik, A.; King, W. E. Laser Powder-Bed Fusion Additive Manufacturing: Physics of Complex Melt Flow and Formation Mechanisms of Pores, Spatter, and Denudation Zones. Acta Mater. 2016, 108, 36-45. doi.org/10.1016/j.actamat.2016.02.014.

(112) Eagar, T. W.; Tsai, N. S. Temperature Fields Produced by Traveling Distributed Heat Sources. Weld. J. 1983, 62 (12), 346-s-355-s.

(113) Schmidt, A. J.; Cheaito, R.; Chiesa, M. A Frequency-Domain Thermoreflectance Method for the Characterization of Thermal Properties. Rev. Sci. Instrum. 2009, 80 (9), 094901. doi.org/10.1063/1.3212673.

(114) Schmidt, A. J.; Cheaito, R.; Chiesa, M. Characterization of Thin Metal Films via Frequency-Domain Thermoreflectance. J. Appl. Phys. 2010, 107 (2), 024908. doi.org/10.1063/1.3289907.

(115) Majumdar, S.; Sierra-Suarez, J. A.; Schiffres, S. N.; Ong, W.-L.; Higgs, C. F.; McGaughey, A. J. H.; Malen, J. A. Vibrational Mismatch of Metal Leads Controls Thermal Conductance of Self-Assembled Monolayer Junctions. Nano Lett. 2015, 15 (5), 2985-2991. doi.org/10.1021/n1504844d.

(116) Landry, E. S.; McGaughey, A. J. H. Effect of Interfacial Species Mixing on Phonon Transport in Semiconductor Superlattices. Phys Rev B 2009, 79 (7), 75316. doi.org/Artn 075316 Doi 10.1103/Physrevb.79.075316.

(117) Jain, A.; McGaughey, A. J. H. Thermal Transport by Phonons and Electrons in Aluminum, Silver, and Gold from First Principles. Phys. Rev. B 2016, 93 (8), 081206. doi.org/10.1103/PhysRevB.93.081206.

(118) Larkin, J. M.; McGaughey, A. J. H. Predicting Alloy Vibrational Mode Properties Using Lattice Dynamics Calculations, Molecular Dynamics Simulations, and the Virtual Crystal Approximation. J. Appl. Phys. 2013, 114 (2), 023507. doi.org/10.1063/1.4812737.

(119) Majumdar, A.; Reddy, P. Role of Electron—Phonon Coupling in Thermal Conductance of Metal—Nonmetal Interfaces. Appl. Phys. Lett. 2004, 84 (23), 4768-4770.

(120) Chen, Z.; Wei, Z.; Chen, Y.; Dames, C. Anisotropic Debye Model for the Thermal Boundary Conductance. Phys. Rev. B 2013, 87 (12). doi.org/10.1103/PhysRevB.87.125426.

(121) Monachon, C.; Weber, L. Effect of Diamond Surface Orientation on the Thermal Boundary Conductance between Diamond and Aluminum. Diam. Relat. Mater. 2013, 39, 8-13. doi.org/10.1016/j.diamond.2013.06.017.

(122) Hopkins, P. E.; Beechem, T.; Duda, J. C.; Hattar, K.; Ihlefeld, J. F.; Rodriguez, M. A.; Piekos, E. S. Influence of Anisotropy on Thermal Boundary Conductance at Solid Interfaces. Phys. Rev. B 2011, 84 (12), 125408. doi.org/10.1103/PhysRevB.84.125408.

(123) Norris, P. M.; Smoyer, J. L.; Duda, J. C.; Hopkins, P. E. Prediction and Measurement of Thermal Transport Across Interfaces Between Isotropic Solids and Graphitic Materials. J. Heat Transf. 2012, 134 (2), 020910. doi.org/10.1115/1.4004932.

(124) Schmidt, A. J.; Collins, K. C.; Minnich, A. J.; Chen, G. Thermal Conductance and Phonon Transmissivity of Metal—Graphite Interfaces. J. Appl. Phys. 2010, 107 (10), 104907. doi.org/10.1063/1.3428464.

(125) Lyeo, H.-K.; Cahill, D. G. Thermal Conductance of Interfaces between Highly Dissimilar Materials. Phys. Rev. B 2006, 73 (14). doi.org/10.1103/PhysRevB.73.144301.

(126) Klemens, P. G. The Electrical and Thermal Conductivities of Monovalent Metals. Aust. J. Phys. 1954, 7 (1), 70-76. doi.org/10.1071/ph540070.

(127) Losego, M. D.; Grady, M. E.; Sottos, N. R.; Cahill, D. G.; Braun, P. V. Effects of Chemical Bonding on Heat Transport across Interfaces. Nat Mater 2012, advance online publication. doi.org/10.1038/nmat3303.

(128) Hopkins, P. E.; Duda, J. C.; Petz, C. W.; Floro, J. A. Controlling Thermal Conductance through Quantum Dot Roughening at Interfaces. Phys. Rev. B 2011, 84 (3). doi.org/10.1103/PhysRevB.84.035438.

(129) Collins, K. C.; Chen, S.; Chen, G. Effects of Surface Chemistry on Thermal Conductance at Aluminum-Diamond Interfaces. Appl. Phys. Lett. 2010, 97 (8), 083102. doi.org/10.1063/1.3480413.

(130) Abyzov, A. M.; Kidalov, S. V.; Shakhov, F. M. High Thermal Conductivity Composites Consisting of Diamond Filler with Tungsten Coating and Copper (Silver) Matrix. J. Mater. Sci. 2011, 46 (5), 1424-1438. doi.org/10.1007/s10853-010-4938-x.

(131) Monachon, C.; Weber, L. Influence of a Nanometric Al2O3 Interlayer on the Thermal Conductance of an Al/(Si, Diamond) Interface. Adv. Eng. Mater. 17 (1), 68-75. doi.org/10.1002/adem.201400060.

(132) Monachon, C.; Weber, L. Influence of Diamond Surface Termination on Thermal Boundary Conductance between Al and Diamond. J. Appl. Phys. 2013, 113 (18), 183504. doi.org/10.1063/1.4804061.

(133) Duda, J. C.; Yang, C.-Y. P.; Foley, B. M.; Cheaito, R.; Medlin, D. L.; Jones, R. E.; Hopkins, P. E. Influence of Interfacial Properties on Thermal Transport at Gold:Silicon Contacts. Appl. Phys. Lett. 2013, 102 (8), 081902. doi.org/10.1063/1.4793431.

(134) Schubert, T.; Ciupiński, Ł.; Zieliński, W.; Michalski, A.; Weißgärber, T.; Kieback, B. Interfacial Characterization of Cu/Diamond Composites Prepared by Powder Metallurgy for Heat Sink Applications. Scr. Mater. 2008, 58 (4), 263-266. doi.org/10.1016/j.scriptamat.2007.10.011.

(135) Schubert, Th.; Trindade, B.; Weißgärber, T.; Kieback, B. Interfacial Design of Cu-Based Composites Prepared by Powder Metallurgy for Heat Sink Applications. Mater. Sci. Eng. A 2008, 475 (1-2), 39-44. doi.org/10.1016/j.msea.2006.12.146.

(136) W. Zhou, X.; E. Jones, R.; C. Duda, J.; E. Hopkins, P. Molecular Dynamics Studies of Material Property Effects on Thermal Boundary Conductance. Phys. Chem. Chem. Phys. 2013, 15 (26), 11078-11087. doi.org/10.1039/C3CP51131F.

(137) Weber, L.; Tavangar, R. On the Influence of Active Element Content on the Thermal Conductivity and Thermal Expansion of Cu—X (X═Cr, B) Diamond Composites. Scr. Mater. 2007, 57 (11), 988-991. doi.org/10.1016/j.scriptamat.2007.08.007.

(138) Monje, I. E.; Louis, E.; Molina, J. M. Optimizing Thermal Conductivity in Gas-Pressure Infiltrated Aluminum/Diamond Composites by Precise Processing Control. Compos. Part Appl. Sci. Manuf. 2013, 48, 9-14. doi.org/10.1016/j.compositesa.2012.12.010.

(139) Ruch, P. W.; Beffort, O.; Kleiner, S.; Weber, L.; Uggowitzer, P. J. Selective Interfacial Bonding in Al(Si)-Diamond Composites and Its Effect on Thermal Conductivity. Compos. Sci. Technol. 2006, 66 (15), 2677-2685. doi.org/10.1016/j.compscitech.2006.03.016.

(140) Monachon, C.; Weber, L. Thermal Boundary Conductance between Refractory Metal Carbides and Diamond. Acta Mater. 2014, 73, 337-346. doi.org/10.1016/j.actamat.2014.04.024.

(141) Monachon, C.; Weber, L. Thermal Boundary Conductance of Transition Metals on Diamond. Emerg. Mater. Res. 2012, 1 (2), 89-98. doi.org/10.1680/emr.11.00011.

(142) Hohensee, G. T.; Wilson, R. B.; Cahill, D. G. Thermal Conductance of Metal-Diamond Interfaces at High Pressure. Nat. Commun. 2015, 6, 6578. doi.org/10.1038/ncomms7578.

(143) Kida, M.; Weber, L.; Monachon, C.; Mortensen, A. Thermal Conductivity and Interfacial Conductance of AN Particle Reinforced Metal Matrix Composites. J. Appl. Phys. 2011, 109 (6), 064907. doi.org/10.1063/1.3553870.

(144) Choi, C.; Roberts, N. Contributions of Mass and Bond Energy Difference and Interface Defects on Thermal Boundary Conductance. AIP Adv. 2015, 5 (9), 097160. doi.org/10.1063/1.4931640.

(145) Sato, K.; Shikida, M.; Yamashiro, T.; Tsunekawa, M.; Ito, S. Roughening of Single-Crystal Silicon Surface Etched by KOH Water Solution. Sens. Actuators Phys. 1999, 73 (1), 122-130. doi.org/10.1016/S0924-4247(98)00270-2.

(146) Quéré, D. Wetting and Roughness. Annu. Rev. Mater. Res. 2008, 38 (1), 71-99. doi.org/10.1146/annurev.matsci.38.060407.132434.

(147) Jennings, C. W. Surface Roughness and Bond Strength of Adhesives. J. Adhes. 1972, 4 (1), 25-38. doi.org/10.1080/00218467208072208.

(148) Santamore, D. H.; Cross, M. C. Effect of Surface Roughness on the Universal Thermal Conductance. Phys. Rev. B 2001, 63 (18). doi.org/10.1103/PhysRevB.63.184306.

(149) Hopkins, P. E.; Phinney, L. M.; Serrano, J. R.; Beechem, T. E. Effects of Surface Roughness and Oxide Layer on the Thermal Boundary Conductance at Aluminum/Silicon Interfaces. 2010, 313-319. doi.org/10.1115/IHTC14-22268.

(150) Wang, H.; Wu, Y.; Cong, C.; Shang, J.; Yu, T. Hysteresis of Electronic Transport in Graphene Transistors. ACS Nano 2010, 4 (12), 7221-7228. doi.org/10.1021/nn101950n.

(151) Liao, Z.-M.; Han, B.-H.; Zhou, Y.-B.; Yu, D.-P. Hysteresis Reversion in Graphene Field-Effect Transistors. J. Chem. Phys. 2010, 133 (4), 044703. doi.org/10.1063/1.3460798.

(152) Yang, J.; Jia, K.; Su, Y.; Chen, Y.; Zhao, C. Hysteresis Analysis of Graphene Transistor under Repeated Test and Gate Voltage Stress. J. Semicond. 2014, 35 (9), 094003. doi.org/10.1088/1674-4926/35/9/094003.

(153) Bartošík, M.; Mach, J.; Piastek, J.; Nezval, D.; Konečný, M.; Švarc, V.; Ensslin, K.; Šikola, T. Mechanism and Suppression of Physisorbed-Water-Caused Hysteresis in Graphene FET Sensors. ACS Sens. 2020, 5 (9), 2940-2949. doi.org/10.1021/acssensors.0c01441.

(154) Leenaerts, O.; Partoens, B.; Peeters, F. M. Adsorption of H₂O, NH₃, CO, NO₂, and NO on Graphene: A First-Principles Study. Phys. Rev. B 2008, 77 (12), 125416. doi.org/10.1103/PhysRevB.77.125416.

(155) Wehling, T. O.; Lichtenstein, A. I.; Katsnelson, M. I. First-Principles Studies of Water Adsorption on Graphene: The Role of the Substrate. Appl. Phys. Lett. 2008, 93 (20), 202110. doi.org/10.1063/1.3033202.

(156) Li, X.; Feng, J.; Wang, E.; Meng, S.; Klimeš, J.; Michaelides, A. Influence of Water on the Electronic Structure of Metal-Supported Graphene: Insights from van Der Waals Density Functional Theory. Phys. Rev. B 2012, 85 (8), 085425. doi.org/10.1103/PhysRevB.85.085425.

(157) Bonmann, M., A. Vorobiev, J. Stake, O. Engström, J. Vac. Sci. Technol. B 2017, 35, 01A115.

(158) Bielinski, A. R., M. Boban, Y. He, E. Kazyak, D. H. Lee, C. Wang, A. Tuteja, N. P. Dasgupta, ACS Nano 2017, 11, 478.

(159) McCoy, T. M., S. A. Holt, A. M. Rozario, T. D. M. Bell, R. F. Tabor, Adv. Mater. Interfaces 2017, 4, 1700803.

(160) Turpin, G. A., S. A. Holt, J. M. P. Scofield, B. M. Teo, R. F. Tabor, Adv. Mater. Interfaces 2020, 7, 1901810.

(161) Rafiee, J., X. Mi, H. Gullapalli, A. V. Thomas, F. Yavari, Y. Shi, P. M. Ajayan, N. A. Koratkar, Nat. Mater. 2012, 11, 217.

(162) Liang, X.-Y., N. Ding, S.-P. Ng, C.-M. L. Wu, Appl. Surf. Sci. 2017, 411, 11.

(163) Naghdi, S., G. Sanchez-Arriaga, K. Y. Rhee, J. Alloys Compd. 2019, 805, 1117.

(164) Tan, Y.-W., Y. Zhang, K. Bolotin, Y. Zhao, S. Adam, E. H. Hwang, S. Das Sarma, H. L. Stormer, P. Kim, Phys. Rev. Lett. 2007, 99, 246803.

(165) Behrndt, K.H., Vacuum Microbalance Techniques: Volume 5, Springer US, 1966.

(166) Bruschi, L., G. Mistura, Phys. Rev. B 2001, 63, 235411.

(167) Deng, X., T. Herranz, C. Weis, H. Bluhm, M. Salmeron, J. Phys. Chem. C 2008, 112, 9668.

(168) Kittel, C., K. Charles, H. Kroemer, K. Herbert, Thermal Physics, Macmillan, 1980.

(169) Matis, B. R., J. S. Burgess, F. A. Bulat, A. L. Friedman, B. H. Houston, J. W. Baldwin, ACS Nano 2012, 6, 17.

(170) Solís-Fernández, P., S. Okada, T. Sato, M. Tsuji, H. Ago, ACS Nano 2016, 10, 2930.

1. A device having a controlled property with respect to surrounding molecules, comprising:
a substrate having a conductive surface;
a dielectric layer formed on the conductive surface; and
a semiconductor nanomaterial, formed on the dielectric layer,
wherein an electrostatic field from the conductive material modifies a property of the semiconductor nanomaterial with respect to the surrounding molecules.

2. The device according to claim 1, wherein the dielectric layer is an insulator, and the conductive material is a metal.

3. The device according to claim 1, wherein the surrounding molecules comprise polar molecules, and the property comprises an absorption or wetting of the semiconductor nanomaterial surface with the polar molecules.

4. The device according to claim 3, wherein the polar molecules comprise water.

5. The device according to claim 1, wherein the semiconductor nanomaterial is graphene.

6. The device according to claim 1, wherein the semiconductor nanomaterial is MoS₂.

7. The device according to claim 1, wherein the semiconductor nanomaterial is a boron compound.

8. The device according to claim 1, further comprising a nanoporous material over the semiconductor nanomaterial.

9. The device according to claim 1, further comprising a metal organic framework over the semiconductor nanomaterial.

10. The device according to claim 1, further comprising a zeolite over the semiconductor nanomaterial.

11. The device according to claim 1, further comprising catalytic nanoparticles proximate to the semiconductor nanomaterial.

12. The device according to claim 1, further comprising a porous membrane, wherein a transport across the porous membrane is dependent on the electrostatic field.

13. The device according to claim 1, further comprising an electronic control configured to establish the electrostatic field.

14. The device according to claim 1, wherein the surrounding molecules are physiosorbed or chemisorbed.

15. The device according to claim 1, further comprising an electronic sensor configured to sense electrical conductivity through the semiconductor nanomaterial.

16. A method of controlling a surface property, comprising:
providing a device having a semiconductor nanomaterial having a surface, formed on a dielectric layer, having a conductive material under the dielectric layer configured to impose an electric field on the semiconductor nanomaterial; and
controlling an electrostatic field on the semiconductor nanomaterial to modify the property of the surface with respect to surrounding molecules.

17. The device according to claim 16, wherein the dielectric layer is an insulator, the conductive material is a metal, and the semiconductor nanomaterial is a 2D material selected from the group consisting of graphene, molybdenum disulfide, and a boron compound.

18. The method according to claim 16, wherein at least one of a nanoporous material, a metal organic framework, a zeolite, catalytic nanoparticles, a surfactant, and a liquid crystal is provided over the semiconductor nanomaterial.

19. The method according to claim 16, wherein a porous membrane is provided, wherein a transport of molecules across the porous membrane is dependent on the electrostatic field.

20. A system, comprising:
a conductive substrate;
a dielectric material on the conductive substrate;
a semiconductor nanomaterial, formed on the dielectric material; and
an automated control, configured to control an electrostatic field surrounding the material, to thereby alter a surface property of the semiconductor nanomaterial.
